(19) United States
(12) Patent Application Publication
(10) Pub. No.: US 2025/0017209 A1
(43) Pub. Date: Jan. 16, 2025

(54) COMPOSITION, MANUFACTURING METHOD FOR SEMICONDUCTOR ELEMENT, AND CLEANING METHOD FOR SEMICONDUCTOR SUBSTRATE

(71) Applicant: FUJIFILM Corporation, Tokyo (JP)

(72) Inventors: Tadashi INABA, Haibara-gun (JP); Naotsugu Muro, Haibara-gun (JP); Tetsuya Kamimura, Haibara-gun (JP); Naoko Ouchi, Haibara-gun (JP)

(73) Assignee: FUJIFILM Corporation, Tokyo (JP)

(21) Appl. No.: 18/890,032

(22) Filed: Sep. 19, 2024

Related U.S. Application Data
(63) Continuation of application No. PCT/JP2023/010327, filed on Mar. 16, 2023.

(30) Foreign Application Priority Data
Mar. 25, 2022 (JP) 2022-050223
Jul. 28, 2022 (JP) 2022-120452
Mar. 10, 2023 (JP) 2023-037421

(51) Int. Cl. A01N 43/80; A01N 25/02; A01N 31/08; A01N 33/12; A01N 37/06; A01N 37/16; A01N 41/06; A01N 43/16; A01N 47/44; B24B 37/04; C11D 7/26; C11D 7/32; C11D 7/34; C11D 7/36; H01L 21/02; H01L 21/306

(52) U.S. Cl. CPC A01N 43/80; A01N 25/02; A01N 31/08; A01N 33/12; A01N 37/06; A01N 37/16; A01N 41/06; A01N 43/16; A01N 47/44; B24B 37/044; C11D 7/261; C11D 7/265; C11D 7/3218; C11D 7/3227; C11D 7/3281; C11D 7/34; C11D 7/36; H01L 21/02057; H01L 21/30625

(57) ABSTRACT

The present invention provides a composition that suppresses the occurrence of defects in an object to be applied, even in a case of being used after a predetermined period of time has elapsed from the production. In addition, the present invention provides a manufacturing method for a semiconductor element and a cleaning method for a semiconductor substrate.

The composition according to the present invention is a composition containing an antibacterial agent, an organic acid, an organic amine, and water, in which a content of the water is 70% by mass or more with respect to a total mass of the composition, and a pH at 25° C. is 4.0 to 9.0.

### CROSS-REFERENCE TO RELATED APPLICATIONS

This application is a Continuation of PCT International Application No. PCT/JP2023/010327 filed on Mar. 16, 2023, which claims priority under 35 U.S.C. § 119(a) to Japanese Patent Application No. 2022-050223 filed on Mar. 25, 2022, Japanese Patent Application No. 2022-120452 filed on Jul. 28, 2022, and Japanese Patent Application No. 2023-037421 filed on Mar. 10, 2023. The above applications are hereby expressly incorporated by reference, in their entirety, into the present application.

### BACKGROUND OF THE INVENTION

### 1. Field of the Invention

The present invention relates to a composition, a manufacturing method for a semiconductor element, and a cleaning method for a semiconductor substrate.

### 2. Description of the Related Art

Semiconductor elements such as charge-coupled devices (CCD) and memories are manufactured by forming fine electronic circuit patterns on a substrate, using photolithography technology. Specifically, semiconductor elements are manufactured by forming a resist film on a laminate that has a metal film serving as a wiring line material, an etching stop layer, and an interlayer insulating layer on a substrate, and carrying out a photolithography step and a dry etching step (for example, a plasma etching treatment).

In manufacturing of a semiconductor element, a chemical mechanical polishing treatment of flattening a surface of a semiconductor substrate having a metal wiring line film, a barrier metal, an insulating film, and the like may be carried out by using a polishing liquid containing polishing fine particles (for example, silica and alumina). In the chemical mechanical polishing treatment, residues such as polishing fine particles used in the chemical mechanical polishing treatment, a polished wiring line metal film, and/or a metal component derived from a barrier metal or the like are likely to remain on the surface of the semiconductor substrate after the chemical mechanical polishing treatment.

Since these residues can short-circuit wiring lines and adversely affect the electrical characteristics of a semiconductor, a cleaning step in which these residues are removed from a surface of the semiconductor substrate is generally carried out.

For example, WO2013/162020A discloses a cleaning agent that is used in a post-process of a chemical mechanical polishing step for a semiconductor substrate having a tungsten wiring line or a tungsten alloy wiring line and having a silicon oxide film, where the cleaning agent is a cleaning agent for a semiconductor substrate, which contains (A) a phosphonic acid-based chelating agent, (B) a primary or secondary monoamine having at least one alkyl group or hydroxylalkyl group in a molecule, and (C) water, and has a pH of more than 6 and less than 7.

### SUMMARY OF THE INVENTION

In association with the miniaturization of semiconductor elements, a composition that is used in the manufacturing process of a semiconductor element, such as a cleaning liquid for a semiconductor substrate, is demanded to have more excellent cleaning performance which makes it possible to remove smaller residues. In addition, the above-described composition needs to not only remove residues (for example, polishing abrasive grains, a metal-containing substance, an organic substance, a substrate material, and a mixture thereof) but also suppress damage (for example, the corrosion or the like of the metal film) to an object such as a substrate. The performance of such a composition for a semiconductor production is often expressed as the number of defects (defects) that are obtained by combining the number of residues and the number of damages.

On the other hand, the number of kinds of elements that are used in the manufacturing process of semiconductor elements tends to increase. Therefore, in order to respond to new kinds of elements, there is a demand for a composition having a wide pH range including a pH range of strong acidity, a pH range of strong alkalinity, and a neutral pH range therebetween.

As a result of studying a composition for a semiconductor substrate, which is close to neutral, based on the technical content described in WO2013/162020A, the inventors of the present invention found that in a case where the composition is used after a predetermined period of time has elapsed from the production, a lot of defects occur in an object to be subjected to application, and thus there is room for improvement.

Therefore, an object of the present invention is to provide a composition that suppresses the occurrence of defects in an object to be subjected to application, even in a case of being used after a predetermined period of time has elapsed from the production. In addition, another object of the present invention is to provide a manufacturing method for a semiconductor element and a cleaning method for a semiconductor substrate.

As a result of diligent studies to achieve the objects, the inventors of the present invention found that the objects can be achieved by the following configurations.

[1] A composition comprising:
an antibacterial agent;
an organic acid;
an organic amine; and
water,
in which a content of the water is 70% by mass or more with respect to a total mass of the composition, and
a pH at 25° C. is 4.0 to 9.0.

[2] The composition according to [1], in which the composition is at least one selected from the group consisting of a cleaning liquid for a semiconductor substrate which has been subjected to a chemical mechanical polishing treatment, a cleaning liquid for a brush that is used for cleaning of a semiconductor substrate, a cleaning liquid for a polishing pad that is used for a treatment of a semiconductor substrate, and a cleaning liquid for buffing cleaning of a semiconductor substrate which has been subjected to a chemical mechanical polishing treatment.

[3] The composition according to [1] or [2], in which a ratio of a content of the antibacterial agent to a content of the organic acid is 0.5 or less in terms of mass ratio, and a ratio of the content of the antibacterial agent to a content of the organic amine is 0.3 or less in terms of mass ratio.

[4] The composition according to any one of [1] to [3], in which the composition is a cleaning liquid for a tungsten-containing semiconductor substrate which has been subjected to a chemical mechanical polishing treatment, or a cleaning liquid for buffing cleaning of a tungsten-containing semiconductor substrate which has been subjected to a chemical mechanical polishing treatment.

[5] The composition according to any one of [1] to [3], in which the composition is a cleaning liquid for a polishing pad containing a polyurethane resin, where the polishing pad is used for a treatment of a semiconductor substrate.

[6] The composition according to any one of [1] to [3], in which the composition is a cleaning liquid for a brush containing a polymer resin having a hydroxyl group, where the brush is used for cleaning of a semiconductor substrate.

[7] The composition according to [1], in which the composition is used for a use application different from any of a cleaning liquid for a semiconductor substrate which has been subjected to a chemical mechanical polishing treatment, a cleaning liquid for a brush that is used for cleaning of a semiconductor substrate, a cleaning liquid for a polishing pad that is used for a treatment of a semiconductor substrate, and a cleaning liquid for buffing cleaning of a semiconductor substrate which has been subjected to a chemical mechanical polishing treatment.

[8] The composition according to any one of [1] to [7], in which an electric conductivity at 25° C. is 0.1 to 2.0 S/m.

[9] The composition according to any one of [1] to [8], in which a diluted liquid obtained by diluting the composition by 50 times or more is used as a cleaning liquid.

[10] The composition according to any one of [1] to [9], in which the organic acid is a compound that has a carboxy group or a sulfo group and has neither an amino group nor a phosphonate group in a molecule.

[11] The composition according to any one of [1] to [10], in which the organic acid contains one or more hydroxy groups and two or more carboxy groups.

[12] The composition according to any one of [1] to [11], in which the organic amine is a compound or a salt thereof, which has at least one amino group selected from the group consisting of a primary amino group, a secondary amino group, and a tertiary amino group in a molecule and has no carboxy group in the molecule.

[13] The composition according to any one of [1] to [12], in which the organic amine is an alkanolamine.

[14] The composition according to any one of [1] to [13], further comprising a chelating agent.

[15] The composition according to any one of [1] to [14], in which the chelating agent has a phosphonate group.

[16] The composition according to any one of [1] to [15], further comprising an anticorrosive agent.

[17] The composition according to any one of [1] to [16], in which the anticorrosive agent is a compound having a purine skeleton.

[18] The composition according to any one of [1] to [17], in which the antibacterial agent includes at least one selected from the group consisting of a carboxylic acid-based antibacterial agent and an isothiazolinone-based antibacterial agent.

[19] A manufacturing method for a semiconductor element, comprising:
a step of cleaning a semiconductor substrate using the composition according to any one of [1] to [18]

[20] A manufacturing method for a semiconductor element, comprising:
a step of subjecting a semiconductor substrate to a chemical mechanical polishing treatment; and
a step of cleaning the semiconductor substrate subjected to the chemical mechanical polishing treatment, by using the composition according to any one of [1] to [18].

[21] A manufacturing method for a semiconductor element, comprising:
a step of subjecting a semiconductor substrate to a chemical mechanical polishing treatment; and
a step of cleaning the semiconductor substrate subjected to the chemical mechanical polishing treatment, by using a diluted liquid obtained by diluting the composition according to any one of [1] to [18] with water by 50 times or more in terms of mass ratio.

[22] A cleaning method for a semiconductor substrate, comprising:
cleaning a semiconductor substrate using the composition according to any one of [1] to [18].

According to the present invention, it is possible to provide a composition that suppresses the occurrence of defects in an object to be subjected to application, even in a case of being used after a predetermined period of time has elapsed from the production. In addition, the present invention can provide a manufacturing method for a semiconductor element and a cleaning method for a semiconductor substrate.

### DESCRIPTION OF THE PREFERRED EMBODIMENTS

Hereinafter, an example of a form for carrying out the present invention will be described. The present invention is not limited to the following embodiments and can be implemented in variously modified forms within the scope of the gist of the present invention.

In the present specification, the numerical value range indicated by using “to” means a range including the numerical values before and after “to” as the lower limit value and the upper limit value, respectively.

In the present specification, the term “preparing” includes not only preparing a predetermined substance by a treatment such as synthesis or blending of raw materials, but also procuring the predetermined substance by purchasing or the like.

In the present specification, in a case where two or more kinds of a certain component are present, the “content” of the component means the total content of the two or more kinds of the component unless otherwise specified.

The compound described in the present specification may include a structural isomer, an optical isomer, and an isotope unless otherwise specified. In addition, one kind of structural isomer, optical isomer, and isotope alone, or two or more kinds thereof may be included.

In the present specification, “psi” means pound-force per square inch, and 1 psi means 6,894.76 Pa.

In the present specification, “ppm” means “parts-per-million (10⁻⁶)”, and “ppb” means “parts-per-billion (10⁻⁹)”.

In the present specification, 1 Å (angstrom) corresponds to 0.1 nm.

In the present specification, unless otherwise specified, the weight-average molecular weight (Mw) and the number average molecular weight (Mn) are values obtained by using TSKgel GMHxL, TSKgel G4000HxL, or TSKgel G2000HxL (all of which are manufactured by Tosoh Corporation) as a column, using tetrahydrofuran as an eluent, using a differential refractometer as a detector, using polystyrene as a standard substance, and carrying out conversion using the polystyrene as a standard substance, which has been subjected to measurement with a gel permeation chromatography (GPC) analysis apparatus.

In the present specification, unless otherwise specified, the molecular weight of a compound having a molecular weight distribution is a weight-average molecular weight.

In the present specification, the term “total solid content” means the total content of all components contained in the composition other than a solvent such as water or an organic solvent.

In the present specification, the concept of “(meth)acrylic acid” includes both acrylic acid and methacrylic acid, and the concept of “(meth)acrylamide” includes both acrylamide and methacrylamide.

### [Composition]

A composition according to an embodiment of the present invention (hereinafter, also simply referred to as a “composition”) contains an antibacterial agent, an organic acid, an organic amine, and water, where a content of the water is 70% by mass or more with respect to a total mass of the composition. In addition, the pH of the composition at 25° C. is 4.0 to 9.0.

The inventors of the present invention found that in a case where the composition contains each of the above-described components, the content of water is in the above-described range, and the pH is 4.0 to 9.0, an effect of suppressing an increase in defects in an object to be subjected to application (hereinafter, also referred to as “the effect of the present invention”) is improved even in a case where the composition is used after a predetermined period of time has elapsed from the production, whereby the present invention was completed.

Although a detailed mechanism by which the effect of the present invention is obtained with such a composition is unknown, the inventors of the present invention presume as follows. The organic acid has a property of forming a salt with a cation (a metal ion or the like) having low solubility, thereby making the salt easy to dissolve in a neutral range (pH 4.0 to 9.0). The organic amine has a property of forming a salt with a hydrophobic anion (such as a BTA derivative) in a neutral range, thereby making the salt easy to dissolve. In addition, in a case where the organic acid and the organic amine are mixed, the organic acid and the organic amine are ionized with each other, and thus the electric conductivity in the aqueous solution is increased, or the surface zeta potential of a substance in contact with the aqueous solution is shifted. Therefore, a residue having an electric charge (colloidal silica or the like) is likely to receive electrical repulsion. From the above facts, it is presumed that the organic acid and the organic amine make it easy for the residue on the object to be released and suppress the reattachment thereof.

On the other hand, in a case where a balance of a quantity ratio between the cation and the anion is disturbed due to some reason, such characteristics as described above may be deteriorated. For example, in a case where a composition accommodated in a tank is not used and time passes, microorganisms such as bacteria and fungi may grow while consuming an active ingredient of the composition. Such a case causes an event in which the reduction of the active ingredient causes an increase in the time required for removing residues, the proliferated microorganisms themselves cause the defects, or microorganisms that form a biofilm further inhibit the release of residues, and thus it is presumed that the defects increase in the object to which the composition is applied.

On the other hand, it is presumed that due to containing the above-described specific component including an antibacterial agent, the present composition can suppress an increase in defects even in a neutral pH range.

Hereinafter, each component contained in the composition will be described.

### [Antibacterial Agent]

The present composition contains an antibacterial agent.

The antibacterial agent is a compound having an antibacterial action against bacteria and/or an antifungal action against fungi, and it is a compound different from various components described later.

The antibacterial agent may have a form of a salt (for example, a publicly known salt).

Examples of the antibacterial agent include a quaternary ammonium-based antibacterial agent, a carboxylic acid-based antibacterial agent, a phenol-based antibacterial agent, a biguanide-based antibacterial agent, a sulfamide-based antibacterial agent, a peroxide-based antibacterial agent, an isothiazolinone-based antibacterial agent, an imidazole-based antibacterial agent, an ester-based antibacterial agent, an alcohol-based antibacterial agent, a carbamate-based antibacterial agent, an iodine-based antibacterial agent, and an antibiotic.

The quaternary ammonium-based antibacterial agent means a compound having an antibacterial action and/or an antifungal action among compounds or salts thereof, each of which has at least one quaternary ammonium cationic group in the molecule.

Examples of the quaternary ammonium-based antibacterial agent include benzalkonium chloride, didecyldimethylammonium chloride (DDAC), hexadecylpyridinium chloride (CPC), 3,3′-(2,7-dioxa-octane)bis(1-dodecylpyridinium bromide) (Hygeria), benzethonium chloride, and domiphen bromide. Among these, benzethonium chloride is preferable.

Examples of the carboxylic acid-based antibacterial agent include unsaturated carboxylic acids such as sorbic acid (hexadienoic acid) and dehydroacetic acid, and aromatic carboxylic acids such as benzoic acid and salicylic acid. Among these, sorbic acid, dehydroacetic acid, or benzoic acid is preferable, sorbic acid or dehydroacetic acid is more preferable, and sorbic acid is still more preferable.

Examples of the phenol-based antibacterial agent include 3-methyl-4-chlorophenol (PCMC), 3-methyl-4-isopropylphenol (BIOSOL), 4-chloro-3,5-dimethylphenol (PCMX), cresol, chlorothymol, dichloroxylenol, and hexachlorophene. Among these, cresol is preferable.

Examples of the biguanide-based antibacterial agent include bis(p-chlorophenyldiguanide)hexanedigluconate (chlorhexidine gluconate) and poly(hexamethylene biguanide)hydrochloride (hexamethylene biguanidine hydrochloride). Among these, chlorhexidine gluconate is preferable.

Examples of the sulfamide-based antibacterial agent include N-dichlorofluoromethylthio-N′,N′-dimethyl-N-phenylsulfamide (dichlofluanid) and N-dichlorofluoromethylthio-N′,N′-dimethyl-N-p-tolylsulfamide (tolylfluanid). Among these, tolylfluanid is preferable.

Examples of the peroxide-based antibacterial agent include hydrogen peroxide, peracetic acid, and chlorine dioxide. Among these, peracetic acid is preferable.

Examples of the isothiazolinone-based antibacterial agent include 2-methyl-4-isothiazolin-3-one (MIT), 2-octyl-4-isothiazolin-3-one (OIT), 1,2-benzisothiazol-3(2H)-one (BIT), and 5-chloro-2-methyl-4-isothiazolin-3-one (CIT). Among these, MIT, OIT, or BIT is preferable, and MIT or OIT is more preferable.

Examples of the imidazole-based antibacterial agent include 2-(4-thiazolyl)-benzimidazole (TBZ) and methyl 2-benzimidazolecarbamate (PREVENTOL BCM).

Examples of the ester-based antibacterial agent include glycerol laurate (monoglyceride) and a parahydroxybenzoic acid ethyl ester (ethylparaben).

Examples of the alcohol-based antibacterial agent include ethyl alcohol (ethanol), 2-propanol (IPA), phenoxyethanol, 1,2-pentanediol, and 1,2-hexanediol.

Examples of the carbamate-based antibacterial agent include 3-iodo-2-propynyl butyl carbamate (GLYCASIL).

Examples of the iodine-based antibacterial agent include [(4-chlorophenoxy)methyl]-3-iodo-2-propynyl ether (IF1000).

The antibacterial agent preferably includes at least one selected from the group consisting of a carboxylic acid-based antibacterial agent and an isothiazolinone-based antibacterial agent, and more preferably includes an isothiazolinone-based antibacterial agent.

In addition, the antibacterial agent more preferably includes at least one selected from the group consisting of sorbic acid, MIT, OIT, and BIT, and still more preferably includes at least one selected from the group consisting of MIT and OIT.

The antibacterial agent may be used alone or in a combination of two or more kinds thereof.

The content of the antibacterial agent is preferably 0.001% to 1.500% by mass and more preferably 0.005% to 0.800% by mass with respect to the total mass of the composition.

In addition, the content of the antibacterial agent is preferably 0.010% to 15.00% by mass and more preferably 0.050% to 8.000% by mass with respect to the total solid content in the composition.

### [Organic Acid]

The present composition contains an organic acid.

The organic acid is an organic compound that has an acidic functional group and is acidic (has a pH of less than 7.0) in an aqueous solution.

It is noted that in the present specification, a compound included in any of a compound having an amino group, the above-described antibacterial agent, a phosphonic acid-based chelating agent described later, an amino polycarboxylic acid-based chelating agent described later, an amino acid-based chelating agent described later, a water-soluble polymer described later, and an anionic surfactant described later is not included in the organic acid.

Examples of the acidic functional group contained in the organic acid include a carboxy group and a sulfo group.

Examples of the organic acid include a carboxylic acid having at least one carboxy group and a sulfonic acid having at least one sulfo group, where a carboxylic acid is preferable. In addition, an organic acid that has neither an amino group nor a phosphonate group in the molecule is preferable.

The organic acid may have a salt form. Examples of the salt include a sodium salt, a potassium salt, and an ammonium salt.

The organic acid is preferably a compound having a weight-average molecular weight of less than 1,000.

Examples of the carboxylic acid include an aliphatic carboxylic acid and an aromatic carboxylic acid.

The number of carboxy groups contained in the carboxylic acid is preferably 2 or more, more preferably 2 to 10, and still more preferably 2 to 5.

In addition, the carboxylic acid may further have a hydroxy group as a functional group other than the carboxy group and preferably further has a hydroxy group. It is more preferably a carboxylic acid having at least one hydroxy group and at least two carboxy groups. The upper limit of the number of hydroxy groups contained in the carboxylic acid is not particularly limited; however, it is preferably 5 or less.

Examples of the aliphatic carboxylic acid include glycolic acid, lactic acid, gluconic acid, oxalic acid, malic acid, tartaric acid, malonic acid, succinic acid, glutaric acid, adipic acid, pimelic acid, sebacic acid, maleic acid, fumaric acid, and citric acid.

Examples of the aromatic carboxylic acid include phthalic acid, isophthalic acid, terephthalic acid, gallic acid, trimellitic acid, mellitic acid, and cinnamic acid.

The carboxylic acid is preferably oxalic acid, malic acid, tartaric acid, malonic acid, succinic acid, glutaric acid, maleic acid, fumaric acid, citric acid, lactic acid, gluconic acid, or glutaric acid, and more preferably tartaric acid or citric acid.

The number of sulfo groups contained in the sulfonic acid is preferably 1 or 2 and more preferably 1.

The sulfonic acid may further have a hydroxy group as a functional group other than the sulfo group.

Examples of the sulfonic acid include methanesulfonic acid, ethanesulfonic acid, propanesulfonic acid, butanesulfonic acid, 2-hydroxyethanesulfonic acid, 3-hydroxypropanesulfonic acid, benzenesulfonic acid, p-toluenesulfonic acid, 4-hydroxybenzenesulfonic acid, 1-naphthalenesulfonic acid, and 2-naphthalenesulfonic acid.

The organic acid is preferably a carboxylic acid, more preferably a carboxylic acid having at least one hydroxy group and at least one carboxy group, still more preferably a carboxylic acid having at least one hydroxy group and at least two carboxy groups, and particularly preferably tartaric acid or citric acid.

The organic acid may be used alone or in a combination of two or more kinds thereof.

The content of the organic acid is preferably 0.01% to 10.0% by mass and more preferably 0.03% to 6.0% by mass with respect to the total mass of the composition.

The content of the organic acid is preferably 0.1% to 3.0% by mass and more preferably 0.3% to 20.0% by mass with respect to the total solid content in the composition.

From the viewpoint that other performances are more excellent while reducing the number of defects, the ratio A/B of the content of the antibacterial agent to the content of the organic acid (content A of antibacterial agent/content B of organic acid) is preferably 0.5 or less and more preferably 0.3 or less in terms of mass ratio. The lower limit of the ratio A/B is not particularly limited; however, it is preferably 0.01 or more and more preferably 0.05 or more from the viewpoint that the effect of the present invention is more excellent.

### [Organic Amine]

The present composition contains an organic amine.

The organic amine is a compound or a salt thereof, which has, in the molecule, at least one group selected from the group consisting of a primary amino group, a secondary amino group, a tertiary amino group, and a quaternary ammonium cationic group. In a case where an organic amine has amino groups of different orders, the organic amine is classified as an organic amine having the highest-order group among the amino groups.

It is noted that in the present specification, a compound that functions as the antibacterial agent (for example, a quaternary ammonium-based antibacterial agent), a compound that functions as a chelating agent described later, and a compound that functions as an anticorrosive agent described later are not included in the organic amine.

Examples of the salt of the organic amine include a salt between the organic amine and an inorganic acid in which at least one non-metal selected from the group consisting of Cl, S, N, and P is bonded to hydrogen, where a hydrochloride, a sulfate, or a nitrate is preferable.

It is preferable that the organic amine is a liquid at 50° C. and exhibits alkalinity (the pH at 25° C. is more than 7.0) in an aqueous solution. Among the above, the organic amine is more preferably an organic amine having a pH of 9.0 to 14.0, and still more preferably an organic amine having a pH of 10.0 to 13.0, where the pH is a pH at 25° C. in an aqueous solution obtained by dissolving the organic amine at a proportion of 0.1 mol/L.

The organic amine may be either chain-like (linear or branched) or cyclic.

Examples of the organic amine include an alkanolamine, an alicyclic amine, an aliphatic amine other than an alkanolamine and an alicyclic amine, and a quaternary ammonium compound.

### <Alkanolamine>

The alkanolamine is, among the organic amines, a compound that further has at least one hydroxylalkyl group in the molecule. The alkanolamine may have any of a primary amino group, a secondary amino group, or a tertiary amino group; however, it preferably has a primary amino group.

The number of amino groups contained in the alkanolamine is, for example, 1 to 5, and preferably 1 to 3.

The number of hydroxy groups contained in the alkanolamine is, for example, 1 to 5, and more preferably 1 to 3.

Among these, the alkanolamine more preferably has only a primary amino group as the amino group.

Examples of the alkanolamine include monoethanolamine (MEA), 3-amino-1-propanol, 1-amino-2-propanol, tris(hydroxymethyl)aminomethane (Tris), 2-amino-2-methyl-1-propanol (AMP), 2-dimethylamino-2-methyl-1-propanol (DMAMP), 2-amino-2-methyl-1,3-propanediol (AMPDO), 2-amino-2-ethyl-1,3-propanediol (AEPDO), 2-amino-1,3-propanediol (2-APDO), 3-amino-1,2-propanediol (3-APDO), 3-methylamino-1,2-propanediol (MAPDO), 2-(methylamino)-2-methyl-1-propanediol (N-MAMP), 2-(aminoethoxy)ethanol (AEE), 2-(2-aminoethylamino)ethanol (AAE), diethanolamine (DEA), triethanolamine (TEA), N-methylethanolamine, N-butyethanolamine, N-cyclohexylethanolamine, 2-(ethylamino)ethanol, propylaminoethanol, diethylene glycolamine (DEGA), N,N′-bis(2-hydroxyethyl)ethylenediamine, 1,2-bis(2-aminoethoxy)ethane, N-tert-butyldiethanolamine, N-butyldiethanolamine, N-methyldiethanolamine, 1-piperidineethanol, and 1-(2-hydroxyethyl)piperazine.

Among these, Tris, DMAMP, AMP, AMPDO, AEPDO, 2-APDO, 3-APDO, or MAPDO is preferable, and Tris or DMAMP is more preferable.

### <Alicyclic Amine>

Examples of the tertiary alicyclic amine include a cyclic amidine compound and a piperazine compound. It is noted that a compound included in the alkanolamine is not included in the alicyclic amine.

The cyclic amidine compound is a compound having a heterocyclic ring including an amidine structure (>N—C═N—) in the ring. The number of ring members in the above-described heterocyclic ring contained in the cyclic amidine compound is preferably 5 or 6 and more preferably 6.

Examples of the cyclic amidine compound include diazabicycloundecene (1,8-diazabicyclo[5.4.0]undeca-7-ene: DBU), diazabicyclononene (1,5-diazabicyclo[4.3.0]nona-5-ene: DBN), 3,4,6,7,8,9,10,11-octahydro-2H-pyrimid[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimid[1.2-a]azepine, and creatinine.

The piperazine compound is a compound having a hetero-6-membered ring (a piperazine ring) in which an opposite >CH— group of a cyclohexane ring is replaced with a tertiary amino group (>N—).

Examples of the piperazine compound include piperazine, 1-methylpiperazine, 2-methylpiperazine, 1-ethylpiperazine, 1-propylpiperazine, 1-butylpiperazine, 1,4-dimethylpiperazine, 2,5-dimethylpiperazine, 2,6-dimethylpiperazine, 1-phenylpiperazine, N-(2-aminoethyl)piperazine (AEP), 1,4-bis(2-aminoethyl)piperazine (BAEP), 1,4-bis(3-aminopropyl)piperazine (BAPP), and 1,4-diazabicyclo[2.2.2]octane (DABCO).

Examples of the alicyclic amine other than the piperazine compound and the cyclic amidine compound include a compound having a nitrogen-containing 5-membered ring such as 1,3-dimethyl-2-imidazolidinone, or having a nitrogen-containing 7-membered ring.

### <Aliphatic Amine>

Examples of the aliphatic amine other than the alkanolamine and the alicyclic amine include a primary aliphatic amine (an aliphatic amine having a primary amino group), a secondary aliphatic amine (an aliphatic amine having a secondary amino group), and a tertiary aliphatic amine (an aliphatic amine having a tertiary amino group).

Examples of the primary aliphatic amine include methylamine, ethylamine, propylamine, dimethylamine, diethylamine, n-butylamine, 3-methoxypropylamine, tert-butylamine, n-hexylamine, n-octylamine, and 2-ethylhexylamine.

Examples of the secondary aliphatic amine include alkylenediamines such as ethylenediamine (EDA), 1,3-propanediamine (PDA), 1,2-propanediamine, 1,3-butanediamine, and 1,4-butanediamine; and polyalkylpolyamines such as diethylenetriamine (DETA), triethylenetetramine (TETA), bis(aminopropyl)ethylenediamine (BAPEDA), and tetraethylenepentamine.

Examples of the tertiary aliphatic amine include a tertiary alkylamine such as trimethylamine or triethylamine; an alkylenediamine such as 1,3-bis(dimethylamino)butane; and a polyalkylpolyamine such as N,N,N′,N″,N″-pentamethyldiethylenetriamine.

### <Quaternary Ammonium Compound>

The quaternary ammonium compound is not particularly limited as long as it is a compound having at least one quaternary ammonium cationic group in which the nitrogen atom is substituted with four hydrocarbon groups (preferably an alkyl group), or a salt thereof.

Examples of the quaternary ammonium compound include a quaternary ammonium hydroxide, a quaternary ammonium fluoride, a quaternary ammonium bromide, a quaternary ammonium iodide, a quaternary ammonium acetate, and a quaternary ammonium carbonate.

Among these, a quaternary ammonium hydroxide is preferable, and a compound represented by Formula (a1) is more preferable.

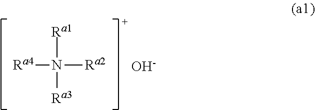

In Formula (a1), R^{a1} to R^{a4} each independently represent an alkyl group having 1 to 16 carbon atoms, an aryl group having 6 to 16 carbon atoms, an aralkyl group having 7 to 16 carbon atoms, or a hydroxyalkyl group having 1 to 16 carbon atoms. At least two of R^{a1} to R^{a4} may be bonded to each other to form a cyclic structure.

From the viewpoint of ease of availability, the compound represented by Formula (a1) is preferably a compound selected from the group consisting of tetramethylammonium hydroxide (TMAH), tetraethylammonium hydroxide (TEAH), tetrapropylammonium hydroxide, tetrabutylammonium hydroxide (TBAH), methyltripropylammonium hydroxide, methyltributylammonium hydroxide, ethyltrimethylammonium hydroxide, dimethyldiethylammonium hydroxide, benzyltrimethylammonium hydroxide (BzTMAH), hexadecyltrimethylammonium hydroxide, (2-hydroxyethyl)trimethylammonium, and spiro-(1,1′)-bipyrrolidinium hydroxide, and it is more preferably TMAH, TEAH, or TBAH.

In a case where the organic amine is a compound or a salt thereof, which has at least one group selected from the group consisting of a primary amino group, a secondary amino group, and a tertiary amino group, the acid dissociation constant of these organic amines is preferably 7.5 or more, more preferably 8.0 or more, and still more preferably 8.2 or more, from the viewpoint that the cleaning performance of the composition is more excellent. The upper limit thereof is not particularly limited; however, it is preferably 12.0 or less. Here, the acid dissociation constant (hereinafter, also referred to as “pKa”) means an acid dissociation constant of a conjugate acid of the organic amine, and it means the highest first acid dissociation constant in a case where a plurality of conjugate acids are present.

Examples of the organic amine having a pKa in the above-described range include TEA (pKa: 7.8), Tris (pKa: 8.3), DEA (pKa: 8.9), MEA (pKa: 9.5), N-MAMP (pKa: 9.7), AMP (pKa: 9.7), DMAMP (pKa: 10.2), DBU (pKa: 10.6), and DBN (pKa: 10.6).

The pKa of the organic amine is a value in water (temperature: 25° C.) that is calculated using Calculator Plugins (manufactured by Fujitsu Limited). It is noted that in a case where the measurement cannot be carried out in water, the value is a value that is calculated in dimethyl sulfoxide.

The organic amine is preferably a compound or a salt thereof, which has, in the molecule, at least one amino group selected from the group consisting of a primary amino group, a secondary amino group, and a tertiary amino group, and among the above, it is more preferably a compound or a salt thereof, which has the above-described amino group and has no carboxy group. In addition, it is more preferably a compound or a salt thereof, which has the above-described amino group but does not have a carbonyl group.

In addition, it is preferable that the organic amine does not contain an aromatic ring. The organic amine is still more preferably an alkanolamine, and particularly preferably the alkanolamine according to the above-described preferred aspect.

The organic amine may be used alone or in a combination of two or more kinds thereof.

The content of the organic amine is preferably 0.5% to 20% by mass and more preferably 0.7% to 15% by mass with respect to the total mass of the composition.

The content of the organic amine is preferably 25% to 70% by mass and more preferably 35% to 65% by mass with respect to the total solid content in the composition.

From the viewpoint that other performances are more excellent while reducing the number of defects, the ratio A/C of the content of the antibacterial agent to the content of the organic amine (content A of antibacterial agent/content C of organic amine) is preferably 0.3 or less, more preferably 0.2 or less, and still more preferably 0.03 or less in terms of mass ratio. The lower limit of the ratio A/C is not particularly limited; however, it is preferably 0.001 or more and more preferably 0.005 or more in terms of mass ratio, from the viewpoint that the effect of the present invention is more excellent.

### [Water]

The present composition contains water, and the content of water is 70% by mass or more with respect to the total mass of the present composition.

The kind of water is not particularly limited as long as it does not affect the semiconductor substrate, and distilled water, deionized water, and pure water (ultrapure water) can be used. Pure water is preferable from the viewpoint that it contains almost no impurities and has less influence on a semiconductor substrate in a manufacturing step of the semiconductor substrate.

From the viewpoint of further reducing contamination due to metal ions, the content of water in the composition is preferably 80% by mass or more and more preferably 85% by mass or more with respect to the total mass of the composition. The upper limit thereof is not particularly limited. However, it is, for example, 99% by mass or less, and it is preferably 95% by mass or less with respect to the total mass of the composition.

### [Optional Component]

The composition may contain other optional components in addition to the above-described components. Examples of the optional component include a chelating agent, an anticorrosive agent, a surfactant, and various additives.

The composition preferably contains at least one selected from the group consisting of a chelating agent, an anticorrosive agent, and a surfactant, and more preferably contains a chelating agent.

Hereinafter, the optional components will be described.

### <Chelating Agent>

The composition may contain a chelating agent, and it is preferable to contain a chelating agent.

The chelating agent is a compound having a function of chelating with a metal ion contained in residues such as polishing particles on the semiconductor substrate. Particularly, a compound having two or more functional groups (coordinating groups) which are coordinately bonded to a metal ion in one molecule is preferable.

Examples of the coordinating group contained in the chelating agent include an acid group and a cationic group. Examples of the acid group include a carboxy group, a phosphonate group, a phosphate group, a sulfo group, and a hydroxy group. Examples of the cationic group include an amino group.

Examples of the chelating agent include a phosphonic acid-based chelating agent having at least one phosphonate group as a coordinating group and an amine-based chelating agent having at least one amino group as a coordinating group. It is noted that the chelating agent having a phosphonate group and an amino group is included in the phosphonate group but is not included in the amine-based chelating agent.

The number of carbon atoms of the chelating agent is preferably 15 or less, more preferably 12 or less, and still more preferably 9 or less. The lower limit thereof is not particularly limited; however, it is preferably 2 or more.

### (Phosphonic Acid-Based Chelating Agent)

The phosphonic acid-based chelating agent is a chelating agent having at least one phosphonate group in the molecule. The number of phosphonate groups contained in the phosphonic acid-based chelating agent is preferably 2 to 5, more preferably 2, 4, or 5, and still more preferably 2 or 5.

The phosphonic acid-based chelating agent may have a coordinating group in addition to the phosphonate group. In a case where the phosphonic acid-based chelating agent has an amino group as a coordinating group, the number of amino groups is preferably 1 to 4, and more preferably 2 or 3.

The phosphonic acid-based chelating agent preferably has 15 or less carbon atoms, more preferably has 12 or less carbon atoms, and still more preferably 8 or less carbon atoms. The lower limit thereof is not particularly limited; however, it is preferably 3 or more.

Examples of the phosphonic acid-based chelating agent include ethylidene diphosphonic acid, 1-hydroxyethylidene-1,1′-diphosphonic acid (HEDPO), 1-hydroxypropyridene-1,1′-diphosphonic acid, and 1-hydroxybutylidene-1,1′-diphosphonic acid, ethylaminobis(methylenephosphonic acid), dodecylaminobis(methylenephosphonic acid), nitrilotris(methylenephosphonic acid) (NTPO), ethylenediaminebis(methylenephosphonic acid) (EDDPO), 1,3-propylenediaminebis(methylenephosphonic acid), ethylenediaminetetra(methylenephosphonic acid) (EDTPO), ethylenediaminetetra(ethylenephosphonic acid), 1,3-propylenediaminetetra(methylenephosphonic acid) (PDTMP), 1,2-diaminopropanetetra(methylenephosphonic acid), 1,6-hexamethylenediaminetetra(methylenephosphonic acid), diethylenetriaminepenta(methylenephosphonic acid) (DEPPO), diethylenetriaminepenta(ethylenephosphonic acid), triethylenetetraminehexa(methylenephosphonic acid), and triethylenetetraminehexa(ethylenephosphonic acid).

In addition, as the phosphonic acid-based chelating agent, the compounds described in paragraphs [0026] to [0036] of WO2018/020878A, and the compounds ((co)polymers) described in paragraphs [0031] to [0046] of WO2018/030006A can be adopted, the contents of which are incorporated in the present specification by reference.

The phosphonic acid-based chelating agent is preferably HEDPO, NTPO, EDTPO, or DEPPO, and more preferably HEDPO or DEPPO.

### (Amine-Based Chelating Agent)

The amine-based chelating agent is a chelating agent having at least one amino group in the molecule. The number of amino groups contained in the amine-based chelating agent is preferably 2 to 5, and more preferably 2 to 4.

The amine-based chelating agent preferably has, as a coordinating group, at least one carboxy group in addition to the amino group. In a case where the amine-based chelating agent has a carboxy group as the coordinating group, the number of carboxy groups is preferably 1 to 5.

The number of carbon atoms of the amine-based chelating agent is preferably 15 or less, more preferably 12 or less, and still more preferably 10 or less. The lower limit thereof is not particularly limited; however, it is preferably 3 or more.

Examples of the amine-based chelating agent include an amino polycarboxylic acid-based chelating agent and an amino acid-based chelating agent.

Examples of the amino polycarboxylic acid-based chelating agent include butylenediaminetetraacetic acid, diethylenetriaminepentaacetic acid (DTPA), ethylenediaminetetrapropionic acid, triethylenetetraminehexacetic acid (TTHA), 1,3-diamino-2-hydroxypropane-N,N,N′,N′-tetraacetic acid, propylenediaminetetraacetic acid, ethylenediaminetetraacetic acid (EDTA), trans-1,2-diaminocyclohexanetetraacetic acid (CyDTA), ethylenediaminediacetic acid (EDDA), ethylenediaminedipropionic acid, 1,6-hexamethylene-diamine-N,N,N′,N′-tetraacetic acid, N,N-bis(2-hydroxybenzyl)ethylenediamine-N,N-diacetic acid, diaminopropanetetraacetic acid, 1,4,7,10-tetraazacyclododecane-tetraacetic acid, diaminopropanoltetraacetic acid, hydroxyethyliminodiacetic acid (HIDA), (hydroxyethyl)ethylenediaminetriacetic acid (EDTA-OH), iminodiacetic acid (IDA), nitrilotriacetic acid (NTA), glycol ether diamine tetraacetic acid (GEDTA), and bis(hydroxyethyl)glycine (Bicine).

Among these, EDTA, EDDA, DTPA, TTHA, HIDA, GEDTA, EDTA-OH, IDA, NTA, Bicine, or CyDTA is preferable, and DTPA or EDTA is more preferable.

Examples of the amino acid-based chelating agent include glycine, serine, α-alanine (2-aminopropionic acid), β-alanine (3-aminopropionic acid), L-lysine, leucine, isoleucine, cystine, cysteine, ethionine, threonine, tryptophan, tyrosine, valine, histidine, a histidine derivative, asparagine, aspartic acid, glutamine, glutamic acid, L-arginine, proline, methionine, phenylalanine, the compounds described in paragraphs [0021] to [0023] of JP2016-086094A, and salts thereof.

It is noted that as the histidine derivative, the compounds described in JP2015-165561A, JP2015-165562A, and the like can be adopted, the contents of which are incorporated in the present specification by reference. In addition, examples of the salt include alkali metal salts such as a sodium salt and a potassium salt, an ammonium salt, a carbonate, and an acetate. The amino acid-based chelating agent is preferably L-lysine, L-arginine, L-histidine, L-ornithine, or L-tryptophan, and more preferably L-lysine or L-arginine.

In addition, as the amine-based chelating agent, at least one biguanide compound selected from the group consisting of a compound having a biguanide group and a salt thereof is also used.

The number of biguanide groups contained in the biguanide compound is not particularly limited and a plurality of biguanide groups can be contained therein.

Examples of the biguanide compound include the compounds described in paragraphs [0034] to [0055] of JP2017-504190A, the contents of which are incorporated in the present specification by reference.

### (Phosphoric Acid-Based Chelating Agent)

Examples of the phosphoric acid-based chelating agent include a fused phosphoric acid and a salt thereof, and an organic compound having two or more phosphate groups (phosphoric acid ester groups) (however, a compound that functions as a surfactant described later is excluded), and more specific examples thereof include pyrophosphoric acid, metaphosphoric acid, tripolyphosphate, tetrapolyphosphate, hexametaphosphoric acid, and phytic acid, as well as salts thereof.

The chelating agent is preferably a phosphonic acid-based chelating agent or an amine-based chelating agent, more preferably a phosphonic acid-based chelating agent or an amino polycarboxylic acid-based chelating agent, still more preferably a phosphonic acid-based chelating agent, and particularly preferably HEDPO or DEPPO.

The chelating agent may be used alone or in a combination of two or more kinds thereof.

In a case where the composition contains a chelating agent, the content of the chelating agent is preferably 0.1% to 10.0% by mass, and more preferably 0.4% to 5.0% by mass with respect to the total mass of the composition, from the viewpoint that the balance between the cleaning performance and the anticorrosion properties is more excellent.

In a case where the composition contains a chelating agent, the content of the chelating agent is preferably 10% to 50% by mass, and more preferably 20% to 40% by mass with respect to the total solid content of the composition for the same reason as described above.

### <Anticorrosive Agent>

The composition may contain an anticorrosive agent.

The anticorrosive agent may be any compound as long as it has a function of preventing corrosion of an exposed surface of a metal film (particularly, a metal film containing tungsten) included in the semiconductor substrate, and examples thereof include a heteroaromatic compound and a water-soluble polymer.

The heteroaromatic compound is not particularly limited as long as it is a compound having a heteroaromatic ring structure in the molecule; however, it is preferably a nitrogen-containing heteroaromatic compound in which at least one of heteroatoms constituting the heteroaromatic ring is a nitrogen atom.

Examples of the nitrogen-containing heteroaromatic compound include a purine compound, an azole compound, a pyridine compound, a pyrazine compound, and a pyrimidine compound. Among these, a purine compound or an azole compound is more preferable, and a purine compound is still more preferable.

### (Purine Compound)

The purine compound is a compound having a purine skeleton, and it is selected from the group consisting of purine and a purine derivative. In a case where the composition contains a purine compound, the anticorrosion properties are excellent, and the purine compound is unlikely to remain as a residue.

The purine compound preferably includes at least one selected from the group consisting of compounds represented by Formulae (B1) to (B4), more preferably includes at least one selected from the group consisting of a compound represented by Formula (B11), a compound represented by Formula (B2), and a compound represented by Formula (B4), and still more preferably includes at least one selected from the group consisting of the compound represented by Formula (B2).

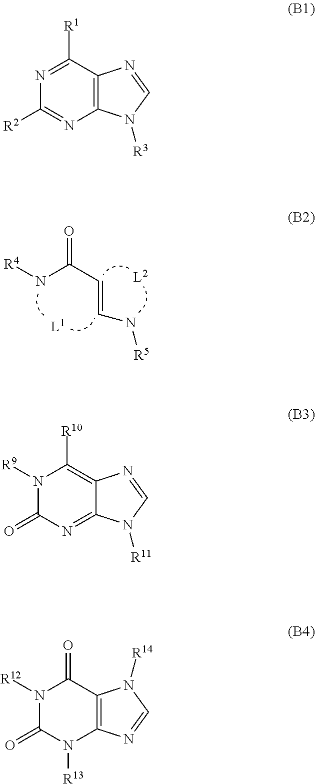

In Formula (B1), R¹ to R³ each independently represent a hydrogen atom, an alkyl group, an amino group, a thiol group, a hydroxyl group, a halogen atom, a sugar group, or a polyoxyalkylene group.

The alkyl group may be linear, branched, or cyclic. The alkyl group preferably has 1 to 10 carbon atoms, more preferably has 1 to 5 carbon atoms, and still more preferably has 1 to 3 carbon atoms.

Examples of the sugar group include a group obtained by removing one hydrogen atom from saccharides selected from the group consisting of monosaccharides, disaccharides, and polysaccharides, where a group obtained by removing one hydrogen atom from monosaccharides is preferable. Examples of the monosaccharides include a pentose such as ribose, deoxyribose, arabinose, or xylose, a triose, a tetrose, a hexose, and a heptose, where a pentose is preferable, ribose, deoxyribose, arabinose, or xylose is more preferable, and ribose or deoxyribose is still more preferable. Examples of the disaccharides include sucrose, lactose, maltose, trehalose, turanose, and cellobiose. Examples of the polysaccharides include glycogen, starch, and cellulose. The saccharides may be chain-like or cyclic, and they are preferably cyclic. Regarding the cyclic saccharides, examples of the ring include a furanose ring and a pyranose ring.

Examples of the polyoxyalkylene group include a polyoxyethylene group, a polyoxypropylene group, and a polyoxybutylene group, and a polyoxyethylene group is preferable.

The alkyl group, the amino group, the sugar group, and the polyoxyalkylene group may further have a substituent. Examples of the substituent include a hydrocarbon group such as an alkyl group; a halogen atom such as a fluorine atom, a chlorine atom, or a bromine atom; an alkoxy group; a hydroxyl group; an alkoxycarbonyl group such as a methoxycarbonyl group or an ethoxycarbonyl group; an acyl group such as an acetyl group, a propionyl group, or benzoyl group; and a cyano group; a nitro group.
R¹ is preferably a hydrogen atom or an amino group which may have a substituent, and more preferably a hydrogen atom. Another suitable aspect of R¹ is preferably a hydrogen atom, an alkyl group which may have a substituent, a thiol group, a hydroxyl group, a halogen atom, a sugar group which may have a substituent, or a polyoxyalkylene group which may have a substituent.
R² is preferably a hydrogen atom or an alkyl group which may have a substituent, and more preferably a hydrogen atom.
R³ is preferably a hydrogen atom, an alkyl group which may have a substituent, or a sugar group which may have a substituent, more preferably a hydrogen atom or an alkyl group which may have a substituent, and still more preferably a hydrogen atom.

In Formula (B2), L¹ represents —CR⁶═N— or —C(═O)—NR⁷—. L² represents —N═CH— or —NR⁸—C(═O)—. R⁴ to R⁸ each independently represent a hydrogen atom, an alkyl group, an amino group, a thiol group, a hydroxyl group, a halogen atom, a sugar group, or a polyoxyalkylene group.

Examples of R⁴ to R⁸ include groups represented by R¹ to R³ in Formula (B1).
R⁴ and R⁵ are preferably a hydrogen atom or an alkyl group which may have a substituent, and more preferably a hydrogen atom.
R⁶ is preferably a hydrogen atom, an alkyl group which may have a substituent, or an amino group which may have a substituent, more preferably a hydrogen atom or an amino group which may have a substituent, and still more preferably a hydrogen atom.
R⁷ is preferably a hydrogen atom or an alkyl group which may have a substituent, and more preferably a hydrogen atom.
L² is preferably —N═CH—.
R⁸ is preferably a hydrogen atom or an alkyl group which may have a substituent, and more preferably a hydrogen atom.

In Formula (B3), R⁹ to R¹¹ each independently represent a hydrogen atom, an alkyl group, an amino group, a thiol group, a hydroxyl group, a halogen atom, a sugar group, or a polyoxyalkylene group.

Examples of R⁹ to R¹¹ include groups represented by R¹ to R³ in Formula (B1).
R⁹ is preferably a hydrogen atom or an alkyl group which may have a substituent, and more preferably a hydrogen atom.
R¹⁰ is preferably a hydrogen atom, an alkyl group which may have a substituent, or an amino group which may have a substituent, more preferably a hydrogen atom or an amino group which may have a substituent, and still more preferably an amino group which may have a substituent.
R¹¹ is preferably a hydrogen atom or an alkyl group which may have a substituent, and more preferably a hydrogen atom.

In Formula (B4), R¹² to R¹⁴ each independently represent a hydrogen atom, an alkyl group, an amino group, a thiol group, a hydroxyl group, a halogen atom, a sugar group, or a polyoxyalkylene group.

Examples of R¹² to R¹⁴ include groups represented by R¹ to R³ in Formula (B1).
R¹² is preferably a hydrogen atom or an alkyl group which may have a substituent, and more preferably an alkyl group which may have a substituent.

Another suitable aspect of R¹² is preferably an alkyl group which may have a substituent, an amino group which may have a substituent, a thiol group, a hydroxyl group, a halogen atom, a sugar group which may have a substituent, or a polyoxyalkylene group which may have a substituent.
R¹³ is preferably a hydrogen atom or an alkyl group which may have a substituent, and more preferably an alkyl group which may have a substituent.
R¹⁴ is preferably a hydrogen atom or an alkyl group which may have a substituent.

Examples of the purine compound include purine or a derivative thereof, adenine or a derivative thereof, guanine or a derivative thereof, hypoxanthine or a derivative thereof, xanthine or a derivative thereof, xanthosine or a derivative thereof, and theobromine or a derivative thereof.

Examples of the purine or a derivative thereof include purine, 2-aminopurine, 2-amino-6-methoxypurine, 2-amino-6-iodopurine, 2-amino-6-chloropurine, 2,6-diaminopurine, 2,6-dichloropurine, 3,7-dihydro-7-methyl-1H-purine-2,6-dione, 6-aminopurine, 6-methoxypurine, 6-(dimethylamino)purine, 6-benzylaminopurine, 6-chloro-9-(tetrahydropyran-2-yl)purine, 6-amino-8-phenyl-9H-purine, 6-ethylaminopurine, and 8-azapurine.

Examples of the adenine or a derivative thereof include adenine, 1-methyladenine, 1-ethyladenine, 1-benzyladenine, 2-methyladenine, 2-chloroadenine, 2-fluoroadenine, 2-hydroxyadenine, 3-methyladenine, 8-aminoadenine, 9-methyladenine, 9-(2-hydroxyethyl)adenine, N-(2-hydroxyethyl)adenine, N-methyladenine, N,N-dimethyladenine, 2-azaadenine, 5-azaadenine, 8-azaadenine, N⁶-benzoyladenosine, and adenosine.

Examples of the guanine or a derivative thereof include guanine, N-methylguanine, N-acetylguanine, O-cyclohexylmethylguanine, 7-(2-hydroxyethyl)guanine, N-(3-chlorophenyl)guanine, N-(3-ethylphenyl)guanine, 8-azaguanine, guanine oxime, 2′-deoxyguanosine, disodium guanosine 5′-monophosphate, and N²-isobutyryl-2′-deoxyguanosine.

Examples of the hypoxanthine or a derivative thereof include hypoxanthine and 8-azahypoxanthine.

Examples of the xanthine or a derivative thereof include xanthine, 1-methylxanthine, 1-butyl-3,7-dimethylxanthine, 1-methyl-3,7-dipropylxanthine, 1,3-dipropyl-7-methylxanthine, 1,3-dipropyl-7-methyl-8-dicyclopropylmethylxanthine, 1,3-dibutyl-7-(2-oxopropyl)xanthine, 1,7-dimethylxanthine, 1,7-dipropyl-3-methylxanthine, 3-methylxanthine, 3,7-dimethyl-1-propylxanthine, 7-methylxanthine, 8-bromo-3-methylxanthine, 8-azaxanthine, 2-thioxanthine, and paraxanthine.

Examples of the xanthosine or a derivative thereof include xanthosine and 7-methylxanthosine.

Examples of the theobromine or a derivative thereof include theobromine and 1-(3-chloropropyl)theobromine.

Examples of the purine compound other than those described above include caffeine, uric acid, isoguanine, enprofylline, theophylline-7-acetic acid, theophylline, 7-(2,3-dihydroxypropyl)theophylline, 7-(2-chloroethyl)theophylline, 8-chlorotheophylline, eritadenine, nelarabine, vidarabine, aciclovir, trans-zeatin, entecavir, valaciclovir, abacavir, disodium inosinate, ganciclovir, β-nicotinamide adenine dinucleotide phosphate, clofarabine, kinetin, proxyphylline, 2′,3′-dideoxyinosine, penciclovir, adefovir dipivoxil, and inosine.

The purine compound more preferably includes at least one selected from the group consisting of purine, adenine, guanine, hypoxanthine, xanthine, theobromine, caffeine, uric acid, isoguanine, adenosine, enprofylline, theophylline, xanthosine, 7-methylxanthosine, 7-methylxanthine, eritadenine, 3-methyladenine, 3-methylxanthine, 1,7-dimethylxanthine, 1-methylxanthine, and paraxanthine, and it particularly preferably includes at least one selected from the group consisting of xanthine, hypoxanthine, and adenine.

### (Azole Compound)

The azole compound is a compound that has a hetero 5-membered ring containing one or more nitrogen atoms and has aromaticity.

The number of nitrogen atoms contained in the hetero 5-membered ring of the azole compound is preferably 1 to 4 and more preferably 1 to 3.

The azole compound may have a substituent on the hetero 5-membered ring. Examples of the substituent include a hydroxyl group, a carboxy group, a mercapto group, an amino group, an alkyl group having 1 to 4 carbon atoms, which may have an amino group, and a 2-imidazolyl group.

Examples of the azole compound include an imidazole compound in which one of the atoms constituting the azole ring is a nitrogen atom, a pyrazole compound in which two of the atoms constituting an azole ring are nitrogen atoms, and a thiazole compound in which one of the atoms constituting an azole ring is a nitrogen atom and the other is a sulfur atom, a triazole compound in which three of the atoms constituting an azole ring are nitrogen atoms, and a tetrazole compound in which four of the atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, and benzimidazole.

Examples of the pyrazole compound include 2,4-dimethylthiazole, benzothiazole, and 2-mercaptobenzothiazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, 5-methylbenzotriazole, and 2,2′-{[(5-methyl-1H-benzotriazole-1-yl)methyl]imino}diethanol. Among these, benzotriazole is preferable.

Examples of the tetrazole compound include 1H-tetrazole (1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

The pyridine compound is a compound having a hetero-6-membered ring (pyridine ring) that includes one nitrogen atom and has aromaticity.

Examples of the pyridine compound include pyridine, 3-aminopyridine, 4-aminopyridine, 3-hydroxypyridine, 4-hydroxypyridine, 2-acetamidopyridine, 2-cyanopyridine, 2-carboxypyridine, and 4-carboxypyridine.

The pyrazine compound is a compound having aromaticity and having a hetero-6-membered ring (pyrazine ring) including two nitrogen atoms located at the para positions, and the pyrimidine compound is a compound having aromaticity and having a hetero-6-membered ring (pyrimidine ring) including two nitrogen atoms located at the meta positions.

Examples of the pyrazine compound include pyrazine, 2-methylpyrazine, 2,5-dimethylpyrazine, 2,3,5-trimethylpyrazine, 2,3,5,6-tetramethylpyrazine, 2-ethyl-3-methylpyrazine, and 2-amino-5-methylpyrazine.

Examples of the pyrimidine compound include pyrimidine, 2-methylpyrimidine, 2-aminopyrimidine, and 4,6-dimethylpyrimidine.

### (Water-Soluble Polymer)

The water-soluble polymer is a water-soluble compound having a weight-average molecular weight of 1,000 or more.

In the present specification, the term “water-soluble” means that a mass dissolved in 100 g of water at 20° C. is 0.1 g or more.

The water-soluble polymer does not include a compound that functions as an anionic surfactant described later.

Examples of the water-soluble polymer include polyvinyl alcohol, hydroxyethyl cellulose, polyvinyl pyrrolidone, poly(meth)acrylic acid, poly(meth)acrylamide, polystyrenesulfonic acid, polymaleic acid, polyvinyl sulfonic acid, polyallyl sulfonic acid, and a copolymer of a monomer having an acid group (for example, a (meth)acrylic acid monomer and a monomer having a sulfonate group and a polymerizable ethylene group), as well as salts thereof.

Examples of the water-soluble polymer also include the compounds described in paragraphs [0043] to [0047] of JP2016-171294A, the contents of which are incorporated in the present specification.

The water-soluble polymer may be ionized in the composition.

The weight-average molecular weight of the water-soluble polymer is preferably 1,000 to 100,000, more preferably 2,000 to 50,000, and still more preferably 5,000 to 50,000.

The water-soluble polymer may be used alone or in a combination of two or more kinds thereof.

In a case where the composition contains a water-soluble polymer, the content of the water-soluble polymer in the composition is preferably 2% by mass or less, more preferably 1% by mass or less, still more preferably 0.5% by mass or less, particularly preferably 0.2% by mass or less, and most preferably 0.04% by mass or less with respect to the total mass of the composition. This is because in a case where the content of the water-soluble polymer is in the above-described range, the viscosity of the composition is reduced, and the effect of the present invention and the effect of suppressing the occurrence of defects in an object to be subjected to application in a case of being used immediately after production are further improved. The lower limit value of the content of the water-soluble polymer is not particularly limited and may be 0% by mass. In a case where the composition contains a water-soluble polymer, the content of the water-soluble polymer is preferably 0.0001% by mass or more with respect to the total mass of the composition.

In addition, in a case where the composition contains a water-soluble polymer, the content of the water-soluble polymer with respect to the total solid content of the composition is, for example, 50% by mass or less, and for the same reason as described above, it is preferably 30% by mass or less, more preferably 20% by mass or less, still more preferably 12% by mass or less, particularly preferably 6% by mass or less, and most preferably 3% by mass or less. The lower limit value of the content of the water-soluble polymer with respect to the total solid content of the composition is not particularly limited and may be 0% by mass. In a case where the composition contains a water-soluble polymer, the content of the water-soluble polymer with respect to the total solid content of the composition is preferably 0.1% by mass or more.

The composition may contain another anticorrosive agent excluding the above-described respective components.

Examples of the other anticorrosive agent include an ascorbic acid compound, a catechol compound, a hydrazide compound, a reducing sulfur compound, sugars (such as fructose, glucose, and ribose), polyols (such as ethylene glycol, propylene glycol, and glycerin), a multimer of polyols such as a polyglycerin (however, the above-described water-soluble polymer and a nonionic surfactant described later are excluded), polyvinyl pyrrolidone, phenanthroline, flavonol and a derivative thereof, as well as anthocyanin and a derivative thereof.

In addition, examples of the other anticorrosive agent include (2Z,2′Z)-3,3′-disulfanediylbis(N-methylacrylamide) (DSBMA), (2Z,2′Z)-3,3′-disulfanediylbis(N-octylacrylamide) (DSBOA), and 2,2′-disulfanedyldibenzamide (DSDBA).

In the composition, the ratio of the total content of DSBMA, DSBOA, and DSDBA to the content of the antibacterial agent is preferably 0.01 to 0.10 and more preferably 0.01 to 0.05.

The anticorrosive agent is preferably a heteroaromatic compound or a water-soluble polymer, more preferably a heteroaromatic compound, and still more preferably a purine compound.

The anticorrosive agent may be used alone or in a combination of two or more kinds thereof.

In a case where the composition contains an anticorrosive agent, the content of the anticorrosive agent is preferably 0.0001% to 10% by mass, and more preferably 0.001% to 3% by mass with respect to the total mass of the composition.

In a case where the composition contains an anticorrosive agent, the content of the anticorrosive agent is preferably 0.001% to 30% by mass, and more preferably 0.01% to 10% by mass with respect to the total solid content of the composition.

It is noted that as these anticorrosive agents, commercially available ones may be used, or those synthesized according to publicly known methods may be used.

### <Surfactant>

The composition may contain a surfactant.

The surfactant is a compound having a hydrophilic group and a hydrophobic group (lipophilic group) in one molecule. Examples of the surfactant include a nonionic surfactant, an anionic surfactant, and an amphoteric surfactant.

From the viewpoint that the corrosion prevention performance of the metal film and the removability of residues such as polishing abrasive grains are more excellent, the composition preferably contains a surfactant.

In a large number of cases, the surfactant has at least one hydrophobic group selected from the group consisting of an aliphatic hydrocarbon group, an aromatic hydrocarbon group, and a group obtained by combining these.

In a case where the hydrophobic group includes an aromatic hydrocarbon group, the hydrophobic group contained in the surfactant preferably has 6 or more carbon atoms and more preferably has 10 or more carbon atoms. In a case where the hydrophobic group does not include an aromatic hydrocarbon group but consists only of an aliphatic hydrocarbon group, the hydrophobic group contained in the surfactant preferably has 9 or more carbon atoms, more preferably has 13 or more carbon atoms, and still more preferably has 16 or more carbon atoms. The upper limit of the number of carbon atoms in the hydrophobic group is preferably 20 or less and more preferably 18 or less.

The total number of carbon atoms of the surfactant is preferably 16 to 100.

Examples of the nonionic surfactant include an ester-type nonionic surfactant, an ether-type nonionic surfactant, an ester-ether-type nonionic surfactant, and an alkanolamine-type nonionic surfactant, where an ether-type nonionic surfactant is preferable.

Examples of the nonionic surfactant include polyethylene glycol, an alkyl polyglucoside (Triton BG-10 and Triton CG-110 surfactants, manufactured by The Dow Chemical Company), octylphenol ethoxylate (Triton X-114, manufactured by The Dow Chemical Company), a silane polyalkylene oxide (copolymer) (Y-17112-SGS sample, manufactured by Momentive Performance Materials, Inc.), nonylphenol ethoxylate (Tergitol NP-12 and Triton (registered trademark) X-102, X-100, X-45, X-15, BG-10, and CG-119, manufactured by The Dow Chemical Company), Silwet (registered trademark) HS-312 (manufactured by Momentive Performance Materials, Inc.), tristyrylphenol ethoxylate (MAKON TSP-20, manufactured by Stepan Company), a polyoxyethylene alkyl ether, a polyoxyethylene alkyl phenyl ether, an alkyl allyl formaldehyde-fused polyoxyethylene ether, a polyoxyethylene polyoxypropylene block polymer, a polyoxyethylene polyoxypropylene alkyl ether, a polyoxyethylene ether of a glycerol ester, a polyoxyethylene ether of a sorbitan ester, a polyoxyethylene ester of a glycerin ester, a polyethylene glycol fatty acid ester, a glycerin ester, a polyglycerin ester, a sorbitan ester, a propylene glycol ester, a sucrose ester, an aliphatic acid alkanolamide, a polyoxyethylene fatty acid amide, a polyoxyethylene alkyl amide, an alcohol ethoxylate such as BRIJ (registered trademark) 56 (C₁₆H₃₃(OCH₂CH₂)₁₀OH), BRIJ (registered trademark) 58 (C₁₆H₃₃(OCH₂CH₂)₂₀OH), or BRIJ (registered trademark) 35 (C₁₂H₂₅(OCH₂CH₂)₂₃OH), an alcohol (primary and secondary) ethoxylate, an amine ethoxylate, a glucoside, a glucamide, polyethylene glycol, poly(ethylene glycol-co-propylene glycol), cetyl alcohol, stearyl alcohol, cetostearyl alcohol (cetyl and stearyl alcohol), oleyl alcohol, octaethylene glycol monododecyl ether, pentaethylene glycol monododecyl ether, a polyoxypropylene glycol alkyl ether, decyl glucoside, lauryl glucoside, octyl glucoside, polyoxyethylene glycol octyl phenyl ether, nonoxynol-9, a glycerol alkyl ester, glyceryl laurate, a polyoxyethylene glycol sorbitan alkyl ester, polysorbate, a sorbitan alkyl ester, Span, cocamide MEA, cocamide DEA, dodecyl dimethylamine oxide, and a block copolymer of polypropylene glycol, as well as a mixture thereof

Examples of the anionic surfactant include, as a hydrophilic group (an acid group), a phosphoric acid ester-based surfactant having a phosphoric acid ester group, a phosphonic acid-based surfactant having a phosphonate group, a sulfonic acid-based surfactant having a sulfo group, a carboxylic acid-based surfactant having a carboxy group, and a sulfuric acid ester-based surfactant having a sulfuric acid ester group.

Examples of the anionic surfactant include alkylbenzenesulfonic acids such as dodecylbenzenesulfonic acid and ammonium dodecylbenzene sulfonate and salts thereof, alkylnaphthalenesulfonic acids such as propylnaphthalenesulfonic acid and triisopropylnaphthalenesulfonic acid and salts thereof, alkylphenyl ether disulfonic acids such as dodecylphenyl ether disulfonic acid and an alkyldiphenyl ether sulfonic acid and salts thereof; alkyldiphenyl ether disulfonic acids such as dodecyldiphenyl ether disulfonic acid and ammonium dodecyldiphenyl ether sulfonate and salts thereof, phenol sulfonic acid-formalin condensates and salts thereof, arylphenol sulfonic acid-formalin condensates and salts thereof; carboxylates such as decanecarboxylic acid, an N-acylamino acid salt and a polyoxyethylene or polyoxypropylene alkyl ether carboxylate; acylated peptides; sulfonates; sulfate esters such as a sulfated oil, an alkyl sulfate, an alkyl ether sulfate, sulfate ester salts such as a polyoxyethylene or polyoxypropylene alkylallyl ether sulfate and an alkylamide sulfate; phosphate ester salts; alkyl phosphates; polyoxyethylene or polyoxypropylene alkylallyl ether phosphates; ammonium lauryl sulfate; sodium lauryl sulfate (sodium dodecyl sulfate); sodium lauryl ether sulfate (SLES); sodium myreth sulfate; sodium dioctyl sulfosuccinate; octane sulfonate; perfluorooctanesulfonate (PFOS); perfluorobutane sulfonate; alkylbenzene sulfonates; alkylaryl ether phosphates; alkyl ether phosphates; alkyl carboxylates; fatty acid salts (soap); sodium stearate; sodium lauroyl sarcosinate; perfluorononanoate; perfluorooctanoate; and mixtures thereof.

Examples of the amphoteric surfactant include a carboxybetaine-type amphoteric surfactant, a sulfobetaine-type amphoteric surfactant, an aminocarboxylate, imidazolinium betaine, lecithin, an alkylamine oxide, and mixture thereof.

Examples of the surfactant include the compounds described in paragraphs [0092] to [0096] of JP2015-158662A, paragraphs [0045] and [0046] of JP2012-151273A, and paragraphs [0014] to [0020] of JP2009-147389A, the contents of which are incorporated in the present specification.

The surfactant may be used alone or in a combination of two or more kinds thereof.

In a case where the composition contains a surfactant, the content of the surfactant is preferably 0.001% to 8.0% by mass, and more preferably 0.005% to 5.0% by mass with respect to the total mass of the composition, from the viewpoint that the performance of the composition is excellent in a well-balanced manner.

From the viewpoint that the performance of the composition is excellent in a well-balanced manner, the content of the surfactant is preferably 0.01% to 50.0% by mass, and more preferably 0.1% to 45.0% by mass with respect to the total solid content in the composition.

### <Additive>

The composition may contain other components as an additive.

Examples of the other components include an oxidizing agent, a polyhydroxy compound having a molecular weight of 500 or more, a pH adjusting agent, a fluorine compound, and an organic solvent.

Examples of the oxidizing agent include a peroxide, a persulfide (for example, a monopersulfide or a dipersulfide), a percarbonate, or an acid thereof or a salt thereof.

Examples of the oxidizing agent include an oxidative halide (a periodic acid such as iodic acid, metaperiodic acid, or orthoperiodic acid, or a salt thereof), a perboric acid, a perboric acid salt, a cerium compound, and a ferricyanide (potassium ferricyanide or the like).

In a case where the composition contains an oxidizing agent, the content of the oxidizing agent is preferably 0.01% to 10.0% by mass and more preferably 0.05% to 5.0% by mass with respect to the total mass of the composition.

In a case where the composition contains an oxidizing agent, the content of the oxidizing agent is preferably 0.1% to 50.0% by mass, and more preferably 1.0% to 30.0% by mass with respect to the total solid content in the composition.

The polyhydroxy compound is an organic compound which has two or more (for example, 2 to 200) alcoholic hydroxyl groups in one molecule and is different from the above-described components.

The molecular weight (the weight-average molecular weight in a case of having a molecular weight distribution) of the polyhydroxy compound is 500 or more, and it is preferably 500 to 100,000 and more preferably 500 to 3,000.

Examples of the polyhydroxy compound include polyoxyalkylene glycols such as polyethylene glycol, polypropylene glycol, and polyoxyethylene polyoxypropylene glycol; oligosaccharides such as manninotriose, cellotriose, gentianose, raffinose, melezitose, cellotetrose, stachyose, and cyclodextrin; and polysaccharides such as starch, glycogen, cellulose, chitin, and chitosan, and hydrolysates thereof.

Examples of the cyclodextrin include α-cyclodextrin, β-cyclodextrin, and γ-cyclodextrin.

The polyhydroxy compound may be used alone or in a combination of two or more kinds thereof.

In a case where the composition contains a polyhydroxy compound, the content of the polyhydroxy compound is preferably 0.01% to 10.0% by mass, and more preferably 0.05% to 5.0% by mass with respect to the total mass of the composition.

In a case where the composition contains a polyhydroxy compound, the content of the polyhydroxy compound is preferably 0.01% to 30.0% by mass, and more preferably 0.05% to 25.0% by mass with respect to the solid content in the composition.

Examples of the pH adjusting agent include a basic compound and an acidic compound, which are different from the above-described components. However, it is permissible to adjust the pH of the composition by adjusting the adding amount of each of the above-described components.

Examples of the acidic compound among the pH adjusting agents include sulfuric acid and nitric acid, and examples of the basic compound include potassium hydroxide and ammonia. Among these, sulfuric acid or potassium hydroxide is preferable.

Examples of the pH adjusting agent also include those described in paragraphs [0053] and [0054] of WO2019-151141A and paragraphs [0021] of WO2019-151001A, the contents of which are incorporated in the present specification.

The pH adjusting agent may be used alone or in a combination of two or more kinds thereof.

In a case where the composition contains a pH adjusting agent, the content of the pH adjusting agent is adjusted according to the kind and amount of other components and the pH of the composition to be obtained.

Examples of the fluorine compound include the compounds described in paragraphs [0013] to [0015] of JP2005-150236A, the contents of which are incorporated in the present specification.

The content of the fluorine compound and the organic solvent may be appropriately set within a range where the effect of the present invention is not impaired.

As the organic solvent, a publicly known organic solvent can be used, and examples thereof include an alcohol (preferably a monohydric alcohol), a ketone, a dialkyl sulfoxide, and a cyclic sulfone. The organic solvent may be used alone or in a combination of two or more kinds thereof.

In a case where the composition contains an organic solvent, the content of the organic solvent is preferably 1.0% to 29% by mass, and more preferably 2.0% to 26% by mass with respect to the total mass of the composition.

The content of each of the components in the composition can be measured by a publicly known method such as gas chromatography-mass spectrometry (GC-MS) or liquid chromatography-mass spectrometry (LC-MS), and ion-exchange chromatography (IC).

### [Physical Properties of Composition]

<pH>

The pH of the composition according to the embodiment of the present invention is 4.0 to 9.0 at 25° C.

The pH of the composition is preferably 5.0 to 7.0, and more preferably 5.5 to 7.0.

The pH of the composition can be measured by a method in accordance with JIS Z8802-1984 using a publicly known pH meter. The temperature for measurement of pH is 25° C.

The pH of the composition can be adjusted by using the above-described pH adjusting agent, and a component having a function of a pH adjusting agent, such as the above-described organic acid, organic amine, or anionic surfactant.

### <Electric Conductivity>

The electric conductivity of the present composition is not particularly limited; however, it is preferably 0.05 to 2.5 S/m, more preferably 0.1 to 2.0 S/m, and still more preferably 0.2 to 1.5 S/m, from the viewpoint that the removability of particle residues is more excellent.

The electric conductivity of the composition is an electric conductivity (S/m) at 25° C., which is measured using a conductivity meter (for example, “WM-32EP”, manufactured by DKK-TOA CORPORATION).

The electric conductivity of the composition can be adjusted by the content of the component which can be ionized in the composition, such as the above-described organic acid and organic amine.

### <Metal Content>

In the composition, the content (measured as an ion concentration) of each metal (metal element of Fe, Co, Na, Cu, Mg, Mn, Li, Al, Cr, Ni, Zn, Sn, and Ag) contained as an impurity in the liquid is preferably 5 ppm by mass or less, and more preferably 1 ppm by mass or less. It is assumed that a composition having a higher purity is demanded in the manufacturing of the most advanced semiconductor element. Therefore, the metal content is still more preferably a value of less than 1 ppm by mass, that is, a content in terms of the order of ppb by mass or less, and particularly preferably 100 ppb by mass or less, and most preferably less than 10 ppb by mass. The lower limit thereof is preferably 0.

Examples of the method for reducing the metal content include carrying out a purifying treatment such as distillation and filtration using an ion exchange resin or a filter at a stage of raw materials used in the production of the composition or a stage after the production of the composition.

Other examples of the method for reducing the metal content include using a container with less elution of impurities, which will be described later, as a container that accommodates the raw material or the produced composition. In addition, other examples thereof include lining an inner wall of the pipe with a fluororesin to prevent the elution of metal components from a pipe or the like during the production of the composition.

### <Silicon Content>

In the composition, the content of silicon contained as an impurity in the liquid (measured as an ion concentration) is preferably 100 ppb by mass or less, and more preferably 50 ppb by mass or less, from the viewpoint of reducing the number of particles detected by a liquid particle counter (LPC). It is still more preferably 30 ppb by mass or less and most preferably less than 10 ppb by mass since it is assumed that a composition having a higher purity is demanded in the manufacturing of the most advanced semiconductor element. The lower limit thereof is preferably 0.

Examples of the method for reducing the silicon content include carrying out a purifying treatment such as distillation and filtration using an ion exchange resin or a filter at a stage of raw materials used in the production of the composition or a stage after the production of the composition.

Other examples of the method for reducing the silicon content include using a container with less elution of impurities, which will be described later, as a container that accommodates a raw material or the produced composition.

### <Coarse Particle>

The cleaning liquid may include coarse particles; however, the content thereof is preferably low.

The coarse particles mean particles having a diameter (particle diameter) of 0.03 μm or more in a case where the shape of the particles is regarded as a sphere.

As for the content of the coarse particles in the composition, the content of the particles having a particle diameter of 0.1 μm or more is preferably 10,000 or less, and more preferably 5,000 or less per 1 mL of the composition. The lower limit thereof is preferably 0 or more and more preferably 0.01 or more per 1 mL of the composition.

The coarse particles contained in the composition correspond to particles of dirt, dust, organic solids, inorganic solids, and the like contained as impurities in raw materials, and particles of dirt, dust, organic solids, and inorganic solids brought in as contaminants during the preparation of the composition, in which the particles are finally present as particles without being dissolved in the composition.

The content of the coarse particles present in the composition can be measured in a liquid phase by using a commercially available measuring device in a light scattering type liquid particle measuring method using a laser as a light source.

Examples of the method for removing the coarse particles include a purification treatment such as filtering which will be described later.

[Production of Composition]

The composition can be produced by a publicly known method. Hereinafter, the production method for the composition will be described in detail.

### <Preparing Step>

Regarding the preparation method for the composition, the composition can be prepared, for example, by mixing the above-described components.

Examples thereof include, regarding the order and/or timing of mixing the respective components, a method of sequentially adding, to a container into which purified pure water is put, an antibacterial agent, an organic acid, an organic amine as necessary, and optional components such as a chelating agent and an anticorrosive agent, and then mixing the resultant mixture with stirring and concurrently adding at least one of an organic amine or a pH adjusting agent to adjust the pH of the mixed liquid, thereby preparing the composition. In addition, in a case where water and the respective components are added to the container, they may be added collectively or dividedly a plurality of times.

As a stirring device and a stirring method, which are used in the preparation of the composition, a known device may be used as a stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and a bead mill.

Mixing of the respective components in the composition preparing step and a purification treatment described later, as well as the storage of the produced composition are preferably carried out at 40° C. or lower and more preferably carried out at 30° C. or lower. In addition, the lower limit thereof is preferably 5° C. or higher, and more preferably 10° C. or higher. In a case of preparing, treating, and/or storing the composition in the temperature range, it is possible to maintain stable performance for a long period of time.

### <Purification Treatment>

It is preferable to subject any one or more of the raw materials for preparing the composition to a purification treatment in advance. Examples of the purification treatment include publicly known methods such as distillation, ion exchange, and filtration (filtering).

Regarding the degree of purification, it is preferable to carry out the purification until the purity of the raw material is 99% by mass or more, and it is more preferable to carry out the purification until the purity of the stock solution is 99.9% by mass or more. The upper limit thereof is preferably 99.9999% by mass or less.

Examples of the method for the purification treatment include a method of passing a raw material through an ion exchange resin or a reverse osmosis membrane (RO membrane), and the like, a distillation of a raw material, and filtering which will be described later.

As the purification treatment, a plurality of the above-described purification methods may be combined and carried out. For example, the raw materials are subjected to primary purification by passing through an RO membrane, and then subjected to secondary purification by passing through a purification device consisting of a cation exchange resin, an anion exchange resin, or a mixed bed type ion exchange resin.

In addition, the purification treatment may be carried out a plurality of times.

### (Filtering)

Examples of the filter to be used for the filtering include a publicly known filter for filtering. Examples thereof include a filter consisting of a fluororesin such as polytetrafluoroethylene (PTFE) and a tetrafluoroethylene-perfluoroalkyl vinyl ether copolymer (PFA), a polyamide-based resin such as nylon, and a polyolefin resin (including a high-density polyolefin and an ultrahigh-molecular-weight polyolefin) such as polyethylene and polypropylene (PP).

Among these materials, a material selected from the group consisting of the polyethylene, the polypropylene (including a high-density polypropylene), the fluororesin (including PTFE and PFA), and the polyamide-based resin (including nylon) is preferable, and among these, the filter with the fluororesin is more preferable. In a case of carrying out filtering of the raw materials using a filter formed with these materials, it is possible to effectively remove high-polarity foreign matters which are likely to cause defects.

The critical surface tension of the filter is preferably 70 to 95 mN/m and more preferably 75 to 85 mN/m. It is noted that the value of the critical surface tension of the filter is a nominal value of a manufacturer. In a case of using a filter having a critical surface tension in the range, it is possible to effectively remove high-polarity foreign matters which are likely to cause defects.

The pore diameter of the filter is preferably 2 to 20 nm and more preferably 2 to 15 nm. By adjusting the pore diameter of the filter to be in the range, it is possible to reliably remove fine foreign matters such as impurities and aggregates included in the raw materials while suppressing clogging in filtering. With regard to the pore diameters herein, reference can be made to nominal values of filter manufacturers.

Filtering may be carried out only once or twice or more. In a case where filtering is carried out twice or more, the filters used may be the same as or different from each other.

In addition, the temperature of the filtering is preferably room temperature (25° C.) or lower, more preferably 23° C. or lower, and still more preferably 20° C. or lower. In addition, the temperature is preferably 0° C. or higher, more preferably 5° C. or higher, and still more preferably 10° C. or higher. In a case of carrying out filtering in the temperature range, it is possible to reduce the amounts of particulate foreign matter and impurities dissolved in the raw material and efficiently remove the foreign matter and impurities.

### <Container>

The composition (including an aspect of a diluted liquid described later) can be filled in any container and stored, transported, and used as long as corrosiveness does not become a problem.

In the use application for a semiconductor, the container is preferably a container which has a high degree of cleanliness inside the container and in which the elution of impurities from an inner wall of an accommodating portion of the container into each liquid is suppressed. Examples of such a container include various containers commercially available as a container for a semiconductor composition, such as “CLEAN BOTTLE” series manufactured by AICELLO CHEMICAL Co., Ltd., and “PURE BOTTLE” manufactured by Kodama Plastics Co., Ltd., but the container is not limited thereto.

In addition, as the container for accommodating the composition, a container in which a liquid contact portion with each liquid, such as an inner wall of the accommodating portion, is formed from a fluororesin (perfluororesin) or a metal which has been subjected to rust prevention and metal elution prevention treatments is preferable.

The inner wall of the container is preferably formed from one or more resins selected from the group consisting of a polyethylene resin, a polypropylene resin, and a polyethylene-polypropylene resin, another resin different from these resins, and a metal which has been subjected to rust prevention and metal elution prevention treatments, such as stainless steel, Hastelloy, Inconel, and Monel.

The other resin described above is preferably a fluororesin (perfluororesin). In this manner, by using a container having an inner wall formed of a fluororesin, the occurrence of a problem of elution of ethylene or propylene oligomers can be suppressed, as compared with a container having an inner wall formed of a polyethylene resin, a polypropylene resin, or a polyethylene-polypropylene resin.

Examples of such a container having an inner wall which is a fluororesin include a FluoroPure PFA composite drum manufactured by Entegris, Inc. In addition, the containers described on page 4 of JP1991-502677A (JP-H3-502677A), page 3 of WO2004/016526A, and pages 9 and 16 of WO99/046309A can also be used.

Further, for the inner wall of the container, quartz and an electropolished metal material (that is, a completely electropolished metal material) are also preferably used, in addition to the above-described fluororesin.

The metal material that is used for producing the electropolished metal material is preferably a metal material which includes at least one selected from the group consisting of chromium and nickel, and has a total content of chromium and nickel of more than 25% by mass with respect to the total mass of the metal material, and examples thereof include stainless steel and a nickel-chromium alloy.

The total content of chromium and nickel in the metal material is more preferably 30% by mass or more with respect to the total mass of the metal material. The upper limit thereof is preferably 90% by mass or less.

As a method for electropolishing the metal material, the publicly known method can be used. For example, the methods described in paragraphs [0011] to [0014] of JP2015-227501A, paragraphs [0036] to [0042] of JP2008-264929A, or the like can be used.

The inside of these containers is preferably subjected to cleaning before filling the composition. For the liquid used for the cleaning, the amount of the metal impurities in the liquid is preferably reduced. The composition may be bottled in a container such as a gallon bottle and a coated bottle after the production, and then may be transported and stored.

In order to prevent the change in the components in the composition during storage, the inside of the container may be replaced with inert gas (nitrogen, argon, or the like) with a purity of 99.99995% by volume or more. In particular, a gas having a low moisture content is preferable. In addition, during the transportation and the storage, the temperature may be normal temperature or may be controlled in a range of −20° C. to 20° C. to prevent deterioration.

### (Clean Room)

It is preferable that the handling including the production of the composition, the opening and cleaning of a container, the filling of the composition, and the like, the treatment analysis, and the measurement are all carried out in a clean room. It is preferable that the clean room satisfies 14644-1 clean room standards. Among these, it is more preferable to satisfy any one of an International Organization for Standardization (ISO) class 1, an ISO class 2, an ISO class 3, an ISO class 4, an ISO class 5, or an ISO class 6, it is still more preferable to satisfy any one of an ISO class 1, an ISO class 2, an ISO class 3, or an ISO class 4, it is particularly preferable to satisfy an ISO class 1 or an ISO class 2, and it is most preferable to satisfy an ISO class 1.

### <Dilution Step>

After undergoing a dilution step of carrying out dilution with a diluted liquid such as water, the composition may be used for cleaning a semiconductor substrate as a composition (a diluted liquid) which has been diluted.

It is noted that the diluted liquid is also a form of the composition according to the embodiment of the present invention as long as the requirements of the present invention are satisfied.

The dilution ratio of the composition in the dilution step may be appropriately adjusted according to the kind and the content of each component and the object to be subjected to application such as a semiconductor substrate. However, the ratio (dilution ratio) of the diluted liquid to the composition before dilution is, for example, 10 to 1,000 times in terms of mass ratio, and it is preferably 30 to 400 times, and more preferably 50 to 300 times.

In particular, in a case of being used as various cleaning liquids, the composition is preferably diluted to 30 times or more, more preferably diluted to 50 times or more, and still more preferably diluted to 100 times or more.

The composition is preferably diluted with water from the viewpoint that the defect inhibition performance is more excellent.

In other words, it is also possible to suitably use a composition (diluted liquid) containing each component with an amount obtained by dividing a suitable content of each component (excluding water) contained in the above-described composition by a dilution ratio (for example, 100) in the above-described range.

In other words, the suitable content of each component (excluding water) with respect to the total mass of the diluted liquid is, for example, an amount obtained by dividing the amount described as the suitable content of each component with respect to the total mass of the composition (composition before dilution) by a dilution ratio in the above-described range (for example, 100).

The change in pH before and after dilution (the difference between the pH of the composition before dilution and the pH of the diluted liquid) is, for example, 2.0 or less, and more preferably 1.0 or less. The lower limit thereof is not particularly limited and may be 0. The preferred range of the pH of the diluted liquid is the same as the preferred range of the pH of the composition described above.

The electric conductivity of the diluted liquid is not particularly limited; however, it is preferably 0.01 to 0.5 S/m and more preferably 0.03 to 0.3 S/m from the viewpoint that the balance between the cleaning properties and the cost is more excellent.

The measuring method and the adjusting method for the electric conductivity of the diluted liquid are the same as the measuring method and the adjusting method for the electric conductivity of the composition. The electric conductivity of the diluted liquid can also be adjusted by the dilution ratio.

It suffices that a specific method of the dilution step of diluting the composition is carried out in accordance with the composition preparing step described above. For a stirring device and a stirring method as well, which are used in the dilution step, it suffices that a publicly known stirring device described in the composition preparing step described above is used.

It is preferable to subject the water that is used in the dilution step to a purification treatment in advance. In addition, it is preferable to subject a diluted liquid obtained in a dilution step to a purification treatment.

Examples of the purification treatment include the ion component reducing treatment using an ion exchange resin, an RO membrane, or the like, and the foreign matter removal using filtering, which are described as the purification treatment for the composition described above, and it is preferable to carry out any one of these treatments.

In the dilution step, any of the above-described pH adjusting agent and the above-described component having a function of a pH adjusting agent may be added to adjust the pH of the diluted liquid as long as the performance of the diluted liquid is not impaired.

### [Use Application of Composition]

Next, the use application of the composition will be described.

The present composition can be used as a composition that is used in a manufacturing process of a semiconductor element. That is, the present composition can be used in any step for manufacturing a semiconductor element.

Examples of the use application of the present composition include a cleaning liquid (a cleaning liquid for a semiconductor substrate) that is used for cleaning of a semiconductor substrate, a cleaning liquid (a cleaning liquid for a member) that is used for cleaning a member that is used for manufacturing a semiconductor substrate, and a treatment liquid (a treatment liquid for a semiconductor substrate) that is used for removing a target such as a metal-containing substance on a semiconductor substrate.

The cleaning liquid for a semiconductor substrate is not particularly limited as long as it is a cleaning liquid that is used for the intended purpose of removing residues such as metal impurities or fine particles attached to a semiconductor substrate, where the metal impurities or the fine particles have been applied to the semiconductor substrate. Examples thereof include a cleaning liquid for a semiconductor substrate subjected to a chemical mechanical polishing (CMP) treatment (a pCMP cleaning liquid), a cleaning liquid for a semiconductor substrate subjected to a CMP treatment (a cleaning liquid for buffing cleaning), a cleaning liquid for a semiconductor substrate subjected to a back grinding treatment, a cleaning liquid for a semiconductor substrate subjected to an etching treatment (a post-etching residue cleaning liquid), and a cleaning liquid for a semiconductor substrate in which electronic components are soldered using a flux or a semiconductor substrate in which solder bumps are formed.

Examples of the cleaning liquid for a member include a cleaning liquid for cleaning an object such as a member that comes into contact with a semiconductor substrate in a manufacturing process of a semiconductor element, and a member that comes into contact with a treatment liquid before being applied to a semiconductor substrate. More specific examples thereof include a cleaning liquid for a cleaning brush that is used for cleaning a semiconductor substrate (a cleaning liquid for a brush), a cleaning liquid for a polishing pad that is used for a treatment of a semiconductor substrate (a cleaning liquid for a pad), a cleaning liquid for cleaning a resin product such as a storage container for a semiconductor substrate, a cleaning liquid for cleaning a glass substrate, and a cleaning liquid for mechanical cleaning.

Examples of the treatment liquid for a semiconductor substrate include an etchant that dissolves and removes a metal-containing substance on a semiconductor substrate, a pre-wet liquid that is applied onto a substrate in order to improve the coatability of an actinic ray-sensitive or radiation-sensitive composition before a step of forming a resist film using the actinic ray-sensitive or radiation-sensitive composition, and a treatment liquid that is applied to a semiconductor substrate, such as a rinsing liquid that rinses off substances that have adhered to a semiconductor substrate.

The present composition exhibits an excellent effect that an increase in defects in an object can be suppressed even in a case where the present composition after a predetermined period has elapsed from the production is applied, where the object is, for example, the semiconductor substrate, the cleaning brush, and the polishing pad, which are exemplified in the above-described use application.

The present composition may be used in only one use application or two or more of use applications among the above-described use applications.

Examples of the method of using the present composition for the above-described use application include a method of bringing an object of the above-described use application into contact with the present composition. As a result, it is possible to carry out the cleaning of an object (the removal or the like of residues on an object) or the removal of one or more kinds of metal-containing substances contained in an object.

More specific examples thereof include a cleaning method of removing residues that have adhered to an object (for example, a method of cleaning a semiconductor substrate which has been subjected to CMP) by using the present composition. In addition, examples thereof also include an etching treatment method of dissolving and removing a metal-containing substance on an object by using the present composition, a pre-wetting treatment method of applying the present composition onto a semiconductor substrate before a step of forming a resist film by using an actinic ray-sensitive or radiation-sensitive composition, and a rinsing treatment method of rinsing a semiconductor substrate by using the present composition.

### [Semiconductor Substrate]

Hereinafter, the semiconductor substrate will be described.

In the following description, the configuration of the semiconductor substrate will be described by taking, as a representative example, a case where the present composition is brought into contact with the semiconductor substrate. However, the aspect to which the composition is applied is not limited to the following description, and as described above, the semiconductor substrate, which is brought into contact with a member to be subjected to cleaning with the present composition or brought into contact with a treatment liquid which is brought into contact with a member to be subjected to cleaning with the present composition, may be a semiconductor substrate described below.

Examples of the semiconductor substrate, which is one of the objects to which the present composition is applied, include a semiconductor substrate having a metal-containing substance on a semiconductor substrate.

In the present specification, the phrase “on the semiconductor substrate” includes, for example, both the front and back surfaces, the side surfaces, and the inside of the groove of the semiconductor substrate. In addition, the metal-containing substance on the semiconductor substrate encompasses not only a case where the metal-containing substance is directly on the surface of the semiconductor substrate but also a case where the metal-containing substance is present on the semiconductor substrate through another layer.

The semiconductor substrate may have two or more kinds of metal-containing substances.

The metal-containing substance may be a substance containing a metal (metal atom).

Examples of the metal contained in the metal-containing substance include at least one metal M selected from the group consisting of copper (Cu), aluminum (Al), ruthenium (Ru), cobalt (Co), tungsten (W), titanium (Ti), tantalum (Ta), chromium (Cr), hafnium (Hf), osmium (Os), platinum (Pt), nickel (Ni), manganese (Mn), zirconium (Zr), molybdenum (Mo), lanthanum (La), and iridium (Ir).

Examples of the metal-containing substance include a simple body of the metal M, an alloy including the metal M, an oxide of the metal M, a nitride of the metal M, and an oxynitride of the metal M. The metal-containing substance may be a mixture containing two or more of these compounds. In addition, the oxide, the nitride, and the oxynitride may be respectively any of a composite oxide, a composite nitride, and a composite oxynitride, which contain a metal.

The content of the metal atom in the metal-containing substance is preferably 10% by mass or more, more preferably 30% by mass or more, and still more preferably 50% by mass or more with respect to the total mass of the metal-containing substance. The upper limit thereof is preferably 100% by mass or less.

The semiconductor substrate preferably has the metal M-containing substance containing the metal M, more preferably has a metal-containing substance containing at least one metal selected from the group consisting of Cu, Al, W, Co, Ti, Ta, Ru, and Mo, still more preferably has a metal-containing substance containing at least one metal selected from the group consisting of W, Co, Cu, Al, Ti, Ta, and Ru, and particularly preferably has a W-containing substance containing W.

Examples of the semiconductor substrate include a semiconductor substrate having a metal wiring line film, a barrier metal, and an insulating film on a surface of a wafer constituting the substrate.

Examples of the wafer constituting a substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), and antimony (Sb)) and a p-type silicon wafer in which a silicon wafer is doped with a trivalent atom (for example, boron (B) and gallium (Ga)). Examples of the silicon of the silicon wafer include amorphous silicon, single crystal silicon, polycrystalline silicon, and polysilicon.

Among them, it is preferably a wafer consisting of a silicon-based material, such as a silicon wafer, a silicon carbide wafer, or a resin-based wafer (a glass epoxy wafer) including silicon.

The semiconductor substrate may have an insulating film on the wafer.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film), where a low-dielectric-constant (Low-k) film is preferable.

The semiconductor substrate often has a metal film containing a metal, as a metal wiring line film, a barrier metal, or another film.

The metal film included in the semiconductor substrate is preferably a metal film containing the metal M, more preferably a metal film containing at least one metal selected from the group consisting of Cu, Al, W, Co, Ti, Ta, Ru, and Mo, and still more preferably a metal film containing at least one metal selected from the group consisting of W, Co, Cu, and Ru.

Examples of the metal film containing at least one metal selected from the group consisting of W, Co, Cu, and Ru include a film containing tungsten as a main component (a W-containing film), a film containing cobalt as a main component (a Co-containing film), a film containing copper as a main component (a Cu-containing film), and a film containing ruthenium as a main component (a Ru-containing film).

Among these, it is preferable that the semiconductor substrate has a W-containing film.

Examples of the W-containing film include a metal film (a W metal film) consisting of only tungsten and a metal film (a W alloy metal film) consisting of an alloy made of tungsten and another metal. Examples of the tungsten alloy metal film include a tungsten-titanium alloy metal film (a WTi alloy metal film), and a tungsten-cobalt alloy metal film (a WCo alloy metal film). The W-containing film is used, for example, as a barrier metal or a connecting portion between a via and a wiring line.

Examples of the Cu-containing film include a wiring line film consisting of only metal copper (Cu wiring line film) and a wiring line film made of an alloy consisting of metal copper and another metal (Cu alloy wiring line film).

Examples of the Co-containing film include a metal film (a Co metal film) consisting of only metal cobalt and a metal film (a Co alloy metal film) consisting of an alloy consisting of metallic cobalt and another metal.

Examples of the Ru-containing film include a metal film consisting of only metal ruthenium (Ru metal film) and a metal film made of an alloy consisting of metal ruthenium and another metal (Ru alloy metal film). The Ru-containing film is often used as a barrier metal.

A method of forming the above-described metal wiring line film, barrier metal, and insulating film on a wafer constituting a semiconductor substrate is not particularly limited as long as it is a method that is generally carried out in this field.

Examples of a method of forming an insulating film include a method in which a wafer constituting a semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the W-containing film, the Cu-containing film, the Ru-containing film, and the Co-containing include a method of forming a circuit on a wafer having the above-described insulating film by a publicly known method such as a resist, and then forming the W-containing film, the Cu-containing film, the Ru-containing film, and the Co-containing film according to a method such as plating and a CVD method.

### <CMP Treatment>

The semiconductor substrate may be a semiconductor substrate that has been subjected to a flattening treatment such as a CMP treatment after providing an insulating film, a barrier metal, and a metal film on the wafer.

In general, the CMP treatment is a treatment of flattening a surface of a semiconductor substrate with a combined action of a chemical action of components contained in a polishing liquid and polishing by mechanical friction, by attaching a polishing pad onto a circular surface plate for polishing (platen), immersing a surface of the polishing pad in a polishing liquid containing polishing fine particles (abrasive grains), pressing a surface of a semiconductor substrate having a metal film, a barrier metal, and an insulating film onto the surface of the attached polishing pad, and rotating both the surface plate for polishing and the substrate in a state where a predetermined pressure (polishing pressure) is applied from a back surface of the semiconductor substrate,

A surface of the semiconductor substrate that has been subjected to the CMP treatment may have impurities remaining thereon, such as abrasive grains (for example, silica and alumina) used in the CMP treatment, a polished metal film, and/or metal impurities (metal residue) derived from the barrier metal. In addition, organic impurities derived from a polishing liquid used in the CMP treatment may remain. For example, since these impurities may short-circuit the wiring lines and deteriorate the electrical characteristics of the semiconductor substrate, the semiconductor substrate that has been subjected to the CMP treatment is subjected to a cleaning treatment for removing these impurities from the surface.

Examples of the semiconductor substrate that has been subjected to the CMP treatment include the substrate that has been subjected to a CMP treatment, described in Vol. 84, No. 3, 2018, but the present invention is not limited thereto.

A polishing liquid is used for the CMP treatment.

As the polishing liquid that is used in the CMP treatment, a publicly known polishing liquid can be appropriately used depending on the kind of the semiconductor substrate, the composition of the polishing liquid, and the kind of the residue to be removed.

Examples of the polishing liquid include a polishing liquid containing iron ions and hydrogen peroxide, or a polishing liquid containing chemically modified colloidal silica (for example, colloidal silica subjected to cationization modification and anionization modification). In addition, examples of the polishing liquid also include the polishing liquids containing an iron complex, which are described in JP2020-068378A, JP2020-015899A, and U.S. Ser. No. 11/043,151B, and the polishing liquid containing chemically modified colloidal silica, which is described in JP2021-082645A, the contents of which are incorporated in the present specification.

A polishing pad that can be used for the CMP treatment is not particularly limited.

Examples of the constituent material of the polishing pad include a thermoplastic resin or an elastomer, and a polyurethane resin (more preferably a foamed polyurethane resin). In addition, a polishing pad including a nonwoven fabric impregnated with a polyurethane resin, and a polishing pad having a suede-like surface can also be used. A polishing pad including a polyurethane resin is preferable from the viewpoint that hydrophilicity is high and the immersion in the polishing liquid is easy.

As a commercially available product thereof, for example, a polishing pad made of a thermoplastic resin or an elastomer can be available from JSR Corporation, and a polishing pad made of a polyurethane resin can be available from NITTA DuPont Incorporated.

### <Buffing Cleaning>

The semiconductor substrate may be a semiconductor substrate which has been subjected to a CMP treatment and then subjected to buffing cleaning.

The buffing cleaning is a treatment of reducing impurities on the surface of the semiconductor substrate using a polishing pad. Specifically, a polished surface of a semiconductor substrate which has been subjected to the CMP treatment is pressed onto a surface of the polishing pad attached to the circular platen to bring the polishing pad into contact with the semiconductor substrate, and then the semiconductor substrate and the polishing pad are allowed to relatively slide while supplying a cleaning liquid for buffing cleaning to a contact portion therebetween. By this treatment, the impurities on the surface of the semiconductor substrate subjected to the CMP treatment are removed by a frictional force due to the polishing pad and a chemical action due to the cleaning liquid.

As the cleaning liquid for buffing cleaning, a publicly known cleaning liquid for buffing cleaning can be appropriately used depending on the kind of semiconductor substrate and the kind and amount of impurities to be removed. Examples of the component contained in the cleaning liquid for buffing cleaning include a water-soluble polymer such as polyvinyl alcohol, water as a dispersion medium, and an acid such as nitric acid.

As will be described later, the semiconductor substrate may be subjected to buffing cleaning by using the present composition as a cleaning liquid for buffing cleaning.

A polishing device, polishing conditions, and the like, which are used in buffing cleaning, can be appropriately selected from known devices and conditions according to the kind of the semiconductor substrate, the object to be removed, and the like. Examples of the buffing cleaning include the treatments described in paragraphs [0085] to [0088] of WO2017/169539A, the contents of which are incorporated in the present specification.

Hereinafter, among use applications of the above-described composition, each use application of a cleaning liquid for a semiconductor substrate (preferably a CMP-treated semiconductor substrate), a cleaning liquid for a brush used for cleaning a semiconductor substrate, a cleaning liquid for a polishing pad used in treatment of a semiconductor substrate, and a cleaning liquid for buffing cleaning of a CMP-treated semiconductor substrate will be described in detail.

The semiconductor substrate used for the above-described use applications is not particularly limited as long as it is the semiconductor substrate described above, but a semiconductor substrate containing tungsten is preferable and a semiconductor substrate having a W-containing film is more preferable.

### [First Use Application: Cleaning of CMP-Treated Semiconductor Substrate]

The present composition can be used as a cleaning liquid for a semiconductor substrate in a cleaning method of a semiconductor substrate, which includes a step of cleaning a CMP-treated semiconductor substrate (hereinafter, also referred to as “first use application”). That is, the present composition can be used as a cleaning liquid that is used for a CMP-treated semiconductor substrate in a manufacturing method of a semiconductor element, which includes a step of subjecting a semiconductor substrate with a CMP treatment and a step of cleaning the CMP-treated semiconductor substrate.

The present composition can be applied to a publicly known method carried out on the CMP-treated semiconductor substrate.

The present composition that is used for the first use application may be a diluted liquid obtained in the above-described dilution step, and it is also preferable to include a step of applying the diluted liquid to the CMP-treated semiconductor substrate to carry out cleaning.

A cleaning step of cleaning the semiconductor substrate subjected to the CMP treatment is not particularly limited as long as it is a method of cleaning the semiconductor substrate by bringing a composition into contact with the semiconductor substrate. Publicly known methods in the field of manufacturing a semiconductor element, such as scrub cleaning in which a cleaning member such as a brush is physically brought into contact with a surface of a semiconductor substrate to remove residues and the like while supplying a composition to the semiconductor substrate, an immersion type in which a semiconductor substrate is immersed in a composition, a spin (dropwise addition) type in which a composition is added dropwise while rotating a semiconductor substrate, and a spraying (spray) type in which a composition is sprayed, are appropriately employed.

In the cleaning of the semiconductor substrate, a mechanical stirring method may be used in order to further reduce the impurities remaining on the surface of the semiconductor substrate and further enhance the cleaning ability of the composition. Examples of the mechanical stirring method include a method of circulating a composition on a semiconductor substrate, a method of flowing or spraying a composition on a semiconductor substrate, and a method of stirring a composition with an ultrasonic wave or a megasonic wave.

The cleaning step may be carried out only once or twice or more. In a case of carrying out cleaning two or more times, the same method may be repeated, or different methods may be combined.

The cleaning method for a semiconductor substrate may be any one of a single-wafer method or a batch method.

The single-wafer method is generally a method of treating semiconductor substrates one by one, and the batch method is generally a method of treating a plurality of semiconductor substrates at the same time.

The temperature of the composition that is used for the cleaning of the semiconductor substrate is not particularly limited as long as it is a temperature that is usually used in this field. Although the cleaning is often carried out at room temperature (about 25° C.), the temperature can be freely selected in order to improve cleaning properties and suppress damage to the member. The temperature of the composition is preferably 10° C. to 60° C. and more preferably 15° C. to 50° C.

A cleaning time in the cleaning of the semiconductor substrate can be appropriately changed depending on the kind, content, and the like of the components contained in the composition. Practically, it is preferably 10 to 120 seconds, more preferably 20 to 90 seconds, and still more preferably 30 to 60 seconds.

The supply amount (the supply rate) of the composition in the cleaning step for the semiconductor substrate is preferably 50 to 5,000 mL/min and more preferably 500 to 2,000 mL/min.

A preferred aspect of the composition that is used for the first use application is as follows. The pH of the composition is 4.0 to 9.0, and it is preferable to be within the above-described preferred range of the pH of the composition.

The composition that is used for the first use application may be a diluted liquid obtained in the above-described dilution step. In a case where a diluted liquid is used, the dilution ratio is preferably 10 times or more, more preferably 30 times or more, still more preferably 50 times or more, and particularly preferably 100 times or more in terms of mass ratio. The upper limit thereof is not particularly limited; however, it is preferably 1,000 times or less, more preferably 400 times or less, and still more preferably 300 times or less. The pH of the diluted liquid is 4.0 to 9.0, and it is preferable that the pH of the diluted liquid is within the above-described preferred range of the diluted liquid.

In the composition, the ratio A/B of the content of the antibacterial agent to the content of the organic acid is preferably 0.5 or less, and it is preferably within the above-described preferred range of the ratio A/B. In addition, in the composition, the ratio A/C of the content of the antibacterial agent to the content of the organic amine is preferably 0.3 or less, and it is preferably within the above-described preferred range of the ratio A/C.

The electric conductivity of the composition at 25° C. is preferably 0.05 S/m or more and more preferably 0.1 to 2.0 S/m.

The antibacterial agent contained in the composition is preferably a carboxylic acid-based antibacterial agent or an isothiazolinone-based antibacterial agent.

After cleaning the semiconductor substrate, a step of rinsing and cleaning the semiconductor substrate with a solvent (hereinafter, also referred to as a “rinsing step”) may be carried out.

The rinsing step is preferably a step which is carried out continuously subsequently after the cleaning step for the semiconductor substrate and in which rinsing is carried out with a rinsing liquid over 5 to 300 seconds. The rinsing step may be carried out using the above-described mechanical stirring method.

Examples of the rinsing liquid include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (an aqueous ammonium hydroxide that has been diluted, or the like) may be used.

As a method of bringing the rinsing liquid into contact with the semiconductor substrate, the above-described method of bringing the composition into contact with the semiconductor substrate can be similarly applied.

In addition, after the rinsing step, a drying step of drying the semiconductor substrate may be carried out.

Examples of the drying method include a spin drying method, a method of flowing a dry gas onto a semiconductor substrate, a method of heating a substrate by a heating means such as a hot plate and an infrared lamp, a Marangoni drying method, a Rotagoni drying method, an isopropyl alcohol (IPA) drying method, and a method of any combinations of these methods.

### [Second Use Application: Cleaning of Cleaning Brush]

The present composition can be used as a cleaning liquid for a brush in a cleaning method of a cleaning brush, which includes a step of cleaning a cleaning brush used for cleaning a semiconductor substrate (hereinafter, also referred to as “second use application”).

Examples of the cleaning brush which is an object to be subjected to cleaning for the second use application include publicly known brushes used for scrub cleaning, in which the cleaning brush is physically brought into contact with a surface of the semiconductor substrate to remove residues. As the cleaning brush, a cleaning brush used for cleaning the CMP-treated semiconductor substrate is preferable.

A shape of the cleaning brush is not particularly limited, examples thereof include a cylindrical roll type brush and a pencil type brush, and a roll type brush is preferable. In addition, in many cases, the cleaning brush has a large number of columnar protrusions protruding in a radial direction on the surface.

Examples of a constituent material of the cleaning brush include polymer resins having a hydroxyl group, such as a polyvinyl alcohol (PVA) resin, a polyurethane resin, and a polyolefin resin. As the cleaning brush, a cleaning brush consisting of a sponge-like substance of the above-described polymer resin is preferable, and a cleaning brush consisting of a sponge-like material of the PVA resin is more preferable.

Examples of a commercially available product of the cleaning brush include a brush manufactured by Entegris, Inc. (for example, model: “PVP1ARXR1”) and a brush manufactured by AION Co., Ltd. (Bell-eater (registered trademark) A series).

As the method of cleaning the cleaning brush using the composition, a publicly known method carried out in the field of manufacturing a semiconductor element, such as the immersion and spray described as the cleaning step of the semiconductor substrate in the above-described first use application is appropriately adopted.

In addition, cleaning conditions including the temperature and cleaning time of the cleaning liquid can also be appropriately selected with reference to the cleaning conditions in the above-described cleaning step of the semiconductor substrate and publicly known cleaning methods, based on the constituent material of the cleaning brush.

A preferred aspect of the composition that is used for the second use application is as follows.

The pH of the composition is 4.0 to 9.0, and it is preferable to be within the above-described preferred range of the pH of the composition.

The composition that is used for the second use application may be a diluted liquid obtained in the above-described dilution step. A dilution ratio in a case of using a diluted liquid is preferably 10 to 100 times and more preferably 30 to 100 times in terms of mass ratio. The pH of the diluted liquid is 4.0 to 9.0, and it is preferable that the pH of the diluted liquid is within the above-described preferred range of the diluted liquid.

In the composition, the ratio A/B of the content of the antibacterial agent to the content of the organic acid is preferably 0.5 or less, and it is preferably within the above-described preferred range of the ratio A/B. In addition, in the composition, the ratio A/C of the content of the antibacterial agent to the content of the organic amine is preferably 0.3 or less, and it is preferably within the above-described preferred range of the ratio A/C.

The electric conductivity of the composition at 25° C. is preferably 0.05 S/m or more and more preferably 0.1 to 1.0 S/m. In addition, the electric conductivity of the diluted composition at 25° C. is preferably 0.02 S/m or more and more preferably 0.05 to 0.8 S/m. The antibacterial agent contained in the composition is preferably a carboxylic acid-based antibacterial agent or an isothiazolinone-based antibacterial agent.

### [Third Use Application: Cleaning of Polishing Pad]

The present composition can be used as a cleaning liquid for a polishing pad in a cleaning method of a polishing pad, which includes a step of cleaning a polishing pad used for treating a semiconductor substrate (hereinafter, also referred to as “third use application”).

The polishing pad which is an object to be subjected to cleaning for the third use application is not particularly limited as long as it is a publicly known polishing pad used for treating a semiconductor substrate, and examples thereof include the polishing pad described in <CMP treatment> described above. Among these, a polishing pad containing a polyurethane resin is preferable. In addition, the polishing pad is preferably a polishing pad used for the CMP treatment.

As the cleaning method for the polishing pad, a publicly known method carried out in the field of manufacturing a semiconductor element, such as the immersion and spray described as the cleaning step of the semiconductor substrate in the above-described first use application is appropriately adopted.

In addition, cleaning conditions including the temperature and cleaning time of the cleaning liquid can also be appropriately selected with reference to the cleaning conditions in the above-described cleaning step of the semiconductor substrate and publicly known cleaning methods, based on the constituent material of the polishing pad.

A preferred aspect of the composition that is used for the third use application is as follows.

The pH of the composition is 4.0 to 9.0, and it is preferable to be within the above-described preferred range of the pH of the composition.

The composition that is used for the third use application may be a diluted liquid obtained in the above-described dilution step. In a case where a diluted liquid is used, the dilution ratio is preferably 10 to 100 times, more preferably 30 to 100 times, and still more preferably 50 to 100 times in terms of mass ratio. The pH of the diluted liquid is 4.0 to 9.0, and it is preferable that the pH of the diluted liquid is within the above-described preferred range of the diluted liquid.

In the composition, the ratio A/B of the content of the antibacterial agent to the content of the organic acid is preferably 0.5 or less, and it is preferably within the above-described preferred range of the ratio A/B. In addition, in the composition, the ratio A/C of the content of the antibacterial agent to the content of the organic amine is preferably 0.3 or less, and it is preferably within the above-described preferred range of the ratio A/C.

The electric conductivity of the composition at 25° C. is preferably 0.05 S/m or more and more preferably 0.1 to 1.0 S/m. The electric conductivity of the diluted composition at 25° C. is preferably 0.02 S/m or more and more preferably 0.05 to 0.8 S/m. The antibacterial agent contained in the composition is preferably a carboxylic acid-based antibacterial agent or an isothiazolinone-based antibacterial agent.

### [Fourth Use Application: Buffing Cleaning]

The present composition can be used as a cleaning liquid for buffing cleaning in a cleaning method of a semiconductor substrate, which includes buffing cleaning step in which a polishing pad is brought into contact with a surface of a CMP-treated semiconductor substrate to clean the surface of the semiconductor substrate (hereinafter, also referred to as “fourth use application”).

A specific method of the buffing cleaning for the fourth use application is as described in <buffing cleaning> described above. In addition, the polishing pad used for the buffing cleaning of the fourth use application is as described in <CMP treatment> described above.

A preferred aspect of the composition that is used for the fourth use application is as follows.

The pH of the composition is 4.0 to 9.0, and it is preferable to be within the above-described preferred range of the pH of the composition.

The composition that is used for the fourth use application may be a diluted liquid obtained in the above-described dilution step. In a case where a diluted liquid is used, the dilution ratio is preferably 10 to 100 times, more preferably 30 to 100 times, and still more preferably 50 to 100 times in terms of mass ratio. The pH of the diluted liquid is 4.0 to 9.0, and it is preferable that the pH of the diluted liquid is within the above-described preferred range of the diluted liquid.

In the composition, the ratio A/B of the content of the antibacterial agent to the content of the organic acid is preferably 0.5 or less, and it is preferably within the above-described preferred range of the ratio A/B. In addition, in the composition, the ratio A/C of the content of the antibacterial agent to the content of the organic amine is preferably 0.3 or less, and it is preferably within the above-described preferred range of the ratio A/C.

The electric conductivity of the composition at 25° C. is preferably 0.05 S/m or more and more preferably 0.2 to 2.0 S/m.

The antibacterial agent contained in the composition is preferably a carboxylic acid-based antibacterial agent or an isothiazolinone-based antibacterial agent.

It is preferable that the composition is substantially free of abrasive grains and coarse particles.

### [Other Use Applications]

The present composition can also be used in use applications different from any of the use applications of cleaning of the CMP-treated semiconductor substrate, cleaning of the cleaning brush used for cleaning a semiconductor substrate, cleaning of the polishing pad used in treatment of a semiconductor substrate, and buffing cleaning of a CMP-treated semiconductor substrate.

<Cleaning of Semiconductor Substrate which has been Subjected to Back Grinding>

For the purpose of reducing the size and thickness of a semiconductor device, there is known a technique (back grinding) of reducing a thickness of a wafer by grinding a surface of the semiconductor substrate opposite to a circuit forming surface.

The present composition can be used as a cleaning liquid in a cleaning step of cleaning a semiconductor substrate which has been subjected to back grinding. By using the present composition, it is possible to remove residues generated by back-grinding and an etching treatment associated with the back grinding.

<Cleaning of Semiconductor Substrate which has been Subjected to Etching Treatment>

In a process of manufacturing a semiconductor element, in a case where a metal layer and/or an insulating layer of a semiconductor substrate is etched by plasma etching using a resist pattern as a mask, residues derived from a photoresist, the metal layer, and the insulating layer are generated on the semiconductor substrate. In addition, in a case where a resist pattern which has been unnecessary is removed by plasma ashing, residues derived from the ashing photoresist are generated on the semiconductor substrate.

The present composition can be used as a cleaning liquid in a cleaning step of cleaning a semiconductor substrate which has been subjected to an etching treatment. By using the present composition, it is possible to remove the etching residues and/or the ashing residues, which are generated on the semiconductor substrate subjected to the etching treatment.

### <Cleaning of Flux Residue on Semiconductor Substrate>

In a case where an electronic component is mounted on a semiconductor substrate by soldering, a flux (accelerator) that removes an oxide which interferes with a connection between a metal such as an electrode or a wiring line and a solder metal and promotes the connection is used. In such a substrate on which the electronic component is soldered using the flux and/or a substrate with a solder bump for soldering the electronic component, which is formed using the flux, residues derived from the flux may remain.

The present composition can be used as a cleaning liquid for cleaning a semiconductor substrate on which the electronic component is soldered using the flux or a semiconductor substrate on which the solder bump is formed using the flux. By using the present composition, it is possible to remove the residues derived from the flux remaining on the semiconductor substrate.

<Cleaning of Semiconductor Substrate which has been Subjected to Etching Treatment>

In a process of manufacturing a semiconductor element, in a case where a metal layer and/or an insulating layer of a semiconductor substrate is etched by plasma etching using a resist pattern as a mask, residues derived from a photoresist, the metal layer, and the insulating layer are generated on the semiconductor substrate. In addition, in a case where a resist pattern which has been unnecessary is removed by plasma ashing, residues derived from the ashing photoresist are generated on the semiconductor substrate.

The present composition can be used as a cleaning liquid in a cleaning step of cleaning a semiconductor substrate which has been subjected to an etching treatment. By using the present composition, it is possible to remove the etching residues and/or the ashing residues, which are generated on the semiconductor substrate subjected to the etching treatment.

<Cleaning of Semiconductor Substrate which has been Subjected to Bonding Treatment>

In a process of manufacturing a semiconductor element, as a semiconductor chip manufactured by cutting (dicing) a wafer into a predetermined size, semiconductor chips held by a dicing film are picked up one by one, and sent to the next bonding step. During this dicing, foreign matters such as cutting shavings of the wafer and cutting shavings of the dicing film adhere to a surface of the semiconductor chip. In particular, in a bonding step such as flip-chip bonding in which the semiconductor chip is connected to the substrate through terminals arranged on the surface of the semiconductor chip, and direct bonding in which another semiconductor chip is directly bonded on top of the semiconductor chip, it has been known that the quality of bonding deteriorates due to minute foreign matter of several m or less, and a cleaning treatment is carried out to remove the foreign matters from the semiconductor chip subjected to the bonding step.

The present composition can be used as a cleaning liquid in a cleaning step of cleaning a semiconductor chip before being subjected to the bonding step. By using the present composition, it is possible to remove, from the semiconductor chip, the foreign matters such as chips generated in the dicing step before the bonding step.

### <Cleaning of Resin Product>

The present composition can be used for cleaning a resin product, particularly a resin container used for accommodating and transporting a semiconductor substrate in a process of manufacturing a semiconductor element.

In a case of accommodating and transporting a semiconductor substrate, a container for accommodating the semiconductor substrate is used to prevent intrusion of particles and to prevent chemical contamination. Examples of such a container include front opening shipping box (FOSB) used in a case of delivering wafers to semiconductor device manufacturers, and front opening unified pod (FOUP) and standard mechanical interface (SMIF) for storing wafers for transport between wafer processing steps. Here, in a case where an operation of storing the semiconductor substrate in the container and taking out the semiconductor substrate is repeated many times, metal impurities may be generated due to the contact between the semiconductor substrate and the inside of the container. In addition, the inside of the container may be contaminated with residues generated in the manufacturing process of the semiconductor element and remaining on the semiconductor substrate. The inside of the container is subjected to cleaning in order to prevent these metal impurities and residues from adhering to the semiconductor substrate.

By using the present composition for cleaning the above-described container, it is possible to remove the etching residues and/or the ashing residues, which are generated on the semiconductor substrate subjected to the etching treatment.

### <Cleaning of Glass Substrate>

The present composition can be used as a cleaning liquid for cleaning a glass substrate, particularly a glass substrate suitable for a flat panel display such as a liquid crystal display, a plasma display, an organic EL display, or a touch panel, and a hard disk. By using the present composition, it is possible to remove residues derived from metal impurities remaining on the glass substrate.

### <Etching Treatment>

The present composition can be used in an etching treatment for removing a metal film on a semiconductor substrate. Examples of the etching treatment include a method of dissolving and removing metal-containing substances on an object by bringing a composition into contact with the semiconductor substrate. The method of bringing the composition into contact with the semiconductor substrate is not particularly limited and the method described in the first use application can be adopted.

For specific aspects of the etching treatment, the description in paragraphs [0049] to [0069] of WO2019/138814A can be adopted, the contents of which are incorporated in the present specification by reference.

The present composition can also be used as a cleaning liquid for various machines including precision machines having a size from a small size to a large size such as MEMS, in addition to the above-described use applications.

All the treatments that are carried out according to the above-described use application by using the present composition may be carried out in combination before or after other steps that are carried out in the manufacturing of the semiconductor element. The above-described treatment may be incorporated into other steps while carrying out the above-described treatment, or the above-described treatment may be incorporated between other steps.

Examples of the other step include a step of forming each structure such as a metal wire, a gate structure, a source structure, a drain structure, an insulating layer, a ferromagnetic layer, and/or a non-magnetic layer (layer formation, etching, a CMP treatment, modification, or the like), a resist forming step, an exposure step and a removal step, a heat treatment step, a cleaning step, and an examination step.

The above-described treatment may be carried out at any stage of a back-end-of-the-line (BEOL) process, a middle-of-the-line (MOL) process, and a front-end-of-the-line (FEOL) process.

### EXAMPLES

Hereinbelow, the present invention will be described in more detail with reference to Examples. The material, the using amount, the proportion, and the like shown in the Examples below may be modified as appropriate as long as the modifications do not depart from the spirit of the present invention. Accordingly, the scope of the present invention should not be construed as being limited to Examples shown below.

In the following examples, the pH and the electric conductivity of the composition were measured using a portable electric conductivity-pH meter (“WM-32EP”, manufactured by DKK-TOA CORPORATION). The pH was measured at 25° C. in accordance with JIS Z8802-1984.

In the production of the compositions of Examples and Comparative Examples, the handling of the container, the preparation, filling, storage, and analytical measurement of the composition were all carried out in a clean room satisfying ISO class 2 or lower.

### [Raw Material of Composition]

The following compounds were used to produce the composition. It is noted that as the various components used in Example, those all classified into a semiconductor grade or those all classified into a high-purity grade equivalent to the semiconductor grade were used.

### [Antibacterial Agent]

Benzethonium chloride
Sorbic acid
Dehydroacetic acid
Cresol
Chlorhexidine gluconate
Tolylfluanid
Peracetic acid
Methyl isothiazolinone (MIT)
Octyl isothiazolinone (OIT)
Benzisothiazolinone (BIT)
Benzoic acid
Salicylic acid

### [Organic Acid]

Tartaric acid
Malic acid
Citric acid
Oxalic acid
Malonic acid
Succinic acid
Trimellitic acid
Gluconic acid
Maleic acid
Glutaric acid
Lactic acid
Methanesulfonic acid
Phthalic acid

### [Organic Amine]

2-(dimethylamino)-2-methyl-1-propanol (DMAMP)
Trishydroxymethylaminomethane (Tris)
2-amino-2-methyl-1-propanol (AMP)
Diethanolamine (DEA)
Triethanolamine (TEA)
Momonoethanolamine (MEA)

### [Chelating Agent]

Diethylenetriaminepenta(methylenephosphonic acid) (DEPPO)
1-hydroxyethylidene-1,1′-diphosphonic acid (HEDPO)
Nitrilotris(methylenephosphonic acid) (NTPO)
Ethylenediaminetetraphosphonic acid (EDTPO)
Ethylenediaminetetraacetic acid (EDTA)
Diethylenetriaminepentaacetic acid (DTPA)
Phytic acid
L-Arginine
L-Lysine
L-Histidine

### [Other Components]

Dodecylbenzenesulfonic acid (DBS, corresponding to a surfactant)
Dodecylbenzenesulfonic acid ammonium salt (DBSA, corresponding to a surfactant)
Polyacrylic acid (PAA, weight-average molecular weight (Mw): 5,000, corresponding to an anticorrosive agent (water-soluble polymer))
Polystyrenesulfonic acid (PSS, weight-average molecular weight (Mw): 10,000, corresponding to an anticorrosive agent (water-soluble polymer))
Adenine (corresponding to an anticorrosive agent (purine compound))
Xanthine (corresponding to an anticorrosive agent (purine compound))
(2Z,2′Z)-3,3′-disulfanediylbis(N-methylacrylamide) (DSBMA, corresponding to an anticorrosive agent)
3-methoxy-3-methyl-1-butanol (MMB, corresponding to an organic solvent)
Ethylene glycol monobutyl ether (EGBE, corresponding to an organic solvent)
Dimethyl sulfoxide (DMSO, corresponding to an organic solvent)
Dipropylene glycol monobutyl ether (DPGBE, corresponding to an organic solvent)
Ethylene glycol monoethyl ether acetate (EGEEA, corresponding to an organic solvent)

### [pH Adjusting Agent and Water]

In the production of the composition in the present example, the organic amine shown in Table 1 was used as a pH adjusting agent, and commercially available ultrapure water (manufactured by FUJIFILM Wako Pure Chemical Corporation) was used as water.

### Preparation Example 1: Preparation of Composition

A composition 101 was prepared according to the following method.

Benzethonium chloride, tartaric acid, and diethylenetriaminepenta(methylenephosphonic acid) (DEPPO) were respectively added to ultrapure water so that amounts thereof were such a formulation as shown in Table 1, and then 2-(dimethylamino)-2-methyl-1-propanol (DMAMP) was added thereto so that the pH of the composition to be prepared was 6.2. The obtained mixed liquid was sufficiently stirred to obtain a composition 101.

Each of compositions 102 to 221 and comparative compositions 1 and 2, which have the compositions shown in Table 1, was produced in accordance with the preparation method for the composition 101.

### Example 1: Evaluation of Cleaning Performance with Respect to Semiconductor Substrate

Using each composition prepared by the above-described method, the cleaning performance in a case where a semiconductor substrate having a metal film subjected to chemical mechanical polishing was subjected to cleaning was evaluated.

### [Evaluation of Cleaning Performance]

100 mL of each of the compositions immediately after being prepared in Preparation Example 1 was fractionated and diluted with ultrapure water at a dilution ratio (in terms of mass ratio) of each of the compositions shown in Table 1 described later to prepare a sample of a diluted liquid for cleaning performance evaluation.

All of the diluted liquids of the prepared compositions 101 to 153 had a pH in a range of 5.5 to 7.0 at 25° C.

In addition, in the preparation of diluted liquids of the compositions 154 to 221, any one of potassium hydroxide (manufactured by FUJIFILM Wako Pure Chemical Corporation) or sulfuric acid (manufactured by FUJIFILM Wako Pure Chemical Corporation) was added as necessary to the diluted liquid as a pH adjusting agent, and then the pH of the diluted liquid at 25° C. was adjusted to a numerical value shown in Table 1 described later.

A polishing liquid obtained by adding, to a CMP slurry (product name: “W2000”, manufactured by Cabot Corporation), 2% by mass of hydrogen peroxide with respect to the total mass of the slurry was used, and a silicon wafer (diameter: 12 inches) having, on a surface, a CVD-W film (tungsten film) having a film thickness of 5,000 Å was subjected to a CMP treatment under the following conditions, by using FREX300S-II (a polishing device, manufactured by Ebara Corporation).
Table rotation speed: 80 rpm
Head rotation speed: 78 rpm
Polishing pressure: 120 hPa
Polishing pad: “IC1400”, manufactured by Rodel Nitta Co., Ltd.
Supply rate of polishing liquid: 250 mL/min
Polishing time: 60 seconds

Using the sample of each diluted liquid adjusted to room temperature (25° C.) as a cleaning liquid, the polished surface of the wafer subjected to the CMP treatment was subjected to scrub cleaning for 30 seconds. Thereafter, the wafer subjected to the cleaning was rinsed with water and dried (dried out).

The polished surface of the obtained wafer was examined with a defect examination device (“ComPLUS 2”, manufactured by APPLIED MATERIALS, INC.) to count the number of defects having a length of 0.1 μm or more on the polished surface.

From the results of the obtained number of defects, the cleaning performance of the sample of each diluted liquid with respect to the semiconductor substrate was evaluated based on the following standards. In terms of practical use, an evaluation of “5” or more is desirable.

### (Evaluation Standards for Cleaning Performance)

8: The number of defects per wafer was less than 20.
7: The number of defects per wafer was 20 or more and less than 30.
6: The number of defects per wafer was 30 or more and less than 40.
5: The number of defects per wafer was 40 or more and less than 50.
4: The number of defects per wafer was 50 or more and less than 60.
3: The number of defects per wafer was 60 or more and less than 80.
2: The number of defects per wafer was 80 or more and less than 100.
1: The number of defects per wafer was 100 or more.

The above-described cleaning performance was evaluated, and the number of defects was counted.

Next, each diluted liquid that was not used in the above-described evaluation test for the cleaning properties was put into a container made of high-density polyethylene (HDPE) and stored in a clean room at 23±2° C. for 1 week. Using each diluted liquid after storage, the cleaning performance of the diluted liquid with respect to the semiconductor substrate was evaluated in the same manner as in the above-described method.

### [Evaluation of Corrosiveness of Tungsten]

Each composition prepared in Example 1 was fractionated and diluted with ultrapure water at a dilution ratio (in terms of mass ratio) of each of the compositions shown in Table 1 described later to prepare a sample (200 g) of a diluted liquid for evaluating anticorrosion properties.

In the same manner as described above, in the preparation of diluted liquids of the compositions 154 to 221, any one of potassium hydroxide (manufactured by FUJIFILM Wako Pure Chemical Corporation) or sulfuric acid (manufactured by FUJIFILM Wako Pure Chemical Corporation) was added as necessary to the diluted liquid as a pH adjusting agent, and then the pH of the diluted liquid at 25° C. was adjusted to a numerical value shown in Table 1 described later.

A wafer (diameter: 12 inches) having a metal film consisting of tungsten (W) on the surface was cut to prepare a 2 cm Q wafer coupon. The thickness of each metal film was 100 nm. The wafer coupon was immersed in a sample (temperature: 25° C.) of the diluted liquid prepared by the above method, and the immersion treatment was carried out for 30 minutes while carrying out stirring at a stirring rotation speed of 250 rpm.

From the difference in the thickness of the metal film which was measured before and after the immersion treatment, the film thickness of the metal film dissolved by the immersion treatment was calculated, and the corrosion rate of the metal film per unit time (unit: A/min) was calculated.

From the obtained corrosion rate of the metal film, the corrosiveness of each diluted liquid with respect to tungsten was evaluated according to the following evaluation standards. The evaluation results are shown in Table 1.

It is noted that the lower the corrosion rate of W, the more excellent the corrosion inhibition performance with respect to tungsten. In terms of practical use, an evaluation of “6” or more is desirable.

### (Evaluation Standards for W Corrosiveness)

8: The corrosion rate was 0.3 Å/min or less.
7: The corrosion rate was more than 0.3 Å/min and 0.4 Å/min or less.
6: The corrosion rate was more than 0.4 Å/min and 0.5 Å/min or less.
5: The corrosion rate was more than 0.5 Å/min and 0.6 Å/min or less.
4: The corrosion rate was more than 0.6 Å/min and 0.7 Å/min or less.
3: The corrosion rate was more than 0.7 Å/min and 0.8 Å/min or less.
2: The corrosion rate was more than 0.8 Å/min and less than 1.0 Å/min.
1: The corrosion rate was 1.0 Å/min or more.

Table 1 shows the composition and physical properties of each composition, the physical properties of the diluted liquid, and the evaluation results according to the above-described evaluation.

In the table, the notation of “-” indicates that the component corresponding to the column is not included in the composition.

The column of “Content (% by mass)” indicates the content (unit: % by mass) of each component with respect to the total mass of the composition. It is noted that the content of each component in the table indicates a content of each component as a compound.

The numerical value in the column of “Ratio A/B” indicates a mass ratio of the content of the antibacterial agent to the content of the organic acid (content of antibacterial agent/content of organic acid), and the numerical value in the column of “Ratio A/C” indicates a mass ratio of the content of the antibacterial agent to the content of the organic amine (content of antibacterial agent/content of organic amine).

“Residual part” in the column of “Water” indicates that a component other than the components shown in the table in each composition is water.

The numerical values in the column of “pH” and the column of “Electric conductivity (S/m)” respectively indicate the pH and the electric conductivity (unit: S/m) of each of the composition and the diluted liquid at 25° C., which are measured with the above-described measuring instrument.

The column of “Dilution ratio” of “Diluted liquid” indicates a dilution ratio (in terms of mass ratio) of the diluted liquid used in each evaluation test to the composition.

TABLE 1

| | Composition and physical properties of composition | | | | | | | | | |
|---|---|---|---|---|---|---|---|---|---|---|
| | Antibacterial agent | | Organic acid | | | Organic amine | | | Chelating agent | |
| | | Content | | Content | | | Content | | | Content |
| Table 1 | | (% by | | (% by | Ratio | | (% by | Ratio | | (% by |
| (1-1) | Kind | mass) | Kind | mass) | A/B | Kind | mass) | A/C | Kind | mass) |
| Composition 101 | Benzethonium | 0.05 | Tartaric acid | 0.5 | 0.10 | DMAMP | 4.8 | 0.01 | DEPPO | 3.0 |
| | chloride | | | | | | | | | |
| Composition 102 | Sorbic acid | 0.05 | Tartaric acid | 0.5 | 0.10 | DMAMP | 4.9 | 0.01 | HEDPO | 3.0 |
| Composition 103 | Sorbic acid | 0.05 | Tartaric acid | 0.5 | 0.10 | Tris | 5.1 | 0.01 | HEDPO | 3.0 |
| Composition 104 | Sorbic acid | 0.05 | Tartaric acid | 0.5 | 0.10 | AMP | 4.9 | 0.01 | HEDPO | 3.0 |
| Composition 105 | Sorbic acid | 0.05 | Tartaric acid | 0.5 | 0.10 | Tris | 0.9 | 0.06 | — | — |
| Composition 106 | Dehydroacetic | 0.05 | Tartaric acid | 0.5 | 0.10 | DMAMP | 4.9 | 0.01 | HEDPO | 3.0 |
| | acid | | | | | | | | | |
| Composition 107 | Dehydroacetic | 0.05 | Tartaric acid | 0.5 | 0.10 | Tris | 5.0 | 0.01 | HEDPO | 3.0 |
| | acid | | | | | | | | | |
| Composition 108 | Dehydroacetic | 0.05 | Tartaric acid | 0.5 | 0.10 | AMP | 3.7 | 0.01 | HEDPO | 3.0 |
| | acid | | | | | | | | | |
| Composition 109 | Cresol | 0.05 | Tartaric acid | 0.5 | 0.10 | DMAMP | 4.8 | 0.01 | HEDPO | 3.0 |
| Composition 110 | Chlorhexidine | 0.05 | Tartaric acid | 0.5 | 0.10 | DMAMP | 4.8 | 0.01 | HEDPO | 3.0 |
| | gluconate | | | | | | | | | |
| Composition 111 | Tolylfluanid | 0.05 | Tartaric acid | 0.5 | 0.10 | DMAMP | 4.8 | 0.01 | HEDPO | 3.0 |
| Composition 112 | Peracetic acid | 0.05 | Tartaric acid | 0.5 | 0.10 | DMAMP | 4.9 | 0.01 | HEDPO | 3.0 |
| Composition 113 | MIT | 0.05 | Malic acid | 0.5 | 0.10 | Tris | 5.1 | 0.01 | HEDPO | 3.0 |
| Composition 114 | MIT | 0.05 | Tartaric acid | 0.5 | 0.10 | Tris | 5.0 | 0.01 | HEDPO | 3.0 |
| Composition 115 | MIT | 0.005 | Citric acid | 0.5 | 0.01 | Tris | 5.1 | 0.001 | HEDPO | 3.0 |
| Composition 116 | MIT | 0.05 | Citric acid | 0.5 | 0.10 | Tris | 5.1 | 0.01 | HEDPO | 3.0 |
| Composition 117 | MIT | 0.1 | Citric acid | 0.5 | 0.20 | Tris | 5.1 | 0.02 | HEDPO | 3.0 |
| Composition 118 | MIT | 0.5 | Citric acid | 5.0 | 0.10 | Tris | 13.7 | 0.04 | HEDPO | 3.0 |
| Composition 119 | MIT | 0.05 | Citric acid | 0.5 | 0.10 | Tris | 5.1 | 0.01 | DEPPO | 3.0 |
| Composition 120 | MIT | 0.05 | Citric acid | 0.5 | 0.10 | DEA | 4.5 | 0.01 | HEDPO | 3.0 |
| Composition 121 | MIT | 0.05 | Citric acid | 0.5 | 0.10 | DMAMP | 5.0 | 0.01 | HEDPO | 3.0 |
| Composition 122 | MIT | 0.05 | Citric acid | 0.5 | 0.10 | TEA | 6.3 | 0.01 | HEDPO | 3.0 |
| Composition 123 | MIT | 0.05 | Citric acid | 0.5 | 0.10 | MEA | 2.6 | 0.02 | HEDPO | 3.0 |
| Composition 124 | MIT | 0.05 | Citric acid | 0.5 | 0.10 | AMP | 3.8 | 0.01 | HEDPO | 3.0 |
| Composition 125 | MIT | 0.05 | Oxalic acid | 0.5 | 0.10 | DMAMP | 3.0 | 0.02 | DEPPO | 3.0 |
| Composition 126 | MIT | 0.05 | Malonic acid | 0.5 | 0.10 | DMAMP | 2.9 | 0.02 | DEPPO | 3.0 |
| Composition 127 | MIT | 0.05 | Succinic acid | 0.5 | 0.08 | DMAMP | 3.5 | 0.01 | NTPO | 3.0 |
| | | | Trimellitic acid | 0.1 | | | | | | |
| Composition 128 | MIT | 0.05 | Gluconic acid | 0.6 | 0.08 | DMAMP | 2.3 | 0.02 | EDTPO | 3.0 |
| Composition 129 | MIT | 0.05 | Maleic acid | 0.5 | 0.10 | DMAMP | 3.9 | 0.01 | EDTA | 3.0 |
| Composition 130 | MIT | 0.05 | Glutaric acid | 0.7 | 0.07 | DMAMP | 3.5 | 0.01 | DTPA | 3.0 |
| | | | | | | | | | L-Arginine | 0.1 |

TABLE 2

| | Composition and physical properties of composition | | | | | | | Evaluation | | |
|---|---|---|---|---|---|---|---|---|---|---|
| | Other components | | | | | Diluted liquid | | Cleaning | Cleaning | |
| | | Content | | | Electric | | Electric | performance | performance | |
| Table 1 | | (% by | | | conductivity | Dilution | conductivity | after | after | W |
| (1-2) | Kind | mass) | Water | pH | (S/m) | ratio | (S/m) | preparation | storage | corrosiveness |
| Composition 101 | — | — | Residual | 6.2 | 1.295 | 100 | 0.090 | 6 | 6 | 7 |
| | | | part | | | | | | | |
| Composition 102 | — | — | Residual | 6.2 | 1.267 | 100 | 0.088 | 7 | 7 | 6 |
| | | | part | | | | | | | |
| Composition 103 | — | — | Residual | 6.0 | 1.267 | 100 | 0.088 | 7 | 7 | 6 |
| | | | part | | | | | | | |
| Composition 104 | — | — | Residual | 6.0 | 1.481 | 100 | 0.103 | 6 | 6 | 6 |
| | | | part | | | | | | | |
| Composition 105 | — | — | Residual | 6.8 | 0.225 | 100 | 0.047 | 5 | 5 | 6 |
| | | | part | | | | | | | |
| Composition 106 | — | — | Residual | 6.3 | 1.264 | 100 | 0.088 | 7 | 6 | 6 |
| | | | part | | | | | | | |
| Composition 107 | — | — | Residual | 6.0 | 1.264 | 100 | 0.088 | 7 | 6 | 6 |
| | | | part | | | | | | | |
| Composition 108 | — | — | Residual | 6.0 | 1.264 | 100 | 0.088 | 7 | 6 | 6 |
| | | | part | | | | | | | |
| Composition 109 | — | — | Residual | 6.2 | 1.259 | 100 | 0.088 | 6 | 6 | 6 |
| | | | part | | | | | | | |
| Composition 110 | — | — | Residual | 6.3 | 1.259 | 100 | 0.088 | 6 | 6 | 6 |
| | | | part | | | | | | | |
| Composition 111 | — | — | Residual | 6.2 | 1.259 | 100 | 0.088 | 7 | 7 | 6 |
| | | | part | | | | | | | |
| Composition 112 | — | — | Residual | 6.2 | 1.270 | 100 | 0.089 | 7 | 7 | 6 |
| | | | part | | | | | | | |
| Composition 113 | — | — | Residual | 6.0 | 1.285 | 100 | 0.090 | 7 | 7 | 6 |
| | | | part | | | | | | | |
| Composition 114 | — | — | Residual | 6.0 | 1.259 | 100 | 0.088 | 7 | 7 | 6 |
| | | | part | | | | | | | |
| Composition 115 | — | — | Residual | 5.9 | 1.297 | 100 | 0.090 | 8 | 7 | 6 |
| | | | part | | | | | | | |
| Composition 116 | — | — | Residual | 5.9 | 1.297 | 100 | 0.090 | 8 | 8 | 6 |
| | | | part | | | | | | | |
| Composition 117 | — | — | Residual | 5.9 | 1.297 | 100 | 0.090 | 8 | 8 | 6 |
| | | | part | | | | | | | |
| Composition 118 | — | — | Residual | 5.9 | 1.587 | 200 | 0.251 | 7 | 7 | 6 |
| | | | part | | | | | | | |
| Composition 119 | — | — | Residual | 6.0 | 1.026 | 100 | 0.072 | 7 | 7 | 6 |
| | | | part | | | | | | | |
| Composition 120 | — | — | Residual | 6.0 | 1.297 | 100 | 0.090 | 7 | 7 | 6 |
| | | | part | | | | | | | |
| Composition 121 | — | — | Residual | 6.2 | 1.297 | 100 | 0.090 | 8 | 8 | 6 |
| | | | part | | | | | | | |
| Composition 122 | — | — | Residual | 6.0 | 1.297 | 100 | 0.090 | 7 | 7 | 6 |
| | | | part | | | | | | | |
| Composition 123 | — | — | Residual | 6.0 | 1.297 | 100 | 0.090 | 7 | 7 | 6 |
| | | | part | | | | | | | |
| Composition 124 | DBS | 0.05 | Residual | 5.8 | 1.299 | 100 | 0.091 | 7 | 7 | 7 |
| | | | part | | | | | | | |
| Composition 125 | PAA | 0.1 | Residual | 5.7 | 1.118 | 100 | 0.078 | 7 | 7 | 8 |
| | | | part | | | | | | | |
| Composition 126 | PSS | 0.1 | Residual | 5.8 | 1.069 | 100 | 0.075 | 7 | 7 | 8 |
| | | | part | | | | | | | |
| Composition 127 | — | — | Residual | 5.8 | 1.131 | 100 | 0.079 | 8 | 8 | 7 |
| | | | part | | | | | | | |
| Composition 128 | Adenine | 0.1 | Residual | 6.1 | 0.817 | 100 | 0.057 | 7 | 7 | 7 |
| | | | part | | | | | | | |
| Composition 129 | Xanthine | 0.1 | Residual | 6.1 | 1.184 | 100 | 0.083 | 7 | 7 | 7 |
| | | | part | | | | | | | |
| Composition 130 | — | — | Residual | 6.0 | 1.201 | 100 | 0.084 | 6 | 6 | 8 |
| | | | part | | | | | | | |

TABLE 3

| | Composition and physical properties of composition | | | | | | | | | |
|---|---|---|---|---|---|---|---|---|---|---|
| | Antibacterial agent | | Organic acid | | | Organic amine | | | Chelating agent | |
| | | Content | | Content | | | Content | | | Content |
| Table 1 | | (% by | | (% by | Ratio | | (% by | Ratio | | (% by |
| (2-1) | Kind | mass) | Kind | mass) | A/B | Kind | mass) | A/C | Kind | mass) |
| Composition 131 | MIT | 0.05 | Lactic acid | 0.3 | 0.17 | DMAMP | 4.3 | 0.01 | Phytic acid | 3.0 |
| | | | | | | | | | L-Lysine | 0.1 |
| Composition 132 | MIT | 0.05 | Methanesulfonic | 0.5 | 0.10 | DMAMP | 4.7 | 0.01 | HEDPO | 3.0 |
| | | | acid | | | | | | | |
| Composition 133 | MIT | 0.041 | Malic acid | 0.5 | 0.10 | DMAMP | 4.9 | 0.01 | HEDPO | 3.0 |
| | OIT | 0.009 | | | | | | | | |
| Composition 134 | MIT | 0.041 | Tartaric acid | 0.5 | 0.10 | DMAMP | 4.8 | 0.01 | HEDPO | 3.0 |
| | OIT | 0.009 | | | | | | | | |
| Composition 135 | MIT | 0.041 | Citric acid | 0.5 | 0.10 | DMAMP | 5.0 | 0.01 | HEDPO | 3.0 |
| | OIT | 0.009 | | | | | | | | |
| Composition 136 | MIT | 0.041 | Succinic acid | 0.5 | 0.10 | DMAMP | 5.1 | 0.01 | HEDPO | 3.0 |
| | OIT | 0.009 | | | | | | | | |
| Composition 137 | BIT | 0.05 | Malic acid | 0.5 | 0.10 | DMAMP | 4.9 | 0.01 | HEDPO | 3.0 |
| Composition 138 | BIT | 0.05 | Tartaric acid | 0.5 | 0.10 | DMAMP | 4.8 | 0.01 | HEDPO | 3.0 |
| Composition 139 | BIT | 0.05 | Citric acid | 0.5 | 0.10 | DMAMP | 5.0 | 0.01 | HEDPO | 3.0 |
| Composition 140 | BIT | 0.05 | Succinic acid | 0.5 | 0.10 | DMAMP | 5.1 | 0.01 | HEDPO | 3.0 |
| Composition 141 | MIT | 0.05 | Citric acid | 0.5 | 0.10 | Tris | 5.1 | 0.01 | HEDPO | 3.0 |
| Composition 142 | Sorbic acid | 0.05 | Citric acid | 3.0 | 0.02 | Tris | 4.7 | 0.01 | — | — |
| Composition 143 | Sorbic acid | 0.05 | Citric acid | 3.0 | 0.02 | Tris | 5.1 | 0.01 | L-Arginine | 0.5 |
| | | | Trimellitic acid | 0.3 | | | | | | |
| Composition 144 | Sorbic acid | 0.05 | Citric acid | 3.0 | 0.02 | Tris | 5.1 | 0.01 | L-Arginine | 0.5 |
| Composition 145 | Sorbic acid | 0.025 | Citric acid | 0.015 | 0.63 | Tris | 0.1 | 0.42 | L-Arginine | 0.025 |
| Composition 146 | Sorbic acid | 0.025 | Citric acid | 0.015 | 0.63 | Tris | 0.1 | 0.42 | L-Arginine | 0.025 |
| Composition 147 | Sorbic acid | 0.025 | Citric acid | 0.015 | 0.63 | Tris | 0.1 | 0.42 | L-Arginine | 0.025 |
| Composition 148 | Sorbic acid | 0.025 | Citric acid | 0.015 | 0.63 | Tris | 0.1 | 0.42 | L-Arginine | 0.025 |
| Composition 149 | Sorbic acid | 0.025 | Citric acid | 0.015 | 0.63 | Tris | 0.1 | 0.42 | L-Arginine | 0.025 |
| Composition 150 | Sorbic acid | 0.025 | Citric acid | 0.015 | 0.63 | Tris | 0.1 | 0.42 | L-Arginine | 0.025 |
| Composition 151 | Sorbic acid | 0.05 | Citric acid | 3.0 | 0.02 | Tris | 6.2 | 0.01 | HEDPO | 0.8 |
| | | | Trimellitic acid | 0.3 | | | | | L-Arginine | 0.5 |
| Composition 152 | Sorbic acid | 0.05 | Citric acid | 1.8 | 0.05 | Tris | 4.2 | 0.01 | HEDPO | 0.8 |
| | | | Trimellitic acid | 0.2 | | | | | L-Arginine | 0.5 |
| Composition 153 | Sorbic acid | 0.05 | Citric acid | 0.03 | 0.63 | Tris | 0.1 | 0.42 | L-Arginine | 0.025 |
| | | | Trimellitic acid | 0.05 | | | | | | |
| Comparative | MIT | 0.05 | Citric acid | 0.5 | 0.10 | — | 0 | — | HEDPO | 3.0 |
| composition 1 | | | | | | | | | | |
| Comparative | — | 0 | Tartaric acid | 0.5 | 0.00 | DMAMP | 3.8 | 0.00 | DEPPO | 3.0 |
| composition 2 | | | | | | | | | | |

TABLE 4

| | Composition and physical properties of composition | | | | | | | Evaluation | | |
|---|---|---|---|---|---|---|---|---|---|---|
| | Other components | | | | | Diluted liquid | | Cleaning | Cleaning | |
| | | Content | | | Electric | | Electric | performance | performance | |
| Table 1 | | (% by | | | conductivity | Dilution | conductivity | after | after | W |
| (2-2) | Kind | mass) | Water | pH | (S/m) | ratio | (S/m) | preparation | storage | corrosiveness |
| Composition 131 | — | — | Residual | 5.5 | 1.166 | 50 | 0.163 | 6 | 6 | 8 |
| | | | part | | | | | | | |
| Composition 132 | — | — | Residual | 5.7 | 1.212 | 100 | 0.085 | 5 | 5 | 6 |
| | | | part | | | | | | | |
| Composition 133 | — | — | Residual | 6.2 | 1.285 | 100 | 0.090 | 7 | 7 | 6 |
| | | | part | | | | | | | |
| Composition 134 | — | — | Residual | 6.1 | 1.259 | 100 | 0.088 | 7 | 7 | 6 |
| | | | part | | | | | | | |
| Composition 135 | — | — | Residual | 6.3 | 1.297 | 100 | 0.090 | 7 | 7 | 6 |
| | | | part | | | | | | | |
| Composition 136 | — | — | Residual | 6.2 | 1.318 | 100 | 0.092 | 7 | 7 | 6 |
| | | | part | | | | | | | |
| Composition 137 | — | — | Residual | 6.2 | 1.285 | 100 | 0.090 | 7 | 7 | 6 |
| | | | part | | | | | | | |
| Composition 138 | — | — | Residual | 6.3 | 1.259 | 100 | 0.088 | 7 | 7 | 6 |
| | | | part | | | | | | | |
| Composition 139 | — | — | Residual | 6.3 | 1.297 | 100 | 0.090 | 7 | 7 | 6 |
| | | | part | | | | | | | |
| Composition 140 | — | — | Residual | 6.3 | 1.318 | 100 | 0.092 | 7 | 7 | 6 |
| | | | part | | | | | | | |
| Composition 141 | DSBMA | 0.001 | Residual | 6.3 | 1.297 | 100 | 0.091 | 8 | 8 | 7 |
| | | | part | | | | | | | |
| Composition 142 | — | — | Residual | 6.0 | 0.982 | 200 | 0.095 | 6 | 6 | 6 |
| | | | part | | | | | | | |
| Composition 143 | — | — | Residual | 6.0 | 1.450 | 200 | 0.185 | 7 | 7 | 8 |
| | | | part | | | | | | | |
| Composition 144 | — | — | Residual | 6.0 | 1.250 | 200 | 0.155 | 6 | 6 | 8 |
| | | | part | | | | | | | |
| Composition 145 | MMB | 25 | Residual | 6.0 | 0.120 | 10 | 0.080 | 7 | 7 | 8 |
| | | | part | | | | | | | |
| Composition 146 | EGBE | 25 | Residual | 6.0 | 0.125 | 10 | 0.085 | 7 | 7 | 8 |
| | | | part | | | | | | | |
| Composition 147 | DMSO | 25 | Residual | 6.0 | 0.115 | 10 | 0.085 | 7 | 7 | 8 |
| | | | part | | | | | | | |
| Composition 148 | DPGBE | 25 | Residual | 6.0 | 0.115 | 10 | 0.090 | 7 | 7 | 8 |
| | | | part | | | | | | | |
| Composition 149 | EGEEA | 25 | Residual | 6.0 | 0.110 | 10 | 0.080 | 7 | 7 | 8 |
| | | | part | | | | | | | |
| Composition 150 | MMB | 12.5 | Residual | 6.0 | 0.105 | 10 | 0.085 | 7 | 7 | 8 |
| | DMSO | 12.5 | part | | | | | | | |
| Composition 151 | — | — | Residual | 6.0 | 1.520 | 200 | 0.217 | 8 | 8 | 8 |
| | | | part | | | | | | | |
| Composition 152 | — | — | Residual | 6.0 | 1.119 | 200 | 0.147 | 8 | 8 | 8 |
| | | | part | | | | | | | |
| Composition 153 | — | — | Residual | 6.0 | 0.120 | 10 | 0.090 | 7 | 7 | 8 |
| | | | part | | | | | | | |
| Comparative | — | — | Residual | 1.2 | 1.152 | 100 | 0.039 | 4 | 4 | 8 |
| composition 1 | | | part | | | | | | | |
| Comparative | — | — | Residual | 6.8 | 1.733 | 100 | 0.059 | 7 | 4 | 6 |
| composition 2 | | | part | | | | | | | |

TABLE 5

| | Composition and physical properties of composition | | | | | | | | | |
|---|---|---|---|---|---|---|---|---|---|---|
| | Antibacterial agent | | Organic acid | | | Organic amine | | | Chelating agent | |
| | | Content | | Content | | | Content | | | Content |
| Table 1 | | (% by | | (% by | Ratio | | (% by | Ratio | | (% by |
| (3-1) | Kind | mass) | Kind | mass) | A/B | Kind | mass) | A/C | Kind | mass) |
| Composition 154 | Sorbic acid | 0.025 | Tartaric acid | 0.9 | 0.03 | Tris | 2.2 | 0.01 | EDTPO | 0.4 |
| Composition 155 | Sorbic acid | 0.025 | Tartaric acid | 0.9 | 0.03 | DMAMP | 2.2 | 0.01 | NTPO | 0.4 |
| Composition 156 | Sorbic acid | 0.025 | Tartaric acid | 0.3 | 0.08 | Tris | 0.5 | 0.05 | L-Lysine | 0.3 |
| Composition 157 | Sorbic acid | 0.025 | Citric acid | 0.9 | 0.03 | Tris | 2.2 | 0.01 | EDTA | 0.8 |
| Composition 158 | Sorbic acid | 0.05 | Citric acid | 0.04 | 1.32 | Tris | 0.7 | 0.07 | HEDPO | 0.4 |
| Composition 159 | Sorbic acid | 0.005 | Citric acid | 0.04 | 0.13 | Tris | 0.7 | 0.01 | HEDPO | 0.4 |
| Composition 160 | Sorbic acid | 0.0005 | Citric acid | 0.04 | 0.01 | AMP | 1.0 | 0.00 | HEDPO | 0.4 |
| Composition 161 | Sorbic acid | 0.05 | Maleic acid | 0.04 | 1.32 | Tris | 1.0 | 0.05 | HEDPO | 0.4 |
| Composition 162 | Sorbic acid | 0.1 | Maleic acid | 1.2 | 0.08 | DMAMP | 2.0 | 0.05 | L-Lysine | 1.0 |
| Composition 163 | Sorbic acid | 0.01 | Succinic acid | 0.04 | 0.26 | AMP | 2.0 | 0.01 | HEDPO | 0.4 |
| Composition 164 | Sorbic acid | 0.05 | Citric acid | 1.6 | 0.03 | Tris | 4.2 | 0.01 | HEDPO | 0.8 |
| | | | Trimellitic | 0.2 | | | | | | |
| | | | acid | | | | | | | |
| Composition 165 | Sorbic acid | 0.05 | Citric acid | 3 | 0.02 | Tris | 5.1 | 0.01 | L-Arginine | 0.5 |
| | | | TMA | 0.3 | | | | | | |
| Composition 166 | Sorbic acid | 0.05 | Citric acid | 0.6 | 0.06 | Tris | 1.0 | 0.05 | L-Arginine | 0.5 |
| | | | Trimellitic | 0.2 | | | | | | |
| | | | acid | | | | | | | |
| Composition 167 | Sorbic acid | 0.5 | Citric acid | 0.3 | 0.63 | Tris | 1.6 | 0.31 | L-Arginine | 0.3 |
| | | | Trimellitic | 0.5 | | | | | | |
| | | | acid | | | | | | | |
| Composition 168 | Sorbic acid | 0.05 | Citric acid | 3 | 0.02 | Tris | 5.1 | 0.01 | L-Lysine | 0.5 |
| | | | Trimellitic | 0.3 | | | | | | |
| | | | acid | | | | | | | |
| Composition 169 | Sorbic acid | 0.05 | Citric acid | 0.6 | 0.06 | Tris | 1.0 | 0.05 | L-Histidine | 0.5 |
| | | | Trimellitic | 0.2 | | | | | | |
| | | | acid | | | | | | | |
| Composition 170 | Sorbic acid | 0.5 | Citric acid | 0.3 | 0.63 | Tris | 1.6 | 0.31 | DEPPO | 0.3 |
| | | | Trimellitic | 0.5 | | | | | | |
| | | | acid | | | | | | | |
| Composition 171 | Sorbic acid | 0.05 | Citric acid | 6 | 0.01 | DMAMP | 10.2 | 0.00 | L-Lysine | 1.0 |
| | | | Trimellitic | 0.6 | | | | | | |
| | | | acid | | | | | | | |
| Composition 172 | Sorbic acid | 0.05 | Phthalic acid | 6 | 0.01 | MEA | 10.2 | 0.00 | L-Lysine | 1.0 |
| | | | Oxalic acid | 0.6 | | | | | | |
| Composition 173 | Dehydroacetic | 0.1 | Citric acid | 3.6 | 0.03 | AMP | 8.3 | 0.01 | DEPPO | 1.7 |
| | acid | | | | | | | | | |
| Composition 174 | Dehydroacetic | 0.025 | Citric acid | 0.9 | 0.03 | MEA | 2.2 | 0.01 | HEDPO | 0.4 |
| | acid | | | | | | | | | |
| Composition 175 | Dehydroacetic | 1.0 | Maleic acid | 0.6 | 1.67 | MEA | 3.2 | 0.31 | L-Histidine | 0.5 |
| | acid | | | | | | | | | |
| Composition 176 | Dehydroacetic | 0.05 | Phthalic acid | 1.5 | 0.03 | Tris | 2.6 | 0.02 | L-Histidine | 0.3 |
| | acid | | Oxalic acid | 0.15 | | | | | | |
| Composition 177 | Dehydroacetic | 1.0 | Phthalic acid | 0.55 | 1.67 | DMAMP | 3.2 | 0.31 | L-Lysine | 0.5 |
| | acid | | Oxalic acid | 0.05 | | | | | | |
| Composition 178 | Dehydroacetic | 1.0 | Phthalic acid | 0.55 | 1.67 | DMAMP | 3.2 | 0.31 | L-Arginine | 0.5 |
| | acid | | Oxalic acid | 0.05 | | | | | | |
| Composition 179 | MIT | 0.2 | Citric acid | 0.04 | 5.26 | Tris | 0.7 | 0.29 | HEDPO | 0.4 |
| Composition 180 | MIT | 0.01 | Citric acid | 0.04 | 0.26 | Tris | 0.7 | 0.01 | HEDPO | 0.4 |
| Composition 181 | MIT | 0.2 | Maleic acid | 0.04 | 5.26 | Tris | 0.7 | 0.29 | HEDPO | 0.4 |
| Composition 182 | MIT | 0.2 | Gluconic acid | 0.04 | 5.26 | Tris | 0.7 | 0.29 | HEDPO | 0.4 |
| Composition 183 | MIT | 0.2 | Tartaric acid | 0.04 | 5.26 | Tris | 0.7 | 0.29 | HEDPO | 0.4 |
| Composition 184 | MIT | 0.01 | Citric acid | 0.04 | 0.26 | AMP | 0.7 | 0.01 | HEDPO | 0.4 |
| Composition 185 | MIT | 0.2 | Maleic acid | 0.04 | 5.26 | MEA | 0.7 | 0.29 | HEDPO | 0.4 |
| Composition 186 | MIT | 0.2 | Gluconic acid | 0.04 | 5.26 | DMAMP | 0.7 | 0.29 | HEDPO | 0.4 |
| Composition 187 | OIT | 0.1 | Citric acid | 0.04 | 2.63 | AMP | 2.0 | 0.05 | EDTA | 0.4 |
| Composition 188 | OIT | 0.05 | Citric acid | 0.04 | 1.32 | Tris | 2.0 | 0.03 | DEPPO | 0.4 |
| Composition 189 | OIT | 0.01 | Citric acid | 0.04 | 0.26 | Tris | 2.0 | 0.01 | HEDPO | 0.4 |
| Composition 190 | OIT | 0.2 | Gluconic acid | 0.04 | 5.26 | Tris | 0.7 | 0.29 | DEPPO | 0.4 |

TABLE 6

| | Composition and physical properties of composition | | | | | | | | Evaluation | | |
|---|---|---|---|---|---|---|---|---|---|---|---|
| | Other components | | | | | Diluted liquid | | | Cleaning | Cleaning | |
| | | Content | | | Electric | | Electric | | performance | performance | |
| Table 1 | | (% by | | | conductivity | Dilution | conductivity | | after | after | W |
| (3-2) | Kind | mass) | Water | pH | (S/m) | ratio | (S/m) | pH | preparation | storage | corrosiveness |
| Composition | — | — | Residual | 6.0 | 0.875 | 100 | 0.060 | 6.4 | 8 | 8 | 8 |
| 154 | | | part | | | | | | | | |
| Composition | — | — | Residual | 6.0 | 0.886 | 100 | 0.063 | 6.4 | 8 | 8 | 8 |
| 155 | | | part | | | | | | | | |
| Composition | — | — | Residual | 6.0 | 0.422 | 100 | 0.009 | 6.1 | 8 | 8 | 8 |
| 156 | | | part | | | | | | | | |
| Composition | — | — | Residual | 6.0 | 0.824 | 100 | 0.057 | 6.4 | 8 | 8 | 8 |
| 157 | | | part | | | | | | | | |
| Composition | DBS | 0.5 | Residual | 6.0 | 0.353 | 100 | 0.012 | 6.4 | 7 | 7 | 7 |
| 158 | | | part | | | | | | | | |
| Composition | DBS | 0.5 | Residual | 6.0 | 0.349 | 100 | 0.012 | 6.4 | 7 | 7 | 7 |
| 159 | | | part | | | | | | | | |
| Composition | DBS | 1.0 | Residual | 6.0 | 0.663 | 100 | 0.013 | 6.6 | 7 | 7 | 7 |
| 160 | | | part | | | | | | | | |
| Composition | DBS | 2.0 | Residual | 6.3 | 0.453 | 100 | 0.013 | 6.5 | 7 | 7 | 7 |
| 161 | | | part | | | | | | | | |
| Composition | — | — | Residual | 6.0 | 1.186 | 100 | 0.022 | 6.4 | 8 | 8 | 8 |
| 162 | | | part | | | | | | | | |
| Composition | DBSA | 1.0 | Residual | 6.3 | 0.698 | 100 | 0.015 | 6.6 | 7 | 7 | 7 |
| 163 | | | part | | | | | | | | |
| Composition | — | — | Residual | 6.0 | 1.200 | 100 | 0.015 | 6.6 | 8 | 8 | 8 |
| 164 | | | part | | | | | | | | |
| Composition | — | — | Residual | 6.0 | 1.450 | 200 | 0.019 | 6.6 | 8 | 8 | 8 |
| 165 | | | part | | | | | | | | |
| Composition | — | — | Residual | 6.0 | 0.505 | 200 | 0.005 | 6.5 | 8 | 8 | 8 |
| 166 | | | part | | | | | | | | |
| Composition | — | — | Residual | 6.0 | 0.092 | 10 | 0.001 | 6.2 | 8 | 8 | 8 |
| 167 | | | part | | | | | | | | |
| Composition | — | — | Residual | 6.0 | 1.411 | 100 | 0.039 | 6.5 | 8 | 8 | 8 |
| 168 | | | part | | | | | | | | |
| Composition | — | — | Residual | 6.0 | 0.512 | 100 | 0.012 | 6.1 | 8 | 8 | 8 |
| 169 | | | part | | | | | | | | |
| Composition | — | — | Residual | 6.0 | 0.092 | 10 | 0.001 | 6.2 | 8 | 8 | 8 |
| 170 | | | part | | | | | | | | |
| Composition | — | — | Residual | 6.0 | 1.365 | 100 | 0.078 | 6.4 | 8 | 8 | 8 |
| 171 | | | part | | | | | | | | |
| Composition | — | — | Residual | 6.0 | 0.888 | 200 | 0.022 | 6.5 | 8 | 8 | 8 |
| 172 | | | part | | | | | | | | |
| Composition | — | — | Residual | 6.0 | 0.905 | 100 | 0.028 | 6.5 | 8 | 8 | 8 |
| 173 | | | part | | | | | | | | |
| Composition | — | — | Residual | 6.0 | 1.215 | 100 | 0.041 | 6.7 | 8 | 8 | 8 |
| 174 | | | part | | | | | | | | |
| Composition | — | — | Residual | 6.0 | 1.223 | 50 | 0.057 | 6.2 | 8 | 8 | 8 |
| 175 | | | part | | | | | | | | |
| Composition | — | — | Residual | 6.0 | 1.127 | 100 | 0.022 | 6.3 | 8 | 8 | 8 |
| 176 | | | part | | | | | | | | |
| Composition | — | — | Residual | 6.0 | 1.615 | 30 | 0.030 | 6.1 | 8 | 8 | 8 |
| 177 | | | part | | | | | | | | |
| Composition | — | — | Residual | 6.0 | 1.583 | 30 | 0.052 | 6.1 | 8 | 8 | 8 |
| 178 | | | part | | | | | | | | |
| Composition | DBS | 0.5 | Residual | 6.3 | 0.382 | 100 | 0.005 | 6.6 | 7 | 7 | 7 |
| 179 | | | part | | | | | | | | |
| Composition | DBS | 0.5 | Residual | 6.3 | 0.381 | 100 | 0.005 | 6.6 | 7 | 7 | 7 |
| 180 | | | part | | | | | | | | |
| Composition | DBS | 0.5 | Residual | 6.3 | 0.336 | 100 | 0.008 | 6.6 | 7 | 7 | 7 |
| 181 | | | part | | | | | | | | |
| Composition | DBS | 0.5 | Residual | 6.3 | 0.336 | 100 | 0.008 | 6.6 | 7 | 7 | 7 |
| 182 | | | part | | | | | | | | |
| Composition | DBS | 0.5 | Residual | 6.3 | 0.337 | 100 | 0.009 | 6.5 | 7 | 7 | 7 |
| 183 | | | part | | | | | | | | |
| Composition | DBS | 0.5 | Residual | 6.3 | 0.336 | 100 | 0.008 | 6.6 | 7 | 7 | 7 |
| 184 | | | part | | | | | | | | |
| Composition | DBS | 0.5 | Residual | 6.3 | 0.336 | 100 | 0.008 | 6.6 | 7 | 7 | 7 |
| 185 | | | part | | | | | | | | |
| Composition | DBS | 0.5 | Residual | 6.3 | 0.365 | 100 | 0.011 | 6.6 | 7 | 7 | 7 |
| 186 | | | part | | | | | | | | |
| Composition | DBS | 0.5 | Residual | 6.3 | 0.365 | 100 | 0.011 | 6.6 | 7 | 7 | 7 |
| 187 | | | part | | | | | | | | |
| Composition | DBS | 1.0 | Residual | 6.3 | 0.402 | 100 | 0.014 | 6.6 | 7 | 7 | 7 |
| 188 | | | part | | | | | | | | |
| Composition | DBS | 2.0 | Residual | 6.3 | 0.812 | 100 | 0.018 | 6.5 | 7 | 7 | 7 |
| 189 | | | part | | | | | | | | |
| Composition | DBS | 0.5 | Residual | 6.3 | 0.365 | 100 | 0.011 | 6.6 | 7 | 7 | 7 |
| 190 | | | part | | | | | | | | |

TABLE 7

| | Composition and physical properties of composition | | | | | | | | | |
|---|---|---|---|---|---|---|---|---|---|---|
| | Antibacterial agent | | Organic acid | | | Organic amine | | | Chelating agent | |
| | | Content | | Content | | | Content | | | Content |
| Table 1 | | (% by | | (% by | Ratio | | (% by | Ratio | | (% by |
| (4-1) | Kind | mass) | Kind | mass) | A/B | Kind | mass) | A/C | Kind | mass) |
| Composition 191 | OIT | 0.01 | Gluconic acid | 0.04 | 0.26 | Tris | 0.7 | 0.01 | EDTA | 0.4 |
| Composition 192 | BIT | 0.1 | Tartaric acid | 2 | 0.05 | AMP | 2.2 | 0.05 | EDTA | 0.2 |
| Composition 193 | BIT | 0.25 | Tartaric acid | 0.15 | 1.67 | MEA | 0.8 | 0.31 | L-Arginine | 0.2 |
| Composition 194 | BIT | 0.25 | Tartaric acid | 0.15 | 1.67 | MEA | 0.8 | 0.31 | L-Lysine | 0.2 |
| Composition 195 | BIT | 0.2 | Citric acid | 0.04 | 5.26 | AMP | 0.7 | 0.29 | HEDPO | 0.4 |
| Composition 196 | BIT | 0.2 | Oxalic acid | 0.04 | 5.26 | AMP | 1.0 | 0.20 | HEDPO | 0.4 |
| Composition 197 | BIT | 0.05 | Maleic acid | 0.04 | 1.32 | AMP | 1.5 | 0.03 | DEPPO | 0.4 |
| Composition 198 | BIT | 0.05 | Maleic acid | 2 | 0.03 | Tris | 2.2 | 0.02 | EDTPO | 0.8 |
| Composition 199 | BIT | 0.25 | Phthalic acid | 0.13 | 1.67 | DMAMP | 0.8 | 0.31 | L-Histidine | 0.2 |
| | | | Oxalic acid | 0.02 | | | | | | |
| Composition 200 | BIT | 0.25 | Phthalic acid | 0.13 | 1.67 | AMP | 0.8 | 0.31 | L-Lysine | 0.2 |
| | | | Oxalic acid | 0.02 | | | | | | |
| Composition 201 | BIT | 0.25 | Phthalic acid | 0.13 | 1.67 | AMP | 0.8 | 0.31 | L-Arginine | 0.2 |
| | | | Oxalic acid | 0.02 | | | | | | |
| Composition 202 | Benzoic acid | 0.5 | Citric acid | 0.3 | 0.63 | Tris | 1.6 | 0.31 | L-Arginine | 0.3 |
| | | | Trimellitic | 0.5 | | | | | | |
| | | | acid | | | | | | | |
| Composition 203 | Benzoic acid | 0.05 | Citric acid | 3 | 0.02 | Tris | 5.1 | 0.01 | L-Arginine | 0.5 |
| | | | Trimellitic | 0.3 | | | | | | |
| | | | acid | | | | | | | |
| Composition 204 | Benzoic acid | 0.05 | Citric acid | 0.6 | 0.06 | Tris | 1 | 0.05 | L-Arginine | 0.5 |
| | | | Trimellitic | 0.2 | | | | | | |
| | | | acid | | | | | | | |
| Composition 205 | Benzoic acid | 0.5 | Citric acid | 0.3 | 0.63 | Tris | 1.6 | 0.31 | L-Arginine | 0.3 |
| | | | Trimellitic | 0.5 | | | | | | |
| | | | acid | | | | | | | |
| Composition 206 | Benzoic acid | 0.05 | Citric acid | 1.6 | 0.03 | Tris | 4.2 | 0.01 | HEDPO | 0.8 |
| | | | Trimellitic | 0.2 | | | | | | |
| | | | acid | | | | | | | |
| Composition 207 | Benzoic acid | 0.05 | Citric acid | 3 | 0.02 | Tris | 5.1 | 0.01 | L-Lysine | 0.5 |
| | | | Trimellitic | 0.3 | | | | | | |
| | | | acid | | | | | | | |
| Composition 208 | Benzoic acid | 0.05 | Citric acid | 0.6 | 0.06 | Tris | 1 | 0.05 | L-Histidine | 0.5 |
| | | | Trimellitic | 0.2 | | | | | | |
| | | | acid | | | | | | | |
| Composition 209 | Benzoic acid | 0.5 | Citric acid | 0.3 | 0.63 | Tris | 1.6 | 0.31 | DEPPO | 0.3 |
| | | | Trimellitic | 0.5 | | | | | | |
| | | | acid | | | | | | | |
| Composition 210 | Benzoic acid | 0.05 | Citric acid | 6 | 0.01 | DMAMP | 10.2 | 0.005 | L-Lysine | 1.0 |
| | | | Trimellitic | 0.6 | | | | | | |
| | | | acid | | | | | | | |
| Composition 211 | Benzoic acid | 0.05 | Phthalic acid | 6 | 0.01 | MEA | 10.2 | 0.005 | L-Lysine | 1.0 |
| | | | Oxalic acid | 0.6 | | | | | | |
| Composition 212 | Salicylic acid | 0.5 | Citric acid | 0.3 | 0.63 | Tris | 1.6 | 0.31 | L-Arginine | 0.3 |
| | | | Trimellitic | 0.5 | | | | | | |
| | | | acid | | | | | | | |
| Composition 213 | Salicylic acid | 0.05 | Citric acid | 3 | 0.02 | Tris | 5.1 | 0.01 | L-Arginine | 0.5 |
| | | | Trimellitic | 0.3 | | | | | | |
| | | | acid | | | | | | | |
| Composition 214 | Salicylic acid | 0.05 | Citric acid | 0.6 | 0.06 | Tris | 1 | 0.05 | L-Arginine | 0.5 |
| | | | Trimellitic | 0.2 | | | | | | |
| | | | acid | | | | | | | |
| Composition 215 | Salicylic acid | 0.5 | Citric acid | 0.3 | 0.63 | Tris | 1.6 | 0.31 | L-Arginine | 0.3 |
| | | | Trimellitic | 0.5 | | | | | | |
| | | | acid | | | | | | | |
| Composition 216 | Salicylic acid | 0.05 | Citric acid | 1.6 | 0.03 | Tris | 4.2 | 0.01 | HEDPO | 0.8 |
| | | | Trimellitic | 0.2 | | | | | | |
| | | | acid | | | | | | | |
| Composition 217 | Salicylic acid | 0.05 | Citric acid | 3 | 0.02 | Tris | 5.1 | 0.01 | L-Lysine | 0.5 |
| | | | Trimellitic | 0.3 | | | | | | |
| | | | acid | | | | | | | |
| Composition 218 | Salicylic acid | 0.05 | Citric acid | 0.6 | 0.06 | Tris | 1 | 0.05 | L-Histidine | 0.5 |
| | | | Trimellitic | 0.2 | | | | | | |
| | | | acid | | | | | | | |
| Composition 219 | Salicylic acid | 0.5 | Citric acid | 0.3 | 0.63 | Tris | 1.6 | 0.31 | DEPPO | 0.3 |
| | | | Trimellitic | 0.5 | | | | | | |
| | | | acid | | | | | | | |
| Composition 220 | Salicylic acid | 0.05 | Citric acid | 6 | 0.01 | DMAMP | 10.2 | 0.005 | L-Lysine | 1.0 |
| | | | Trimellitic | 0.6 | | | | | | |
| | | | acid | | | | | | | |
| Composition 221 | Salicylic acid | 0.05 | Phthalic acid | 6 | 0.01 | MEA | 10.2 | 0.005 | L-Lysine | 1.0 |
| | | | Oxalic acid | 0.6 | | | | | | |

TABLE 8

| | Composition and physical properties of composition | | | | | | | | Evaluation | | |
|---|---|---|---|---|---|---|---|---|---|---|---|
| | Other components | | | | | Diluted liquid | | | Cleaning | Cleaning | |
| | | Content | | | Electric | | Electric | | performance | performance | |
| Table 1 | | (% by | | | conductivity | Dilution | conductivity | | after | after | W |
| (4-2) | Kind | mass) | Water | pH | (S/m) | ratio | (S/m) | pH | preparation | storage | corrosiveness |
| Composition | DBS | 0.5 | Residual | 6.3 | 0.340 | 100 | 0.076 | 6.6 | 7 | 7 | 7 |
| 191 | | | part | | | | | | | | |
| Composition | — | — | Residual | 6.0 | 1.010 | 100 | 0.025 | 6.4 | 8 | 8 | 8 |
| 192 | | | part | | | | | | | | |
| Composition | — | — | Residual | 6.0 | 0.477 | 100 | 0.021 | 6.6 | 8 | 8 | 8 |
| 193 | | | part | | | | | | | | |
| Composition | — | — | Residual | 6.0 | 0.477 | 100 | 0.021 | 6.6 | 8 | 8 | 8 |
| 194 | | | part | | | | | | | | |
| Composition | DBS | 1.0 | Residual | 6.3 | 0.731 | 100 | 0.022 | 6.5 | 7 | 7 | 7 |
| 195 | | | part | | | | | | | | |
| Composition | DBSA | 1.0 | Residual | 6.3 | 0.731 | 100 | 0.022 | 6.5 | 7 | 7 | 7 |
| 196 | | | part | | | | | | | | |
| Composition | DBSA | 0.5 | Residual | 6.3 | 0.365 | 100 | 0.011 | 6.6 | 7 | 7 | 7 |
| 197 | | | part | | | | | | | | |
| Composition | — | — | Residual | 6.0 | 1.010 | 100 | 0.025 | 6.4 | 8 | 8 | 8 |
| 198 | | | part | | | | | | | | |
| Composition | — | — | Residual | 6.0 | 0.949 | 50 | 0.043 | 6.6 | 8 | 8 | 8 |
| 199 | | | part | | | | | | | | |
| Composition | — | — | Residual | 6.0 | 0.949 | 50 | 0.043 | 6.6 | 8 | 8 | 8 |
| 200 | | | part | | | | | | | | |
| Composition | — | — | Residual | 6.0 | 0.949 | 50 | 0.043 | 6.6 | 8 | 8 | 8 |
| 201 | | | part | | | | | | | | |
| Composition | — | — | Residual | 6.0 | 0.092 | 10 | 0.001 | 6.2 | 8 | 8 | 8 |
| 202 | | | part | | | | | | | | |
| Composition | — | — | Residual | 6.0 | 1.450 | 200 | 0.019 | 6.6 | 8 | 8 | 8 |
| 203 | | | part | | | | | | | | |
| Composition | — | — | Residual | 6.0 | 0.505 | 200 | 0.005 | 6.5 | 8 | 8 | 8 |
| 204 | | | part | | | | | | | | |
| Composition | — | — | Residual | 6.0 | 0.092 | 10 | 0.001 | 6.2 | 8 | 8 | 8 |
| 205 | | | part | | | | | | | | |
| Composition | — | — | Residual | 6.0 | 1.200 | 100 | 0.015 | 6.6 | 8 | 8 | 8 |
| 206 | | | part | | | | | | | | |
| Composition | — | — | Residual | 6.0 | 1.411 | 100 | 0.039 | 6.5 | 8 | 8 | 8 |
| 207 | | | part | | | | | | | | |
| Composition | — | — | Residual | 6.0 | 0.512 | 100 | 0.012 | 6.1 | 8 | 8 | 8 |
| 208 | | | part | | | | | | | | |
| Composition | — | — | Residual | 6.0 | 0.092 | 10 | 0.001 | 6.2 | 8 | 8 | 8 |
| 209 | | | part | | | | | | | | |
| Composition | — | — | Residual | 6.0 | 1.365 | 100 | 0.078 | 6.4 | 8 | 8 | 8 |
| 210 | | | part | | | | | | | | |
| Composition | — | — | Residual | 6.0 | 0.888 | 200 | 0.022 | 6.5 | 8 | 8 | 8 |
| 211 | | | part | | | | | | | | |
| Composition | — | — | Residual | 6.0 | 0.092 | 10 | 0.001 | 6.2 | 8 | 8 | 8 |
| 212 | | | part | | | | | | | | |
| Composition | — | — | Residual | 6.0 | 1.450 | 200 | 0.019 | 6.6 | 8 | 8 | 8 |
| 213 | | | part | | | | | | | | |
| Composition | — | — | Residual | 6.0 | 0.505 | 200 | 0.005 | 6.5 | 8 | 8 | 8 |
| 214 | | | part | | | | | | | | |
| Composition | — | — | Residual | 6.0 | 0.092 | 10 | 0.001 | 6.2 | 8 | 8 | 8 |
| 215 | | | part | | | | | | | | |
| Composition | — | — | Residual | 6.0 | 1.200 | 100 | 0.015 | 6.6 | 8 | 8 | 8 |
| 216 | | | part | | | | | | | | |
| Composition | — | — | Residual | 6.0 | 1.411 | 100 | 0.039 | 6.5 | 8 | 8 | 8 |
| 217 | | | part | | | | | | | | |
| Composition | — | — | Residual | 6.0 | 0.512 | 100 | 0.012 | 6.1 | 8 | 8 | 8 |
| 218 | | | part | | | | | | | | |
| Composition | — | — | Residual | 6.0 | 0.092 | 10 | 0.001 | 6.2 | 8 | 8 | 8 |
| 219 | | | part | | | | | | | | |
| Composition | — | — | Residual | 6.0 | 1.365 | 100 | 0.078 | 6.4 | 8 | 8 | 8 |
| 220 | | | part | | | | | | | | |
| Composition | — | — | Residual | 6.0 | 0.888 | 200 | 0.022 | 6.5 | 8 | 8 | 8 |
| 221 | | | part | | | | | | | | |

From the results shown in the above tables, it has been confirmed that as compared with the comparative composition 1 containing no organic amine and the comparative composition 2 containing no antibacterial agent, the composition according to the embodiment of the present invention makes it possible to obtain an effect that the cleaning performance in a case where a semiconductor substrate is subjected to cleaning by using a diluted liquid after a lapse of a predetermined period of time.

It has been confirmed that in a case where the ratio A/C of the content of the antibacterial agent to the content of the organic amine is 0.005 to 0.03 in the composition, the cleaning performance is more excellent in a case where a semiconductor substrate is subjected to cleaning by using a diluted liquid after a lapse of a predetermined period of time (the comparison among the compositions 115 to 118).

In addition, it has been confirmed that in a case where the composition contains Tris or DMAMP as the organic amine, the cleaning performance is more excellent (the comparison among the compositions 102 to 104 and the comparison among the compositions 119 to 124).

As a result of carrying out the above-described evaluation test for the cleaning performance by using a sample of a diluted liquid prepared by using ammonia (manufactured by FUJIFILM Wako Pure Chemical Corporation) instead of potassium hydroxide as a pH adjusting agent in the preparation of the diluted liquids of the compositions 154 to 221, the cleaning performance of the diluted liquid prepared by using ammonia was the same as the cleaning performance of the diluted liquid prepared by using potassium hydroxide.

As a result of also evaluating the cleaning performance of other compositions other than the compositions 117, 102, and 134 among the compositions 101 to 221 according to the above-described procedure, the peak intensity corresponding to the residual amount of colloidal silica was smaller and the cleaning effect was more excellent in a case where the other compositions were used, as compared with a case of using ultrapure water or the comparative composition 1.

### Example 2: Evaluation of Cleaning Performance with Respect to Cleaning Brush

Using each of the compositions prepared by the above-described method, the cleaning performance in a case of cleaning a brush that is used for cleaning a semiconductor substrate was evaluated.

Each of the compositions 117, 102, and 134 and the comparative composition 1 was fractionated and diluted 30 times in terms of mass ratio with ultrapure water to prepare a sample of a diluted liquid for brush cleaning.

A polishing liquid obtained by adding, to a CMP slurry (product name: “W2000”, manufactured by Cabot Corporation), 2% by mass of hydrogen peroxide with respect to the total mass of the slurry was used, and then a silicon wafer (diameter: 12 inches) having, on a surface, a CVD-W film having a film thickness of 5,000 Å was subjected to a CMP treatment under the same conditions as those described in Example 1, by using FREX300S-II (a polishing device, manufactured by Ebara Corporation). Next, the polished surface of the wafer subjected to the CMP treatment was subjected to scrub cleaning for 30 seconds while allowing ultrapure water to flow and rotating a brush (a roll type brush made of PVA, model number: “PVP1ARXR1”, manufactured by Entegris, Inc.).

Next, the wafer was removed from the polishing device and then subjected to cleaning for 1 minute by allowing the sample of the diluted liquid prepared above or ultrapure water to flow onto the brush at a flow rate of 1 L/min while rotating the brush. Subsequently, the brush was subjected to a rinsing treatment for 1 minute by using ultrapure water and then dried. The surface of the dried brush was subjected to measurement using a Fourier transform infrared spectrometer (FT-IR) to determine a peak intensity (height) of a peak in the vicinity of 1,100 cm⁻¹. The obtained peak intensity corresponds to the amount of the colloidal silica remaining on the surface of the brush.

Next, each diluted liquid that was not used in the above-described evaluation test for the cleaning performance was put into a container made of HDPE and stored in a clean room at 23±2° C. for 1 month. The brush was subjected to cleaning by using each of the diluted liquids after storage in the same manner as in the above-described method, and the cleaning performance of the diluted liquid with respect to the brush was evaluated.

Table 2 below shows the numerical value of the peak intensity measured by the above method after cleaning the brush with the sample of each diluted liquid, in a case where the peak intensity measured by the above-described method after cleaning the brush with ultrapure water was set to 100. It is noted that the numerical value described in the column of “After preparation” is a measured value in a case where the brush is washed using a diluted sample which has not been stored, and the numerical value described in the column of “After storage for 1 month” is a measured value in a case where the brush is washed using a sample of the diluted liquid which has been subjected to the storage test.

The numerical value in the column of “Peak intensity” in the table corresponds to an amount of colloidal silica remaining on the surface of the brush subjected to cleaning with the sample of each diluted liquid, in a case where the amount of colloidal silica remaining on the surface of the brush subjected to cleaning with ultrapure water is set to 100.

TABLE 9

| | Peak intensity (Residual | |
|---|---|---|
| | amount of colloidal silica) | |
| Cleaning liquid | After preparation | After storage for 1 month |
| Ultrapure water | 100 | |
| 30-fold diluted liquid of | 31 | 32 |
| composition 117 | | |
| 30-fold diluted liquid of | 45 | 43 |
| composition 102 | | |
| 30-fold diluted liquid of | 38 | 38 |
| composition 134 | | |
| 30-fold diluted liquid of | 94 | 105 |
| comparative composition 1 | | |

As a result of also evaluating the cleaning performance with respect to the brush, regarding other compositions other than the compositions 117, 102, and 134 among the compositions 101 to 221 according to the above-described procedure, the peak intensity corresponding to the residual amount of colloidal silica was smaller and the cleaning effect was more excellent in a case where the other compositions were used, as compared with a case of using ultrapure water or the comparative composition 1.

As described above, it has been confirmed that the composition according to the embodiment of the present invention has more excellent cleaning performance with respect to the cleaning brush as compared with the comparative composition 1 containing no organic amine, and furthermore, has more excellent cleaning performance in a case where the cleaning brush is washed with a diluted liquid after a lapse of a predetermined period of time.

### Example 3: Evaluation of Cleaning Performance with Respect to Polishing Pad

Using each of the compositions prepared by the above-described method, the cleaning performance in a case of cleaning a polishing pad that is used for treating a semiconductor substrate was evaluated.

According to the procedure described in Example 1, a silicon wafer (diameter: 12 inches) having a W film was subjected to a CMP treatment under the same conditions as those described in Example 1. Next, a diluted liquid (25° C.) obtained by diluting the composition 117 with ultrapure water by 100 times in terms of mass ratio was allowed to flow, and the polished surface of the wafer which had been subjected to the CMP treatment was subjected to scrub cleaning while rotating the brush. The wafer subjected to the cleaning was rinsed with water and dried (dried out), and then the number of defects on the polished surface of the wafer was counted according to the procedure described in Example 1 (Test Example 3-1).

The surface of the polishing pad used for the CMP treatment was subjected to dressing (setting treatment) for 20 seconds using a CMP dresser while ultrapure water was allowed to flow. The CMP treatment was carried out according to the above-described method using the polishing pad which had been subjected to dressing, and then the number of defects on the polished surface of the wafer was counted (Test Example 3-2).

9 cycles of a series of treatments consisting of the dressing of the polishing pad using ultrapure, the CMP treatment, and the measurement of the number of defects, which were described above, was carried out including the above-described Test Example 3-2 (Test Examples 3-2 to 3-10).

After carrying out the treatment of the 9 cycles described above, the surface of the polishing pad that had been used for the CMP treatment was subjected to dressing (setting treatment) for 20 seconds using a CMP dresser while a diluted liquid (25° C.) obtained by diluting the composition 117 with ultrapure water by 30 times in terms of mass ratio was allowed to flow. The CMP treatment was carried out according to the above-described method using the polishing pad which had been subjected to dressing, and then the number of defects on the polished surface of the wafer was counted (Test Example 3-11).

Next, a 30-fold diluted liquid of the composition 117 that had not been used for the dressing described above was put into a container made of HDPE and then stored in a clean room at 23±2° C. for 1 month. The brush was subjected to cleaning by using the diluted liquid after storage in the same manner as in the above-described method, and the cleaning performance of the diluted liquid with respect to the brush was evaluated.

In the same manner as in Test Examples 3-1 to 3-10, a silicon wafer having a W film, which had been subjected to the CMP treatment, scrub cleaning, rinsing, and drying, was further subjected to a treatment of 9 cycles of a series of treatments consisting of dressing, a CMP treatment, and a measurement of the number of defects. Next, dressing was carried out in the same manner as in Test Example 3-11, except that a diluted liquid after storage (25° C.) was used for the surface of the polishing pad that had been used for the CMP treatment. Subsequently, the CMP treatment was carried out using the polishing pad which had been subjected to dressing, and then the number of defects on the polished surface of the wafer was counted (Test Example 3-12).

Table 3 below shows the number of times of dressing, the kind of cleaning liquid used for dressing, and the number of defects on the polished surface of the wafer in Test Examples 3-1, 3-5, 3-10, 3-11, and 3-12.

TABLE 10

| | | | | Wafer |
|---|---|---|---|---|
| Test | Dressing | | Wafer | Number of |
| Example | Time | Cleaning liquid | Cleaning liquid | defects |
| 3-1 | — | — | 100-fold diluted liquid of | 11 |
| | | | composition 117 | |
| 3-5 | 4 | Ultrapure water | 100-fold diluted liquid of | 14 |
| | | | composition 117 | |
| 3-10 | 9 | Ultrapure water | 100-fold diluted liquid of | 17 |
| | | | composition 117 | |
| 3-11 | 10 | 1st to 9th time: ultrapure water | 100-fold diluted liquid of | 11 |
| | | 10th time: 30-fold diluted liquid | composition 117 | |
| | | of composition 117 | | |
| 3-12 | 10 | 1st to 9th time: ultrapure water | 100-fold diluted liquid of | 11 |
| | | 10th time: 30-fold diluted liquid | composition 117 | |
| | | of composition 117 after | | |
| | | storage | | |

As shown in the above table, it has been confirmed that in a case where the polishing pad is subjected to cleaning by using the composition according to the embodiment of the present invention, the number of defects on the surface of the wafer is reduced, and the cleaning performance with respect to the polishing pad is excellent as compared with a case where the polishing pad is subjected to cleaning by using ultrapure water. Further, it has been confirmed that even in a case where a diluted liquid after a lapse of a predetermined period of time is used, the composition according to the embodiment of the present invention can maintain the cleaning performance with respect to a polishing pad in a case where a diluted liquid immediately after preparation is used.

### Example 4: Performance Evaluation in Buffing Cleaning

The composition prepared by the above-described method was used to evaluate the cleaning performance in a case where a semiconductor substrate subjected to a CMP treatment was subjected to buffing cleaning.

According to the procedure described in Example 1, a silicon wafer (diameter: 12 inches) having a W film having a film thickness of 5,000 Å was subjected to a CMP treatment under the same conditions as those described in Example 1. The wafer subjected to the CMP treatment was transferred onto a platen of a polishing device (manufactured by Ebara Corporation, “FREX300S-II”) different from the polishing device used in the CMP treatment.

The polished surface of the wafer subjected to the CMP treatment was subjected to buffing cleaning under the following conditions.
Table rotation speed: 80 rpm
Head rotation speed: 78 rpm
Polishing pressure: 90 hPa
Polishing pad: IC1400, manufactured by Rodel Nitta Co., Ltd.
Cleaning liquid: A diluted liquid obtained by diluting composition 102 with ultrapure water by 30 times in terms of mass ratio
Supply rate of cleaning liquid: 250 mL/min
Polishing time: 60 seconds

Thereafter, a diluted liquid obtained by diluting composition 102 with ultrapure water by 100 times in terms of mass ratio was used as a cleaning liquid to subject a polished surface of the wafer, which had been subjected to the above-described buffing cleaning, to scrub cleaning for 30 seconds. Thereafter, the wafer subjected to the cleaning was rinsed with water and dried (dried out), and then the number of defects on the polished surface of the wafer which had been subjected to buffing cleaning was counted according to the procedure described in Example 1.

Next, a 30-fold diluted liquid of the composition 102 that had not been used for the buffing cleaning described above was put into a container made of HDPE and then stored in a clean room at 23±2° C. for 1 month. The polished surface of the wafer subjected to the CMP treatment in the same manner as in the above-described method was subjected to buffing cleaning by using the diluted liquid after storage. Next, in the same manner as described above, the polished surface of the wafer subjected to the buffing cleaning was subjected to scrub cleaning for 30 seconds, the wafer subjected to the cleaning was subsequently rinsed with water and dried, and the number of defects on the polished surface of the wafer subjected to the buffing cleaning was counted according to the procedure described in Example 1.

As a result of evaluating the cleaning performance from the measurement results of the obtained number of defects, based on the evaluation standards for cleaning performance described in Example 1, the evaluation result in a case where a diluted liquid of the composition 102 after preparation (before storage) and the evaluation result in a case where a diluted liquid of the composition 102 after storage were both “8”. On the other hand, as shown in Table 1 of Example 1, the evaluation result in a case where the buffing cleaning was not carried out was “7”.

From the above facts, it has been confirmed that the number of defects on the polished surface can be further reduced by the above-described buffing cleaning which is carried out using the composition according to the embodiment of the present invention, and furthermore, even in a case where a diluted liquid after a lapse of a predetermined period of time is used, it is possible to maintain the cleaning performance with a polishing pad in a case where a diluted liquid immediately after preparation is used.

### Preparation Example 2: Preparation of Composition

A composition 301 was prepared according to the following method.

Citric acid, 1-hydroxyethylidene-1,1′-diphosphonic acid (HEDPO), a sulfonic acid-based surfactant, and ultrapure water were mixed so that amounts thereof were such a formulation as shown in Table 4, and then the mixed liquid was sufficiently stirred with a stirrer to obtain a composition 301. It is noted that as the sulfonic acid surfactant, a mixture containing the following compounds (LAS-10, LAS-11, LAS-12, and LAS-13) at the ratios (in terms of mass ratio) shown in Table 4 was used. The content of the sulfonic acid-based surfactant shown in Table 4 is the total content of LAS-10, LAS-11, LAS-12, and LAS-13 with respect to the total amount of the composition.

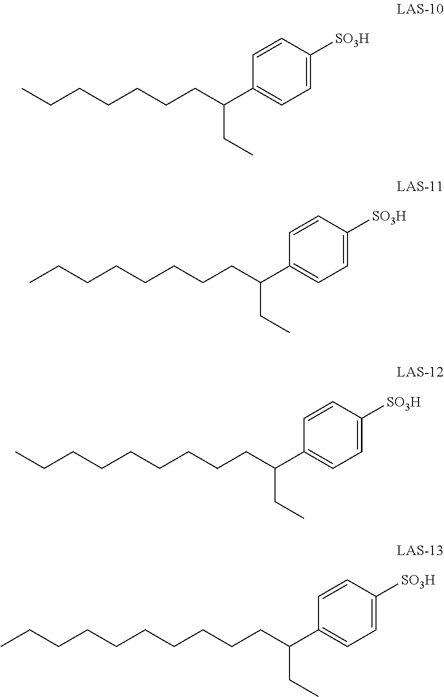 [SMILES: CCCCCCCC(CC)c1ccc(S(=O)(=O)O)cc1 ; CCCCCCCCC(CC)c1ccc(S(=O)(=O)O)cc1 ; CCCCCCCCCC(CC)c1ccc(S(=O)(=O)O)cc1 ; CCCCCCCCCCC(CC)c1ccc(S(=O)(=O)O)cc1]

Compositions 302 to 320 having the compositions shown in Table 4 were respectively produced in accordance with the preparation method for the composition 301.

It is noted that the composition was repeatedly subjected to a filtration treatment so that after producing each composition, the concentration of copper ions contained in the composition was 0.2 ppb by mass with respect to the total mass of the composition, and the concentration of phosphate ions contained in the composition was 0.001% by mass with respect to the total mass of the composition. The concentration of copper ions was checked by ICP-MS (Agilent 8800 triple quadrupole ICP-MS (for semiconductor analysis, option #200)). Specifically, as a sample introduction system, a quartz torch, a coaxial PFA nebulizer (for self-suction), and a platinum interface cone were used. Measurement parameters of cool plasma conditions were as follows.
Radio frequency (RF) output (W): 600
Carrier gas flow rate (L/min): 0.7
Makeup gas flow rate (L/min): 1
Sampling depth (mm): 18

In addition, the content of the phosphate ion was measured by ion exchange chromatography (IC).

In addition, each of compositions 401 to 420 having the compositions shown in Table 5 was produced in accordance with the preparation method for the composition 101 in Preparation Example 1.

### Example 5: Evaluation of Cleaning Performance with Respect to Semiconductor Substrate

### [Evaluation of Cleaning Performance]

The compositions 301 to 320 and 401 to 420, which had been prepared by the above-described method were used to evaluate the cleaning performance in a case where a semiconductor substrate having a metal film subjected to chemical mechanical polishing was subjected to cleaning.

Specifically, 100 mL of the compositions 401 to 420 immediately after being prepared in Preparation Example 2 was fractionated and diluted with ultrapure water at a dilution ratio (in terms of mass ratio) of each of the compositions shown in Table 5 described later to prepare a sample of a diluted liquid for cleaning performance evaluation.

In the preparation of diluted liquids of the compositions 401 to 420, any one of potassium hydroxide (manufactured by FUJIFILM Wako Pure Chemical Corporation) or sulfuric acid (manufactured by FUJIFILM Wako Pure Chemical Corporation) was added as necessary to the diluted liquid as a pH adjusting agent, and then the pH of the diluted liquid at 25° C. was adjusted to a numerical value shown in Table 5 described later.

The cleaning performance of each composition with respect to a semiconductor substrate was evaluated according to the method described in [Evaluation of cleaning performance] of Example 1, except that the polished surface of the wafer subjected to the CMP treatment was subjected to scrub cleaning for 30 seconds using the composition 301 and then subjected to scrub cleaning for 30 seconds using the diluted liquid of the composition 401 (twice consecutive cleaning operations).

In the same manner, the above-described twice consecutive cleaning operations were carried out using a set obtained by combining the diluted liquids of the compositions 302 to 320 and the compositions 402 to 420, respectively, and the cleaning performance of each composition with respect to a semiconductor substrate was evaluated.

### [Evaluation of Corrosiveness of Tungsten]

Each of compositions 401 to 420 prepared by the above-described method was fractionated and diluted with ultrapure water at a dilution ratio (in terms of mass ratio) of each of the compositions shown in Table 5 described later to prepare a sample (200 g) of a diluted liquid for evaluating anticorrosion properties. In the same manner as described above, in the preparation of the sample of the diluted liquid, any one of potassium hydroxide (manufactured by FUJIFILM Wako Pure Chemical Corporation) or sulfuric acid (manufactured by FUJIFILM Wako Pure Chemical Corporation) was added as necessary to the diluted liquid as a pH adjusting agent, and then the pH of the diluted liquid at 25° C. was adjusted to a numerical value shown in Table 5 described later.

The corrosiveness of each diluted liquid with respect to tungsten was evaluated according to the method described in [Evaluation of corrosiveness of tungsten] of Example 1, except that the sample of the diluted liquid prepared above was used.

Table 4 shows the composition and physical properties of the compositions 301 to 320, and Table 5 shows the composition and physical properties of the compositions 401 to 420, the physical properties of the diluted liquid, and the evaluation results according to the above-described evaluation.

In the table, the column of “Silicon content (ppb by mass)” indicates the content (unit: ppb by mass) of silicon with respect to the total mass of the composition. As shown in Table 4 and Table 5, all of the contents of silicon contained in the respective compositions were less than 50 ppb by mass with respect to the total mass of the composition.

TABLE 11

| | | | Sulfonic acid-based surfactant | | | | | | | |
|---|---|---|---|---|---|---|---|---|---|---|
| | Citric acid | HEDPO | Ratio (in terms of mass ratio) | | | | Content | | Silicon content | |
| Table 4 | (% by mass) | (% by mass) | LAS-10 | LAS-11 | LAS-12 | LAS-13 | (% by mass) | Water | (ppb by mass) | pH |
| Composition 301 | 30.0 | 1.40 | 10 | 35 | 30 | 25 | 0.07 | Residual | <50 | 1.00 |
| | | | | | | | | part | | |
| Composition 302 | 30.0 | 0.20 | 10 | 35 | 30 | 25 | 0.07 | Residual | <50 | 1.00 |
| | | | | | | | | part | | |
| Composition 303 | 3.0 | 0.06 | 10 | 35 | 30 | 25 | 0.01 | Residual | <50 | 1.77 |
| | | | | | | | | part | | |
| Composition 304 | 30.0 | 0.45 | 10 | 35 | 30 | 25 | 0.07 | Residual | <50 | 1.00 |
| | | | | | | | | part | | |
| Composition 305 | 30.0 | 0.35 | 10 | 35 | 30 | 25 | 0.07 | Residual | <50 | 1.00 |
| | | | | | | | | part | | |
| Composition 306 | 30.0 | 0.55 | 10 | 35 | 30 | 25 | 0.07 | Residual | <50 | 1.00 |
| | | | | | | | | part | | |
| Composition 307 | 30.0 | 1.10 | 10 | 35 | 30 | 25 | 0.07 | Residual | <50 | 1.00 |
| | | | | | | | | part | | |
| Composition 308 | 30.0 | 0.55 | 10 | 35 | 30 | 25 | 0.42 | Residual | <50 | 1.00 |
| | | | | | | | | part | | |
| Composition 309 | 15.0 | 0.27 | 10 | 35 | 30 | 25 | 0.03 | Residual | <50 | 1.69 |
| | | | | | | | | part | | |
| Composition 310 | 0.3 | 0.0055 | 10 | 35 | 30 | 25 | 0.0007 | Residual | <50 | 2.64 |
| | | | | | | | | part | | |
| Composition 311 | 30.0 | 0.90 | 10 | 35 | 30 | 25 | 0.07 | Residual | <50 | 1.00 |
| | | | | | | | | part | | |
| Composition 312 | 30.0 | 0.55 | 10 | 35 | 30 | 25 | 0.06 | Residual | <50 | 1.00 |
| | | | | | | | | part | | |
| Composition 313 | 30.0 | 0.55 | 10 | 35 | 30 | 25 | 0.04 | Residual | <50 | 1.00 |
| | | | | | | | | part | | |
| Composition 314 | 30.0 | 0.55 | 10 | 35 | 30 | 25 | 0.03 | Residual | <50 | 1.00 |
| | | | | | | | | part | | |
| Composition 315 | 30.0 | 0.55 | 10 | 35 | 30 | 25 | 0.10 | Residual | <50 | 1.00 |
| | | | | | | | | part | | |
| Composition 316 | 30.0 | 0.25 | 10 | 35 | 30 | 25 | 0.07 | Residual | <50 | 1.00 |
| | | | | | | | | part | | |
| Composition 317 | 30.0 | 0.55 | 10 | 35 | 30 | 25 | 0.40 | Residual | <50 | 1.00 |
| | | | | | | | | part | | |
| Composition 318 | 30.0 | 0.55 | 10 | 35 | 30 | 25 | 0.05 | Residual | <50 | 1.00 |
| | | | | | | | | part | | |
| Composition 319 | 7.0 | 0.14 | 10 | 35 | 30 | 25 | 0.02 | Residual | <50 | 1.71 |
| | | | | | | | | part | | |
| Composition 320 | 30.0 | 0.70 | 10 | 35 | 30 | 25 | 0.07 | Residual | <50 | 1.00 |
| | | | | | | | | part | | |

TABLE 12

| | Composition and physical properties of composition | | | | | | | | | |
|---|---|---|---|---|---|---|---|---|---|---|
| | Antibacterial agent | | Organic acid | | | Organic amine | | | Chelating agent | |
| Table 5 | | Content | | Content | Ratio | | Content | Ratio | | Content |
| (1) | Kind | (% by mass) | Kind | (% by mass) | A/B | Kind | (% by mass) | A/C | Kind | (% by mass) |
| Composition | Benzethonium | 0.05 | Tartaric acid | 0.5 | 0.10 | DMAMP | 4.8 | 0.01 | DEPPO | 3.0 |
| 401 | chloride | | | | | | | | | |
| Composition | MIT | 0.05 | Malic acid | 0.5 | 0.10 | Tris | 5.1 | 0.01 | HEDPO | 3.0 |
| 402 | | | | | | | | | | |
| Composition | MIT | 0.05 | Tartaric acid | 0.5 | 0.10 | Tris | 5.0 | 0.01 | HEDPO | 3.0 |
| 403 | | | | | | | | | | |
| Composition | MIT | 0.041 | Malic acid | 0.5 | 0.10 | DMAMP | 4.9 | 0.01 | HEDPO | 3.0 |
| 404 | OIT | 0.009 | | | | | | | | |
| Composition | Sorbic acid | 0.05 | Malic acid | 0.5 | 0.10 | Tris | 5.1 | 0.01 | HEDPO | 3.0 |
| 405 | | | | | | | | | | |
| Composition | Sorbic acid | 0.05 | Citric acid | 0.38 | 0.13 | Tris | 6.5 | 0.01 | HEDPO | 4.2 |
| 406 | | | | | | | | | | |
| Composition | MIT | 0.041 | Succinic acid | 0.5 | 0.10 | DMAMP | 5.1 | 0.01 | HEDPO | 3.0 |
| 407 | OIT | 0.009 | | | | | | | | |
| Composition | Dehydroacetic | 0.05 | Tartaric acid | 0.5 | 0.10 | AMP | 3.7 | 0.01 | HEDPO | 3.0 |
| 408 | acid | | | | | | | | | |
| Composition | Cresol | 0.05 | Tartaric acid | 0.5 | 0.10 | DMAMP | 4.8 | 0.01 | HEDPO | 3.0 |
| 409 | | | | | | | | | | |
| Composition | Sorbic acid | 0.05 | Citric acid | 0.04 | 1.32 | Tris | 0.7 | 0.07 | HEDPO | 0.4 |
| 410 | | | | | | | | | | |
| Composition | Sorbic acid | 0.005 | Citric acid | 0.04 | 0.13 | Tris | 0.7 | 0.01 | HEDPO | 0.4 |
| 411 | | | | | | | | | | |
| Composition | Sorbic acid | 0.05 | Citric acid | 1.6 | 0.03 | Tris | 4.2 | 0.01 | HEDPO | 0.8 |
| 412 | | | Trimellitic acid | 0.2 | | | | | | |
| Composition | Sorbic acid | 0.05 | Citric acid | 3 | 0.02 | Tris | 5.1 | 0.01 | L-Arginine | 0.5 |
| 413 | | | Trimellitic acid | 0.3 | | | | | | |
| Composition | BIT | 0.05 | Maleic acid | 2 | 0.03 | Tris | 2.2 | 0.02 | EDTPO | 0.8 |
| 414 | | | | | | | | | | |
| Composition | Sorbic acid | 0.05 | Phthalic acid | 0.10 | 1.67 | DMAMP | 0.8 | 0.31 | L-Histidine | 0.2 |
| 415 | | | Oxalic acid | 0.05 | | | | | | |
| Composition | BIT | 0.25 | Phthalic acid | 0.10 | 1.67 | AMP | 0.8 | 0.31 | L-Lysine | 0.2 |
| 416 | | | Oxalic acid | 0.05 | | | | | | |
| Composition | Dehydroacetic | 0.05 | Citric acid | 0.6 | 0.06 | Tris | 1.0 | 0.05 | L-Histidine | 0.5 |
| 417 | acid | | Trimellitic acid | 0.2 | | | | | | |
| Composition | Sorbic acid | 0.5 | Citric acid | 0.3 | 0.63 | Tris | 1.6 | 0.31 | DEPPO | 0.3 |
| 418 | | | Trimellitic acid | 0.5 | | | | | | |
| Composition | Dehydroacetic | 0.05 | Citric acid | 6 | 0.01 | DMAMP | 10.2 | 0.00 | L-Lysine | 1.0 |
| 419 | acid | | Trimellitic acid | 0.6 | | | | | | |
| Composition | Sorbic acid | 0.05 | Citric acid | 0.04 | 1.32 | Tris | 0.7 | 0.07 | HEDPO | 0.4 |
| 420 | | | | | | | | | | |

TABLE 13

| | Composition and physical properties of composition | | | | | | | | | Evaluation | | |
|---|---|---|---|---|---|---|---|---|---|---|---|---|
| | | | | Silicon | | | Diluted liquid | | | Cleaning | Cleaning | |
| | Other components | | | content | | Electric | | Electric | | performance | performance | |
| Table 5 | | Content | | (ppb by | | conductivity | Dilution | conductivity | | after | after | W |
| (2) | Kind | (% by mass) | Water | mass) | PH | (S/m) | ratio | (S/m) | pH | preparation | storage | corrosiveness |
| Composition | — | — | Residual | <50 | 6.2 | 1.295 | 100 | 0.090 | 6.3 | 6 | 6 | 7 |
| 401 | | | part | | | | | | | | | |
| Composition | — | — | Residual | <50 | 6.0 | 1.285 | 100 | 0.090 | 6.4 | 7 | 7 | 6 |
| 402 | | | part | | | | | | | | | |
| Composition | — | — | Residual | <50 | 6.0 | 1.259 | 100 | 0.088 | 6.6 | 7 | 7 | 6 |
| 403 | | | part | | | | | | | | | |
| Composition | — | — | Residual | <50 | 6.2 | 1.285 | 100 | 0.090 | 6.3 | 7 | 7 | 6 |
| 404 | | | part | | | | | | | | | |
| Composition | — | — | Residual | <50 | 6.0 | 1.285 | 100 | 0.090 | 6.4 | 5 | 5 | 6 |
| 405 | | | part | | | | | | | | | |
| Composition | — | — | Residual | <50 | 6.0 | 1.312 | 100 | 0.040 | 6.5 | 7 | 7 | 6 |
| 406 | | | part | | | | | | | | | |
| Composition | — | — | Residual | <50 | 6.2 | 1.318 | 100 | 0.092 | 6.4 | 7 | 7 | 6 |
| 407 | | | part | | | | | | | | | |
| Composition | — | — | Residual | <50 | 6.0 | 1.264 | 100 | 0.088 | 6.4 | 7 | 6 | 6 |
| 408 | | | part | | | | | | | | | |
| Composition | — | — | Residual | <50 | 6.2 | 1.259 | 100 | 0.088 | 6.3 | 6 | 6 | 6 |
| 409 | | | part | | | | | | | | | |
| Composition | DBS | 0.5 | Residual | <50 | 6.0 | 0.353 | 100 | 0.012 | 6.4 | 7 | 7 | 7 |
| 410 | | | part | | | | | | | | | |
| Composition | DBS | 0.5 | Residual | <50 | 6.0 | 0.349 | 100 | 0.012 | 6.4 | 7 | 7 | 7 |
| 411 | | | part | | | | | | | | | |
| Composition | — | — | Residual | <50 | 6.0 | 1.200 | 100 | 0.015 | 6.6 | 8 | 8 | 8 |
| 412 | | | part | | | | | | | | | |
| Composition | — | — | Residual | <50 | 6.0 | 1.450 | 200 | 0.019 | 6.6 | 8 | 8 | 8 |
| 413 | | | part | | | | | | | | | |
| Composition | — | — | Residual | <50 | 6.0 | 1.010 | 100 | 0.025 | 6.4 | 8 | 8 | 8 |
| 414 | | | part | | | | | | | | | |
| Composition | — | — | Residual | <50 | 6.0 | 0.949 | 50 | 0.043 | 6.6 | 8 | 8 | 8 |
| 415 | | | part | | | | | | | | | |
| Composition | — | — | Residual | <50 | 6.0 | 0.949 | 50 | 0.043 | 6.6 | 8 | 8 | 8 |
| 416 | | | part | | | | | | | | | |
| Composition | — | — | Residual | <50 | 6.0 | 0.512 | 100 | 0.012 | 6.1 | 8 | 8 | 8 |
| 417 | | | part | | | | | | | | | |
| Composition | — | — | Residual | <50 | 6.0 | 0.092 | 10 | 0.001 | 6.2 | 8 | 8 | 8 |
| 418 | | | part | | | | | | | | | |
| Composition | — | — | Residual | <50 | 6.0 | 1.365 | 100 | 0.078 | 6.4 | 8 | 8 | 8 |
| 419 | | | part | | | | | | | | | |
| Composition | DBS | 0.5 | Residual | <50 | 6.0 | 0.353 | 100 | 0.012 | 6.4 | 7 | 7 | 7 |
| 420 | | | part | | | | | | | | | |

From the results shown in the above table, it has been confirmed that even in a case where a semiconductor substrate was subjected to preliminary cleaning by using any of the compositions 301 to 320 and then subjected to cleaning with the diluted liquid of the composition after a lapse of a predetermined period of time according to the embodiment of the present invention, the excellent cleaning performance is maintained with respect to the polished surface of the wafer subjected to the CMP treatment.

In addition, it has been confirmed that all of the compositions 301 to 320 used for the preliminary cleaning in Example 5 have good cleaning performance. This is presumed to be because the silicon content in each composition is low, and the number of particles detected by a liquid particle counter (LPC) is reduced.

It is noted that as a result of evaluating the cleaning performance according to the above evaluation method, in a case where a semiconductor substrate having a metal film subjected to chemical mechanical polishing was subjected to cleaning, except that preliminary cleaning was carried out using the diluted liquids of the composition 301 to 320 instead of the compositions 301 to 320, it has been confirmed that it is possible to obtain excellent cleaning performance similar to the cleaning performance that is obtained in a case where preliminary cleaning is performed using the compositions 301 to 320.

### Example 6: Evaluation of Cleaning Performance with Respect to Semiconductor Substrate

Each of compositions 501 to 588 having the compositions shown in Table 6 was prepared in accordance with the preparation method for the composition 101 in Preparation Example 1. Next, 100 mL of each of the compositions immediately after being prepared was fractionated and diluted with ultrapure water at a dilution ratio (in terms of mass ratio) of each of the compositions shown in Table 6 described later to prepare a sample of a diluted liquid for cleaning performance evaluation.

All of the diluted liquids of the prepared compositions 501 to 588 had a pH in a range of 5.5 to 7.0 at 25° C.

The cleaning performance of the diluted liquid with respect to the semiconductor substrate in a case where a diluted liquid after preparation (before storage) and a diluted liquid after storage, and the corrosiveness of each diluted liquid with respect to tungsten were each evaluated according to the evaluation method described in Example 1, except that the diluted liquid of each prepared composition was used.

In Example 6, the following compounds were used to produce each composition. All of the following compounds are those classified into a semiconductor grade or those classified into a high-purity grade equivalent to the semiconductor grade.
Polymer 1 (polyacrylic acid, Mw: 3,000, “JURYMER AC-10SL” manufactured by Toagosei Company, Limited, corresponding to an anticorrosive agent (water-soluble polymer))
Polymer 2 (polyacrylic acid, Mw: 6,000, “ARON-A-10SL” manufactured by Toagosei Company, Limited, corresponding to an anticorrosive agent (water-soluble polymer))
Polymer 3 (polyacrylic acid, Mw: 10,000, “ARON-SD-10” manufactured by Toagosei Company, Limited, corresponding to an anticorrosive agent (water-soluble polymer))
Polymer 4 (polyacrylic acid, Mw: 25,000, “Polyacrylic Acid 25,000” manufactured by FUJIFILM Wako Pure Chemical Corporation, corresponding to an anticorrosive agent (water-soluble polymer))
Polymer 5 (polyacrylic acid, Mw: 10,000, “ARON A-12SL” manufactured by Toagosei Company, Limited, corresponding to an anticorrosive agent (water-soluble polymer))
Polymer 6 (sodium polystyrene sulfonate, Mw: 8,000, manufactured by FUJIFILM Wako Pure Chemical Corporation, corresponding to an anticorrosive agent (water-soluble polymer))
Polymer 7 (a copolymer of an acrylic acid monomer and a sulfonate group-containing monomer, Mw: 10,000, “ARON A-6012” manufactured by Toagosei Company, Limited, corresponding to an anticorrosive agent (water-soluble polymer))
Polymer 8 (a copolymer of an acrylic acid monomer and a sulfonate group-containing monomer, Mw: 2,500, “A-6016A” manufactured by Toagosei Company, Limited, corresponding to an anticorrosive agent (water-soluble polymer))
Polyglycerin (PG, molecular weight 310, “Polyglycerin #310” manufactured by Sakamoto Yakuhin Kogyo Co., Ltd.)

Table 6 shows the composition and physical properties of each composition, the physical properties of the diluted liquid, and the evaluation results according to the above-described evaluation.

The numerical value in the column of “Ratio R” indicates a mass ratio of the content of the water-soluble polymer to the total content of the antibacterial agent, the organic acid, and the organic amine ((content of water-soluble polymer)/(total content of antibacterial agent, organic acid, and organic amine)).

TABLE 14

| | Composition and physical properties of composition | | | | | | | | | |
|---|---|---|---|---|---|---|---|---|---|---|
| | Antibacterial agent | | Organic acid | | | Organic amine | | | Chelating agent | |
| Table 6 | | Content | | Content | Ratio | | Content | Ratio | | Content |
| (1-1) | Kind | (% by mass) | Kind | (% by mass) | A/B | Kind | (% by mass) | A/C | Kind | (% by mass) |
| Composition | Sorbic acid | 0.05 | Citric acid | 1.8 | 0.03 | Tris | 4.2 | 0.01 | HEDPO | 0.84 |
| 501 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 502 | | | Trimellitic acid | 0.2 | | | | | L-Arginine | 0.5 |
| Composition | Sorbic acid | 0.05 | Citric acid | 3 | 0.02 | Tris | 5.1 | 0.01 | L-Arginine | 0.5 |
| 503 | | | Trimellitic acid | 0.3 | | | | | | |
| Composition | Sorbic acid | 0.05 | Citric acid | 0.6 | 0.06 | Tris | 1 | 0.05 | L-Arginine | 0.5 |
| 504 | | | Trimellitic acid | 0.2 | | | | | | |
| Composition | Sorbic acid | 0.05 | Citric acid | 0.6 | 0.06 | Tris | 1 | 0.05 | L-Arginine | 0.5 |
| 505 | | | Trimellitic acid | 0.2 | | | | | | |
| Composition | Sorbic acid | 0.05 | Citric acid | 0.6 | 0.06 | Tris | 1 | 0.05 | L-Arginine | 0.5 |
| 506 | | | Trimellitic acid | 0.2 | | | | | | |
| Composition | Sorbic acid | 0.05 | Citric acid | 0.6 | 0.06 | Tris | 1 | 0.05 | L-Arginine | 0.5 |
| 507 | | | Trimellitic acid | 0.2 | | | | | | |
| Composition | Sorbic acid | 0.05 | Citric acid | 0.6 | 0.06 | Tris | 1 | 0.05 | L-Arginine | 0.5 |
| 508 | | | Trimellitic acid | 0.2 | | | | | | |
| Composition | Sorbic acid | 0.05 | Citric acid | 0.6 | 0.06 | Tris | 1 | 0.05 | L-Arginine | 0.5 |
| 509 | | | Trimellitic acid | 0.2 | | | | | | |
| Composition | Sorbic acid | 0.05 | Citric acid | 0.6 | 0.06 | Tris | 1 | 0.05 | L-Arginine | 0.5 |
| 510 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 511 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 512 | | | Trimellitic acid | 0.2 | | | | | L-Arginine | 0.5 |
| Composition | Sorbic acid | 0.05 | Citric acid | 3 | 0.02 | Tris | 5.1 | 0.01 | L-Arginine | 0.5 |
| 513 | | | Trimellitic acid | 0.3 | | | | | | |
| Composition | Sorbic acid | 0.05 | Citric acid | 0.6 | 0.06 | Tris | 1 | 0.05 | L-Arginine | 0.5 |
| 514 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 515 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 516 | | | Trimellitic acid | 0.2 | | | | | L-Arginine | 0.5 |
| Composition | Sorbic acid | 0.05 | Citric acid | 3 | 0.02 | Tris | 5.1 | 0.01 | L-Arginine | 0.5 |
| 517 | | | Trimellitic acid | 0.3 | | | | | | |
| Composition | Sorbic acid | 0.05 | Citric acid | 0.6 | 0.06 | Tris | 1 | 0.05 | L-Arginine | 0.5 |
| 518 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 519 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 520 | | | Trimellitic acid | 0.2 | | | | | L-Arginine | 0.5 |
| Composition | Sorbic acid | 0.05 | Citric acid | 3 | 0.02 | Tris | 5.1 | 0.01 | L-Arginine | 0.5 |
| 521 | | | Trimellitic acid | 0.3 | | | | | | |
| Composition | Sorbic acid | 0.05 | Citric acid | 0.6 | 0.06 | Tris | 1 | 0.05 | L-Arginine | 0.5 |
| 522 | | | Trimellitic acid | 0.2 | | | | | | |

TABLE 15

| | Composition and physical properties of composition | | | | | | | Evaluation | | |
|---|---|---|---|---|---|---|---|---|---|---|
| | Other components | | | | | Diluted liquid | | Cleaning | Cleaning | |
| | | Content | | | Electric | | Electric | performance | performance | |
| Table 6 | | (% by | | | conductivity | Dilution | conductivity | after | after | W |
| (1-2) | Kind | mass) | Water | pH | (S/m) | ratio | (S/m) | preparation | storage | corrosiveness |
| Composition | Polymer 1 | 0.1 | Residual | 6.0 | 13.8 | 200 | 0.16 | 7 | 7 | 7 |
| 501 | | | part | | | | | | | |
| Composition | Polymer 1 | 0.1 | Residual | 6.0 | 13.5 | 200 | 0.16 | 7 | 7 | 7 |
| 502 | | | part | | | | | | | |
| Composition | Polymer 1 | 0.1 | Residual | 6.0 | 5.7 | 200 | 0.05 | 7 | 7 | 7 |
| 503 | | | part | | | | | | | |
| Composition | Polymer 1 | 0.1 | Residual | 6.0 | 6.5 | 200 | 0.06 | 7 | 7 | 7 |
| 504 | | | part | | | | | | | |
| Composition | Polymer 1 | 0.5 | Residual | 6.0 | 6.5 | 200 | 0.06 | 7 | 6 | 7 |
| 505 | | | part | | | | | | | |
| Composition | Polymer 1 | 1 | Residual | 6.0 | 6.5 | 200 | 0.06 | 6 | 6 | 7 |
| 506 | | | part | | | | | | | |
| Composition | Polymer 1 | 2 | Residual | 6.0 | 6.5 | 200 | 0.06 | 6 | 5 | 7 |
| 507 | | | part | | | | | | | |
| Composition | Polymer 2 | 0.1 | Residual | 6.0 | 6.5 | 200 | 0.06 | 7 | 7 | 7 |
| 508 | | | part | | | | | | | |
| Composition | Polymer 3 | 0.1 | Residual | 6.0 | 6.5 | 200 | 0.06 | 7 | 7 | 7 |
| 509 | | | part | | | | | | | |
| Composition | Polymer 4 | 0.1 | Residual | 6.0 | 6.5 | 200 | 0.06 | 7 | 7 | 7 |
| 510 | | | part | | | | | | | |
| Composition | PG | 0.1 | Residual | 6.0 | — | 200 | 0.16 | 7 | 7 | 7 |
| 511 | | | part | | | | | | | |
| Composition | PG | 0.1 | Residual | 6.0 | — | 200 | 0.16 | 7 | 7 | 7 |
| 512 | | | part | | | | | | | |
| Composition | PG | 0.1 | Residual | 6.0 | — | 200 | 0.05 | 7 | 7 | 7 |
| 513 | | | part | | | | | | | |
| Composition | PG | 0.1 | Residual | 6.0 | — | 200 | 0.06 | 7 | 7 | 7 |
| 514 | | | part | | | | | | | |
| Composition | Polymer 5 | 0.1 | Residual | 6.0 | 13.8 | 200 | 0.16 | 7 | 7 | 7 |
| 515 | | | part | | | | | | | |
| Composition | Polymer 5 | 0.1 | Residual | 6.0 | 13.5 | 200 | 0.16 | 7 | 7 | 7 |
| 516 | | | part | | | | | | | |
| Composition | Polymer 5 | 0.1 | Residual | 6.0 | 5.7 | 200 | 0.05 | 7 | 7 | 7 |
| 517 | | | part | | | | | | | |
| Composition | Polymer 5 | 0.1 | Residual | 6.0 | 6.5 | 200 | 0.06 | 7 | 7 | 7 |
| 518 | | | part | | | | | | | |
| Composition | Polymer 6 | 0.1 | Residual | 6.0 | 13.8 | 200 | 0.16 | 7 | 7 | 7 |
| 519 | | | part | | | | | | | |
| Composition | Polymer 6 | 0.1 | Residual | 6.0 | 13.5 | 200 | 0.16 | 7 | 7 | 7 |
| 520 | | | part | | | | | | | |
| Composition | Polymer 6 | 0.1 | Residual | 6.0 | 5.7 | 200 | 0.05 | 7 | 7 | 7 |
| 521 | | | part | | | | | | | |
| Composition | Polymer 6 | 0.1 | Residual | 6.0 | 6.5 | 200 | 0.06 | 7 | 7 | 7 |
| 522 | | | part | | | | | | | |

TABLE 16

| | Composition and physical properties of composition | | | | | | | | | |
|---|---|---|---|---|---|---|---|---|---|---|
| | Antibacterial agent | | Organic acid | | | Organic amine | | | Chelating agent | |
| | | Content | | Content | | | Content | | | Content |
| Table 6 | | (% by | | (% by | Ratio | | (% by | Ratio | | (% by |
| (2-1) | Kind | mass) | Kind | mass) | A/B | Kind | mass) | A/C | Kind | mass) |
| Composition | Sorbic acid | 0.05 | Citric acid | 1.8 | 0.03 | Tris | 4.2 | 0.01 | HEDPO | 0.84 |
| 523 | | | Trimellitic acid | 0.2 | | | | | | |
| Composition | Sorbic acid | 0.05 | Citric acid | 1.8 | 0.03 | Tris | 4.2 | 0.01 | HEDPO | 0.84 |
| 524 | | | Trimellitic acid | 0.2 | | | | | L-Arginine | 0.5 |
| Composition | Sorbic acid | 0.05 | Citric acid | 3 | 0.02 | Tris | 5.1 | 0.01 | L-Arginine | 0.5 |
| 525 | | | Trimellitic acid | 0.3 | | | | | | |
| Composition | Sorbic acid | 0.05 | Citric acid | 0.6 | 0.06 | Tris | 1 | 0.05 | L-Arginine | 0.5 |
| 526 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 527 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 528 | | | Trimellitic acid | 0.2 | | | | | L-Arginine | 0.5 |
| Composition | MIT | 0.1 | Citric acid | 3 | 0.03 | Tris | 5.1 | 0.02 | L-Arginine | 0.5 |
| 529 | | | Trimellitic acid | 0.3 | | | | | | |
| Composition | MIT | 0.1 | Citric acid | 0.6 | 0.13 | Tris | 1 | 0.10 | L-Arginine | 0.5 |
| 530 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 531 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 532 | | | Trimellitic acid | 0.2 | | | | | L-Arginine | 0.5 |
| Composition | MIT | 0.1 | Citric acid | 3 | 0.03 | Tris | 5.1 | 0.02 | L-Arginine | 0.5 |
| 533 | | | Trimellitic acid | 0.3 | | | | | | |
| Composition | MIT | 0.1 | Citric acid | 0.6 | 0.13 | Tris | 1 | 0.10 | L-Arginine | 0.5 |
| 534 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 535 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 536 | | | Trimellitic acid | 0.2 | | | | | L-Arginine | 0.5 |
| Composition | MIT | 0.1 | Citric acid | 3 | 0.03 | Tris | 5.1 | 0.02 | L-Arginine | 0.5 |
| 537 | | | Trimellitic acid | 0.3 | | | | | | |
| Composition | MIT | 0.1 | Citric acid | 0.6 | 0.13 | Tris | 1 | 0.10 | L-Arginine | 0.5 |
| 538 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 539 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 540 | | | Trimellitic acid | 0.2 | | | | | L-Arginine | 0.5 |
| Composition | MIT | 0.1 | Citric acid | 3 | 0.03 | Tris | 5.1 | 0.02 | L-Arginine | 0.5 |
| 541 | | | Trimellitic acid | 0.3 | | | | | | |
| Composition | MIT | 0.1 | Citric acid | 0.6 | 0.13 | Tris | 1 | 0.10 | L-Arginine | 0.5 |
| 542 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 543 | | | Trimellitic acid | 0.2 | | | | | | |
| Composition | MIT | 0.1 | Citric acid | 1.8 | 0.05 | Tris | 4.2 | 0.02 | HEDPO | 0.84 |
| 544 | | | Trimellitic acid | 0.2 | | | | | L-Arginine | 0.5 |

TABLE 17

| | | | | | | | | Evaluation | | |
|---|---|---|---|---|---|---|---|---|---|---|
| | Composition and physical properties of composition | | | | | Diluted liquid | | Cleaning | Cleaning | |
| | Other components | | | | Electric | | Electric | performance | performance | |
| Table 6 | | Content | | | conductivity | Dilution | conductivity | after | after | W |
| (2-2) | Kind | (% by mass) | Water | pH | (S/m) | ratio | (S/m) | preparation | storage | corrosiveness |
| Composition 523 | Polymer 7 | 0.1 | Residual | 6.0 | 14.1 | 200 | 0.17 | 7 | 7 | 7 |
| | | | part | | | | | | | |
| Composition 524 | Polymer 7 | 0.1 | Residual | 6.0 | 13.8 | 200 | 0.16 | 7 | 7 | 7 |
| | | | part | | | | | | | |
| Composition 525 | Polymer 7 | 0.1 | Residual | 6.0 | 6.0 | 200 | 0.05 | 7 | 7 | 7 |
| | | | part | | | | | | | |
| Composition 526 | Polymer 7 | 0.1 | Residual | 6.0 | 6.7 | 200 | 0.06 | 7 | 7 | 7 |
| | | | part | | | | | | | |
| Composition 527 | Polymer 1 | 0.1 | Residual | 6.0 | 13.9 | 200 | 0.17 | 7 | 7 | 7 |
| | | | part | | | | | | | |
| Composition 528 | Polymer 1 | 0.1 | Residual | 6.0 | 13.1 | 200 | 0.15 | 7 | 7 | 7 |
| | | | part | | | | | | | |
| Composition 529 | Polymer 1 | 0.1 | Residual | 6.0 | 5.9 | 200 | 0.05 | 7 | 7 | 7 |
| | | | part | | | | | | | |
| Composition 530 | Polymer 1 | 0.1 | Residual | 6.0 | 7.6 | 200 | 0.07 | 7 | 7 | 7 |
| | | | part | | | | | | | |
| Composition 531 | PG | 0.1 | Residual | 6.0 | — | 200 | 0.16 | 7 | 7 | 7 |
| | | | part | | | | | | | |
| Composition 532 | PG | 0.1 | Residual | 6.0 | — | 200 | 0.16 | 7 | 7 | 7 |
| | | | part | | | | | | | |
| Composition 533 | PG | 0.1 | Residual | 6.0 | — | 200 | 0.05 | 7 | 7 | 7 |
| | | | part | | | | | | | |
| Composition 534 | PG | 0.1 | Residual | 6.0 | — | 200 | 0.06 | 7 | 7 | 7 |
| | | | part | | | | | | | |
| Composition 535 | Polymer 5 | 0.1 | Residual | 6.0 | 13.8 | 200 | 0.16 | 7 | 7 | 7 |
| | | | part | | | | | | | |
| Composition 536 | Polymer 5 | 0.1 | Residual | 6.0 | 13.5 | 200 | 0.16 | 7 | 7 | 7 |
| | | | part | | | | | | | |
| Composition 537 | Polymer 5 | 0.1 | Residual | 6.0 | 5.7 | 200 | 0.05 | 7 | 7 | 7 |
| | | | part | | | | | | | |
| Composition 538 | Polymer 5 | 0.1 | Residual | 6.0 | 6.5 | 200 | 0.06 | 7 | 7 | 7 |
| | | | part | | | | | | | |
| Composition 539 | Polymer 6 | 0.1 | Residual | 6.0 | 13.8 | 200 | 0.16 | 7 | 7 | 7 |
| | | | part | | | | | | | |
| Composition 540 | Polymer 6 | 0.1 | Residual | 6.0 | 13.5 | 200 | 0.16 | 7 | 7 | 7 |
| | | | part | | | | | | | |
| Composition 541 | Polymer 6 | 0.1 | Residual | 6.0 | 5.7 | 200 | 0.05 | 7 | 7 | 7 |
| | | | part | | | | | | | |
| Composition 542 | Polymer 6 | 0.1 | Residual | 6.0 | 6.5 | 200 | 0.06 | 7 | 7 | 7 |
| | | | part | | | | | | | |
| Composition 543 | Polymer 7 | 0.1 | Residual | 6.0 | 14.2 | 200 | 0.17 | 7 | 7 | 7 |
| | | | part | | | | | | | |
| Composition 544 | Polymer 7 | 0.1 | Residual | 6.0 | 13.3 | 200 | 0.16 | 7 | 7 | 7 |
| | | | part | | | | | | | |

TABLE 18

| | Composition and physical properties of composition | | | | | | | | | |
|---|---|---|---|---|---|---|---|---|---|---|
| | Antibacterial agent | | Organic acid | | | Organic amine | | | Chelating agent | |
| Table 6 | | Content | | Content | Ratio | | Content | Ratio | | Content |
| (3-1) | Kind | (% by mass) | Kind | (% by mass) | A/B | Kind | (% by mass) | A/C | Kind | (% by mass) |
| Composition 545 | MIT | 0.1 | Citric acid | 3 | 0.03 | Tris | 5.1 | 0.02 | L-Arginine | 0.5 |
| | | | Trimellitic acid | 0.3 | | | | | | |
| Composition 546 | MIT | 0.1 | Citric acid | 0.6 | 0.13 | Tris | 1 | 0.10 | L-Arginine | 0.5 |
| | | | Trimellitic acid | 0.2 | | | | | | |
| Composition 547 | Sorbic acid | 0.05 | Citric acid | 1.8 | 0.03 | Tris | 4.2 | 0.01 | HEDPO | 0.84 |
| | | | Trimellitic acid | 0.2 | | | | | | |
| Composition 548 | Sorbic acid | 0.05 | Citric acid | 1.8 | 0.03 | Tris | 4.2 | 0.01 | HEDPO | 0.84 |
| | | | Trimellitic acid | 0.2 | | | | | L-Arginine | 0.5 |
| Composition 549 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 550 | Sorbic acid | 0.05 | Citric acid | 0.6 | 0.06 | Tris | 1 | 0.05 | L-Arginine | 0.5 |
| | | | Trimellitic acid | 0.2 | | | | | | |
| Composition 551 | Sorbic acid | 0.05 | Citric acid | 1.8 | 0.03 | Tris | 4.2 | 0.01 | HEDPO | 0.84 |
| | | | Trimellitic acid | 0.2 | | | | | | |
| Composition 552 | Sorbic acid | 0.05 | Citric acid | 1.8 | 0.03 | Tris | 4.2 | 0.01 | HEDPO | 0.84 |
| | | | Trimellitic acid | 0.2 | | | | | L-Arginine | 0.5 |
| Composition 553 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 554 | Sorbic acid | 0.05 | Citric acid | 0.6 | 0.06 | Tris | 1 | 0.05 | L-Arginine | 0.5 |
| | | | Trimellitic acid | 0.2 | | | | | | |
| Composition 555 | Sorbic acid | 0.05 | Citric acid | 1.8 | 0.03 | Tris | 4.2 | 0.01 | HEDPO | 0.84 |
| | | | Trimellitic acid | 0.2 | | | | | | |
| Composition 556 | Sorbic acid | 0.05 | Citric acid | 1.8 | 0.03 | Tris | 4.2 | 0.01 | HEDPO | 0.84 |
| | | | Trimellitic acid | 0.2 | | | | | L-Arginine | 0.5 |
| Composition 557 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 558 | Sorbic acid | 0.05 | Citric acid | 0.6 | 0.06 | Tris | 1 | 0.05 | L-Arginine | 0.5 |
| | | | Trimellitic acid | 0.2 | | | | | | |
| Composition 559 | Sorbic acid | 0.05 | Citric acid | 1.8 | 0.03 | Tris | 4.2 | 0.01 | HEDPO | 0.84 |
| | | | Trimellitic acid | 0.2 | | | | | | |
| Composition 560 | Sorbic acid | 0.05 | Citric acid | 1.8 | 0.03 | Tris | 4.2 | 0.01 | HEDPO | 0.84 |
| | | | Trimellitic acid | 0.2 | | | | | L-Arginine | 0.5 |
| Composition 561 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 562 | Sorbic acid | 0.05 | Citric acid | 0.6 | 0.06 | Tris | 1 | 0.05 | L-Arginine | 0.5 |
| | | | Trimellitic acid | 0.2 | | | | | | |
| Composition 563 | Sorbic acid | 0.05 | Citric acid | 1.8 | 0.03 | Tris | 4.2 | 0.01 | HEDPO | 0.84 |
| | | | Trimellitic acid | 0.2 | | | | | | |
| Composition 564 | Sorbic acid | 0.05 | Citric acid | 1.8 | 0.03 | Tris | 4.2 | 0.01 | HEDPO | 0.84 |
| | | | Trimellitic acid | 0.2 | | | | | L-Arginine | 0.5 |
| Composition 565 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 566 | Sorbic acid | 0.05 | Citric acid | 0.6 | 0.06 | Tris | 1 | 0.05 | L-Arginine | 0.5 |
| | | | Trimellitic acid | 0.2 | | | | | | |

TABLE 19

| | Composition and physical properties of composition | | | | | | | Evaluation | | |
|---|---|---|---|---|---|---|---|---|---|---|
| | Other components | | | | | Diluted liquid | | Cleaning | Cleaning | |
| | | Content | | | Electric | | Electric | performance | performance | |
| Table 6 | | (% by | | | conductivity | Dilution | conductivity | after | after | W |
| (3-2) | Kind | mass) | Water | pH | (S/m) | ratio | (S/m) | preparation | storage | corrosiveness |
| Composition | Polymer 7 | 0.1 | Residual | 6.0 | 6.2 | 200 | 0.06 | 7 | 7 | 7 |
| 545 | | | part | | | | | | | |
| Composition | Polymer 7 | 0.1 | Residual | 6.0 | 7.8 | 200 | 0.07 | 7 | 7 | 7 |
| 546 | | | part | | | | | | | |
| Composition | Polymer 1 | 0.1 | Residual | 6.0 | 13.9 | 200 | 0.17 | 7 | 7 | 7 |
| 547 | | | part | | | | | | | |
| Composition | Polymer 1 | 0.1 | Residual | 6.0 | 13.1 | 200 | 0.15 | 7 | 7 | 7 |
| 548 | | | part | | | | | | | |
| Composition | Polymer 1 | 0.1 | Residual | 6.0 | 5.9 | 200 | 0.05 | 7 | 7 | 7 |
| 549 | | | part | | | | | | | |
| Composition | Polymer 1 | 0.1 | Residual | 6.0 | 7.6 | 200 | 0.07 | 7 | 7 | 7 |
| 550 | | | part | | | | | | | |
| Composition | PG | 0.1 | Residual | 6.0 | — | 200 | 0.16 | 7 | 7 | 7 |
| 551 | | | part | | | | | | | |
| Composition | PG | 0.1 | Residual | 6.0 | — | 200 | 0.16 | 7 | 7 | 7 |
| 552 | | | part | | | | | | | |
| Composition | PG | 0.1 | Residual | 6.0 | — | 200 | 0.05 | 7 | 7 | 7 |
| 553 | | | part | | | | | | | |
| Composition | PG | 0.1 | Residual | 6.0 | — | 200 | 0.06 | 7 | 7 | 7 |
| 554 | | | part | | | | | | | |
| Composition | Polymer 5 | 0.1 | Residual | 6.0 | 13.8 | 200 | 0.16 | 7 | 7 | 7 |
| 555 | | | part | | | | | | | |
| Composition | Polymer 5 | 0.1 | Residual | 6.0 | 13.5 | 200 | 0.16 | 7 | 7 | 7 |
| 556 | | | part | | | | | | | |
| Composition | Polymer 5 | 0.1 | Residual | 6.0 | 5.7 | 200 | 0.05 | 7 | 7 | 7 |
| 557 | | | part | | | | | | | |
| Composition | Polymer 5 | 0.1 | Residual | 6.0 | 6.5 | 200 | 0.06 | 7 | 7 | 7 |
| 558 | | | part | | | | | | | |
| Composition | Polymer 6 | 0.1 | Residual | 6.0 | 13.8 | 200 | 0.16 | 7 | 7 | 7 |
| 559 | | | part | | | | | | | |
| Composition | Polymer 6 | 0.1 | Residual | 6.0 | 13.5 | 200 | 0.16 | 7 | 7 | 7 |
| 560 | | | part | | | | | | | |
| Composition | Polymer 6 | 0.1 | Residual | 6.0 | 5.7 | 200 | 0.05 | 7 | 7 | 7 |
| 561 | | | part | | | | | | | |
| Composition | Polymer 6 | 0.1 | Residual | 6.0 | 6.5 | 200 | 0.06 | 7 | 7 | 7 |
| 562 | | | part | | | | | | | |
| Composition | Polymer 7 | 0.1 | Residual | 6.0 | 14.2 | 200 | 0.17 | 7 | 7 | 7 |
| 563 | | | part | | | | | | | |
| Composition | Polymer 7 | 0.1 | Residual | 6.0 | 13.3 | 200 | 0.16 | 7 | 7 | 7 |
| 564 | | | part | | | | | | | |
| Composition | Polymer 7 | 0.1 | Residual | 6.0 | 6.2 | 200 | 0.06 | 7 | 7 | 7 |
| 565 | | | part | | | | | | | |
| Composition | Polymer 7 | 0.1 | Residual | 6.0 | 7.8 | 200 | 0.07 | 7 | 7 | 7 |
| 566 | | | part | | | | | | | |

TABLE 20

| | Composition and physical properties of composition | | | | | | | | | |
|---|---|---|---|---|---|---|---|---|---|---|
| | Antibacterial agent | | Organic acid | | | Organic amine | | | Chelating agent | |
| Table 6 | | Content | | Content | Ratio | | Content | Ratio | | Content |
| (4-1) | Kind | (% by mass) | Kind | (% by mass) | A/B | Kind | (% by mass) | A/C | Kind | (% by mass) |
| Composition 567 | Sorbic acid | 0.05 | Citric acid | 1.8 | 0.03 | Tris | 4.2 | 0.01 | HEDPO | 0.84 |
| | | | Trimellitic acid | 0.2 | | | | | | |
| Composition 568 | Sorbic acid | 0.05 | Citric acid | 1.8 | 0.03 | Tris | 4.2 | 0.01 | HEDPO | 0.84 |
| | | | Trimellitic acid | 0.2 | | | | | L-Arginine | 0.5 |
| Composition 569 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 570 | Sorbic acid | 0.05 | Citric acid | 0.6 | 0.06 | Tris | 1 | 0.05 | L-Arginine | 0.5 |
| | | | Trimellitic acid | 0.2 | | | | | | |
| Composition 571 | MIT | 0.05 | Malic acid | 0.5 | 0.10 | Tris | 5.1 | 0.01 | HEDPO | 3.0 |
| Composition 572 | MIT | 0.05 | Tartaric acid | 0.5 | 0.10 | Tris | 5.0 | 0.01 | HEDPO | 3.0 |
| Composition 573 | MIT | 0.041 | Malic acid | 0.5 | 0.10 | DMAMP | 4.9 | 0.01 | HEDPO | 3.0 |
| | OIT | 0.009 | | | | | | | | |
| Composition 574 | Sorbic acid | 0.05 | Malic acid | 0.5 | 0.10 | Tris | 5.1 | 0.01 | HEDPO | 3.0 |
| Composition 575 | Sorbic acid | 0.05 | Citric acid | 0.38 | 0.13 | Tris | 6.5 | 0.01 | HEDPO | 4.2 |
| Composition 576 | MIT | 0.041 | Succinic acid | 0.5 | 0.10 | DMAMP | 5.1 | 0.01 | HEDPO | 3.0 |
| | OIT | 0.009 | | | | | | | | |
| Composition 577 | Dehydroacetic | 0.05 | Tartaric acid | 0.5 | 0.10 | AMP | 3.7 | 0.01 | HEDPO | 3.0 |
| | acid | | | | | | | | | |
| Composition 578 | Cresol | 0.05 | Tartaric acid | 0.5 | 0.10 | DMAMP | 4.8 | 0.01 | HEDPO | 3.0 |
| Composition 579 | Sorbic acid | 0.05 | Citric acid | 0.04 | 1.32 | Tris | 0.7 | 0.07 | HEDPO | 0.4 |
| Composition 580 | Sorbic acid | 0.005 | Citric acid | 0.04 | 0.13 | Tris | 0.7 | 0.01 | HEDPO | 0.4 |
| Composition 581 | Sorbic acid | 0.05 | Citric acid | 1.6 | 0.03 | Tris | 4.2 | 0.01 | HEDPO | 0.8 |
| | | | Trimellitic acid | 0.2 | | | | | | |
| Composition 582 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 583 | BIT | 0.05 | Maleic acid | 2 | 0.03 | Tris | 2.2 | 0.02 | EDTPO | 0.8 |
| Composition 584 | Sorbic acid | 0.05 | Phthalic acid | 0.10 | 1.67 | DMAMP | 0.8 | 0.31 | L-Histidine | 0.2 |
| | | | Oxalic acid | 0.05 | | | | | | |
| Composition 585 | BIT | 0.25 | Phthalic acid | 0.10 | 1.67 | AMP | 0.8 | 0.31 | L-Lysine | 0.2 |
| | | | Oxalic acid | 0.05 | | | | | | |
| Composition 586 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 587 | Sorbic acid | 0.05 | Citric acid | 3 | 0.02 | Tris | 5.1 | 0.01 | L-Arginine | 0.5 |
| | | | Trimellitic acid | 0.3 | | | | | | |
| Composition 588 | Sorbic acid | 0.05 | Citric acid | 3 | 0.02 | Tris | 5.1 | 0.01 | L-Arginine | 0.5 |
| | | | Trimellitic acid | 0.3 | | | | | | |

TABLE 21

| | | | | | | | | Evaluation | | |
|---|---|---|---|---|---|---|---|---|---|---|
| | Composition and physical properties of composition | | | | | Diluted liquid | | Cleaning | Cleaning | |
| | Other components | | | | Electric | | Electric | performance | performance | |
| Table 6 | | Content | | | conductivity | Dilution | conductivity | after | after | W |
| (4-2) | Kind | (% by mass) | Water | pH | (S/m) | ratio | (S/m) | preparation | storage | corrosiveness |
| Composition | Polymer 8 | 0.1 | Residual | 6.0 | 14.2 | 200 | 0.17 | 7 | 7 | 7 |
| 567 | | | part | | | | | | | |
| Composition | Polymer 8 | 0.1 | Residual | 6.0 | 13.3 | 200 | 0.16 | 7 | 7 | 7 |
| 568 | | | part | | | | | | | |
| Composition | Polymer 8 | 0.1 | Residual | 6.0 | 6.2 | 200 | 0.06 | 7 | 7 | 7 |
| 569 | | | part | | | | | | | |
| Composition | Polymer 8 | 0.1 | Residual | 6.0 | 7.8 | 200 | 0.07 | 7 | 7 | 7 |
| 570 | | | part | | | | | | | |
| Composition | Polymer 1 | 0.1 | Residual | 6.0 | 14.1 | 200 | 0.17 | 7 | 7 | 7 |
| 571 | | | part | | | | | | | |
| Composition | Polymer 1 | 0.1 | Residual | 6.0 | 14.2 | 200 | 0.17 | 7 | 7 | 7 |
| 572 | | | part | | | | | | | |
| Composition | Polymer 1 | 0.1 | Residual | 6.0 | 15.2 | 200 | 0.18 | 7 | 7 | 7 |
| 573 | | | part | | | | | | | |
| Composition | Polymer 1 | 0.1 | Residual | 6.0 | 14.1 | 200 | 0.17 | 7 | 7 | 7 |
| 574 | | | part | | | | | | | |
| Composition | Polymer 1 | 0.1 | Residual | 6.0 | 14.3 | 200 | 0.17 | 7 | 7 | 7 |
| 575 | | | part | | | | | | | |
| Composition | Polymer 1 | 0.1 | Residual | 6.0 | 15.3 | 200 | 0.18 | 7 | 7 | 7 |
| 576 | | | part | | | | | | | |
| Composition | Polymer 1 | 0.1 | Residual | 6.0 | 15.5 | 200 | 0.18 | 7 | 7 | 7 |
| 577 | | | part | | | | | | | |
| Composition | Polymer 1 | 0.1 | Residual | 6.0 | 15.2 | 200 | 0.18 | 7 | 7 | 7 |
| 578 | | | part | | | | | | | |
| Composition | Polymer 1 | 0.1 | Residual | 6.0 | 14.1 | 200 | 0.17 | 7 | 7 | 7 |
| 579 | | | part | | | | | | | |
| Composition | Polymer 1 | 0.1 | Residual | 6.0 | 14.0 | 200 | 0.17 | 7 | 7 | 7 |
| 580 | | | part | | | | | | | |
| Composition | Polymer 1 | 0.1 | Residual | 6.0 | 15.3 | 200 | 0.20 | 7 | 7 | 7 |
| 581 | | | part | | | | | | | |
| Composition | Polymer 1 | 0.1 | Residual | 6.0 | 16.2 | 200 | 0.23 | 7 | 7 | 7 |
| 582 | | | part | | | | | | | |
| Composition | Polymer 1 | 0.1 | Residual | 6.0 | 13.9 | 200 | 0.16 | 7 | 7 | 7 |
| 583 | | | part | | | | | | | |
| Composition | Polymer 1 | 0.1 | Residual | 6.0 | 15.1 | 200 | 0.18 | 7 | 7 | 7 |
| 584 | | | part | | | | | | | |
| Composition | Polymer 1 | 0.1 | Residual | 6.0 | 15.3 | 200 | 0.10 | 7 | 7 | 7 |
| 585 | | | part | | | | | | | |
| Composition | Polymer 1 | 0.5 | Residual | 6.0 | 5.7 | 200 | 0.05 | 7 | 6 | 7 |
| 586 | | | part | | | | | | | |
| Composition | Polymer 1 | 1 | Residual | 6.0 | 5.7 | 200 | 0.05 | 6 | 6 | 7 |
| 587 | | | part | | | | | | | |
| Composition | Polymer 1 | 2 | Residual | 6.0 | 5.7 | 200 | 0.05 | 6 | 5 | 7 |
| 588 | | | part | | | | | | | |

From the results shown in the above tables, it has been confirmed that as compared with the comparative composition 1 containing no organic amine and the comparative composition 2 containing no antibacterial agent, all of the compositions 501 to 588 make it possible to obtain an effect that the cleaning performance in a case where a semiconductor substrate is subjected to cleaning by using a diluted liquid after a lapse of a predetermined period of time.

It has been confirmed that the effect of the present invention is more excellent in a case where the content of the water-soluble polymer in the composition is 100 by mass or less, it has been confirmed that the cleaning performance is more excellent in a case where the content thereof is 0.5% by mass or less, and it has been confirmed that the effect of the present invention is further excellent in a case where the content thereof is 0.2% by mass or less (the comparison among the compositions 504 to 507 and the comparison among the compositions 503 and 586 to 588).

What is claimed is:

1. A composition comprising:
an antibacterial agent;
an organic acid;
an organic amine; and
water,
wherein a content of the water is 70% by mass or more with respect to a total mass of the composition, and
a pH at 25° C. is 4.0 to 9.0.

2. The composition according to claim 1,
wherein the composition is at least one selected from the group consisting of a cleaning liquid for a semiconductor substrate which has been subjected to a chemical mechanical polishing treatment, a cleaning liquid for a brush that is used for cleaning of a semiconductor substrate, a cleaning liquid for a polishing pad that is used for a treatment of a semiconductor substrate, and a cleaning liquid for buffing cleaning of a semiconductor substrate which has been subjected to a chemical mechanical polishing treatment.

3. The composition according to claim 1,
wherein a ratio of a content of the antibacterial agent to a content of the organic acid is 0.5 or less in terms of mass ratio, and
a ratio of the content of the antibacterial agent to a content of the organic amine is 0.3 or less in terms of mass ratio.

4. The composition according to claim 1,
wherein the composition is a cleaning liquid for a tungsten-containing semiconductor substrate which has been subjected to a chemical mechanical polishing treatment, or a cleaning liquid for buffing cleaning of a tungsten-containing semiconductor substrate which has been subjected to a chemical mechanical polishing treatment.

5. The composition according to claim 1,
wherein the composition is a cleaning liquid for a polishing pad containing a polyurethane resin, where the polishing pad is used for a treatment of a semiconductor substrate.

6. The composition according to claim 1,
wherein the composition is a cleaning liquid for a brush containing a polymer resin having a hydroxyl group, where the brush is used for cleaning of a semiconductor substrate.

7. The composition according to claim 1,
wherein the composition is used for a use application different from any of a cleaning liquid for a semiconductor substrate which has been subjected to a chemical mechanical polishing treatment, a cleaning liquid for a brush that is used for cleaning of a semiconductor substrate, a cleaning liquid for a polishing pad that is used for a treatment of a semiconductor substrate, and a cleaning liquid for buffing cleaning of a semiconductor substrate which has been subjected to a chemical mechanical polishing treatment.

8. The composition according to claim 1,
wherein an electric conductivity at 25° C. is 0.1 to 2.0 S/m.

9. The composition according to claim 1,
wherein a diluted liquid obtained by diluting the composition by 50 times or more is used as a cleaning liquid.

10. The composition according to claim 1,
wherein the organic acid is a compound that has a carboxy group or a sulfo group and has neither an amino group nor a phosphonate group in a molecule.

11. The composition according to claim 1,
wherein the organic acid contains one or more hydroxy groups and two or more carboxy groups.

12. The composition according to claim 1,
wherein the organic amine is a compound or a salt thereof, which has at least one amino group selected from the group consisting of a primary amino group, a secondary amino group, and a tertiary amino group in a molecule and has no carboxy group in the molecule.

13. The composition according to claim 1,
wherein the organic amine is an alkanolamine.

14. The composition according to claim 1, further comprising:
a chelating agent.

15. The composition according to claim 14,
wherein the chelating agent has a phosphonate group.

16. The composition according to claim 1, further comprising:
an anticorrosive agent.

17. The composition according to claim 16,
wherein the anticorrosive agent is a compound having a purine skeleton.

18. The composition according to claim 1,
wherein the antibacterial agent includes at least one selected from the group consisting of a carboxylic acid-based antibacterial agent and an isothiazolinone-based antibacterial agent.

19. A manufacturing method for a semiconductor element, comprising:
a step of cleaning a semiconductor substrate using the composition according to claim 1.

20. A manufacturing method for a semiconductor element, comprising:
a step of subjecting a semiconductor substrate to a chemical mechanical polishing treatment; and
a step of cleaning the semiconductor substrate subjected to the chemical mechanical polishing treatment, by using the composition according to claim 1.

21. A manufacturing method for a semiconductor element, comprising:
a step of subjecting a semiconductor substrate to a chemical mechanical polishing treatment; and
a step of cleaning the semiconductor substrate subjected to the chemical mechanical polishing treatment, by using a diluted liquid obtained by diluting the composition according to claim 1 with water by 50 times or more in terms of mass ratio.

22. A cleaning method for a semiconductor substrate, comprising:
cleaning a semiconductor substrate using the composition according to claim 1.
